(19) United States
(12) Patent Application Publication
(10) Pub. No.: US 2015/0338743 A1
(43) Pub. Date: Nov. 26, 2015

(54) PATTERN FORMING METHOD, METHOD FOR MANUFACTURING ELECTRONIC DEVICE USING SAME, AND ELECTRONIC DEVICE

(71) Applicant: FUJIFILM CORPORATION, Tokyo (JP)

(72) Inventor: Kaoru IWATO, Haibara-gun (JP)

(73) Assignee: FUJIFILM CORPORATION, Tokyo (JP)

(21) Appl. No.: 14/814,844

(22) Filed: Jul. 31, 2015

Related U.S. Application Data
(63) Continuation of application No. PCT/JP2014/050846, filed on Jan. 17, 2014.

(30) Foreign Application Priority Data
Jan. 31, 2013 (JP) 2013-017957

(51) Int. Cl. G03F 7/32; G03F 7/20; G03F 7/40; G03F 7/16

(52) U.S. Cl. CPC G03F 7/325; G03F 7/16; G03F 7/2004; G03F 7/20; G03F 7/2041; G03F 7/40

(57) ABSTRACT

There is provided a pattern forming method comprising a step of forming a resist film from an actinic ray-sensitive or radiation-sensitive resin composition containing a resin capable of increasing the polarity by an action of an acid to decrease the solubility in an organic solvent-containing developer and a compound capable of decomposing upon irradiation with an actinic ray or radiation to generate an acid, a step of forming, on the resist film, a protective film from a protective film composition, a step of exposing the resist film having a protective film to an electron beam or an extreme-ultraviolet ray, and a step of developing the resist film by using the organic solvent-containing developer.

### CROSS REFERENCE TO RELATED APPLICATION

This is a continuation of International Application No. PCT/JP2014/050846 filed on Jan. 17, 2014, and claims priority from Japanese Patent Application No. 2013-017957 filed on Jan. 31, 2013, the entire disclosures of which are incorporated therein by reference.

### TECHNICAL FIELD

The present invention relates to a pattern forming method using a developer containing an organic solvent, which is suitably used in the ultramicrolithography process such as production of VLSI or a high-capacity microchip and in other fabrication processes, a method for manufacturing an electronic device by using the same, and an electronic device. More specifically, the present invention relates to a pattern forming method using a developer containing an organic solvent, which is suitably used in microfabrication of a semiconductor device using an electron beam or EUV light (wavelength: around 13 nm), a method for manufacturing an electronic device by using the same, and an electronic device.

### BACKGROUND ART

In the process of producing a semiconductor device such as IC and LSI, microfabrication by lithography using a photoresist composition has been conventionally performed. In recent years, with an increase in the integration degree of an integrated circuit, formation of an ultrafine pattern in the sub-micron or quarter-micron region is required, and in turn, the exposure wavelength tends to become shorter, for example, from g line to i line or further to KrF excimer laser light. In addition to the excimer laser light, development of lithography using an electron beam, an X-ray or EUV light is also being pursued at present.

Such electron beam, X-ray or EUV lithography is positioned as a next-generation or next-next-generation pattern formation technology, and a resist composition having high sensitivity and high resolution is demanded.

In particular, the elevation of sensitivity is a very important issue for shortening the wafer processing time, but when higher sensitivity is pursued, the pattern profile or resolution indicated by a limiting resolution line width is deteriorated, and it is strongly desired to develop a resist composition satisfying all of these properties at the same time.

High sensitivity is in a trade-off relationship with high resolution and good pattern profile, and how to satisfy these properties at the same time is very important.

The actinic ray-sensitive or radiation-sensitive composition generally includes a “positive” type using a resin sparingly soluble or insoluble in an alkali developer and forming a pattern by solubilizing the exposed area in an alkali developer by the exposure to radiation, and a “negative” type using a resin soluble in an alkali developer and forming a pattern by sparingly solubilizing or insolubilizing the exposed area in an alkali developer by the exposure to radiation.

As the actinic ray-sensitive or radiation-sensitive composition suitable for such a lithography process using electron beam, X-ray or EUV light, a chemical amplification positive resist composition utilizing an acid catalytic reaction is mainly studied from the standpoint of elevating the sensitivity, and a chemical amplification positive resist composition composed of, as the main component, a phenolic resin that is insoluble or sparingly soluble in an alkali developer and has a property of becoming soluble in an alkali developer by an action of an acid (hereinafter, simply referred to as “phenolic acid-decomposable resin”), and an acid generator is being effectively used.

On the other hand, the manufacture of a semiconductor device, etc. requires formation of patterns having various profiles, such as line, trench and hole. In order to meet the requirement for the formation of patterns having various profiles, actinic ray-sensitive or radiation-sensitive resin compositions of not only a positive type but also a negative type are under development (see, for example, Patent Documents 1 and 2).

In the formation of an ultrafine patter, more improvements are demanded on the reduction of resolution and the pattern profile.

To solve this problem, a method of developing an acid-decomposable resin by using a developer other than an alkali developer has also been proposed (see, for example, Patent Documents 3 and 4).

### RELATED ART

### Patent Document

Patent Document 1: JP-A-2002-148806 (the term “JP-A” as used herein means an “unexamined published Japanese patent application”)

Patent Document 2: JP-A-2008-268935

Patent Document 3: JP-A-2010-217884

Patent Document 4: JP-A-2011-123469

### DISCLOSURE OF THE INVENTION

### Problems that the Invention is to Solve

However, in the method of forming a pattern by developing an acid-decomposable resin with a developer (typically, an organic developer) other than an alkali developer, it is required to more enhance the solubility, for example, at the time of forming an isolated space pattern having an ultrafine space width (for example, a space width of 30 nm or less).

An object of the present invention is to solve the above-described problem and provide a pattern forming method ensuring excellent resolution at the time of formation of an isolated space pattern having an ultrafine space width (for example, a space width of 30 nm or less).

### Means for Solving the Problems

The present invention has the following configurations, and the above-described object of the present invention is thereby achieved.

[1] A pattern forming method comprising:

a step of forming a resist film from an actinic ray-sensitive or radiation-sensitive resin composition containing a resin capable of increasing the polarity by an action of an acid to decrease the solubility in an organic solvent-containing developer and a compound capable of decomposing upon irradiation with an actinic ray or radiation to generate an acid,

a step of forming, on the resist film, a protective film from a protective film composition,

a step of exposing the resist film having a protective film to an electron beam or an extreme-ultraviolet ray, and

a step of developing the resist film by using the organic solvent-containing developer.

[2] The pattern forming method as described in [1],

wherein the exposure is exposure without intervention of an immersion medium.

[3] The pattern forming method as described in [1] or [2],

wherein the protective film composition is an aqueous composition.

[4] The pattern forming method as described in [3],

wherein the pH of the aqueous composition is from 1 to 10.

[5] The pattern forming method as described in any one of [1] to [4],

wherein the protective film composition contains an amphiphatic resin.

[6] The pattern forming method as described in [1] or [2],

wherein the protective film composition is an organic solvent-based composition.

[7] The pattern forming method as described in any one of [1] to [6],

wherein the resin capable of increasing the polarity by an action of an acid to decrease the solubility in an organic solvent-containing developer contains a repeating unit represented by the following formula (I):

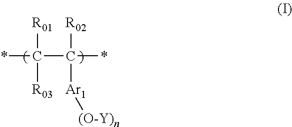

wherein

each of R₀₁, R₀₂ and R₀₃ independently represents a hydrogen atom, an alkyl group, a cycloalkyl group, a halogen atom, a cyano group or an alkoxycarbonyl group,

R₀₃ may represent an alkylene group and combine with Ar₁ to form a 5- or 6-membered ring,

Ar₁ represented an aromatic ring group,

each of n Ys independently represents a hydrogen atom or a group capable of leaving by an action of an acid, provided that at least one Y represents a group capable of leaving by an action of an acid, and

n represents an integer of 1 to 4.

[8] The pattern forming method as described in any one of [1] to [7],

wherein the resin capable of increasing the polarity by an action of an acid to decrease the solubility in an organic solvent-containing developer contains a repeating unit having a lactone structure-containing group.

[9] The pattern forming method as described in any one of [1] to [8],

wherein the organic solvent contained in the organic solvent-containing developer is at least one organic solvent selected from the group consisting of a ketone-based solvent, an ester-based solvent and an ether-based solvent.

[10] The pattern forming method as described in any one of [1] to [9], comprising rinsing the resist film by using an organic solvent-containing rinsing solution after development using the organic solvent-containing developer.
[11] The pattern forming method as described in [10],

wherein the organic solvent contained in the rinsing solution is an alcohol-based solvent.

[12] A method for manufacturing an electronic device, comprising the pattern forming method described in any one of [1] to [11].
[13] An electronic device manufactured by the method for manufacturing an electronic device described in [12].

### Advantage of the Invention

According to the present invention, a pattern forming method ensuring excellent resolution at the time of formation of an isolated space pattern having an ultrafine space width (for example, a space width of 30 nm or less) can be provided.

### MODE FOR CARRYING OUT THE INVENTION

The mode for carrying out the present invention is described below.

In the description of the present invention, when a group (atomic group) is denoted without specifying whether substituted or unsubstituted, the group encompasses both a group having no substituent and a group having a substituent. For example, “an alkyl group” encompasses not only an alkyl group having no substituent (unsubstituted alkyl group) but also an alkyl group having a substituent (substituted alkyl group).

In the description of the present invention, the “light” encompasses not only an extreme-ultraviolet ray (EUV light) but also an electron beam.

Furthermore, unless otherwise indicated, the “exposure” as used in the description of the present invention encompasses not only exposure to an extreme-ultraviolet ray (EUV light) but also lithography with an electron beam.

The “actinic ray” or “radiation” as used in the description of the present invention means, for example, an extreme-ultraviolet ray (EUV light), an X-ray or an electron beam. Also, in the present invention, the “light” means an actinic ray or radiation. Unless otherwise indicated, the “exposure” as used in the description of the present invention encompasses not only exposure to X-ray, EUV light, etc. but also lithography with a particle beam such as electron beam and ion beam.

The pattern forming method of the present invention includes the following steps and preferably includes these steps in this order:

(i) a step of forming a resist film from an actinic ray-sensitive or radiation-sensitive resin composition containing a resin capable of increasing the polarity by an action of an acid to decrease the solubility in an organic solvent-containing developer (hereinafter, sometimes referred to as “acid-decomposable resin”) and a compound capable of decomposing upon irradiation with an actinic ray or radiation to generate an acid (hereinafter, sometimes referred to as “acid generator”),

(ii) a step of forming, on the resist film, a protective film from a protective film composition,

(iii) a step of exposing the resist film having a protective film to an electron beam or an extreme-ultraviolet ray, and

(iv) a step of developing the resist film by using the organic solvent-containing developer.

Thanks to this configuration, a pattern forming method ensuring excellent resolution at the time of formation of an isolated space pattern having an ultrafine space width (for example, a space width of 30 nm or less) can be provided. The reason therefor is not clearly known but is presumed as follows.

In general, when a resist film formed using an actinic ray-sensitive or radiation-sensitive resin composition containing an acid generator is exposed, the surface layer part of the resist film allows a high degree of exposure compared to the inner part, leading to a tendency that the concentration of an acid generated is increased and a reaction of the acid with an acid-decomposable resin more proceeds. If the exposed film is then developed using an organic solvent-containing developer, the region defining an isolated pattern (i.e., the exposed area) tends to have a reverse tapered shape or a T-top shape in the cross-section. This time, the present inventors have found that exposure to an electron beam or an extreme-ultraviolet ray may be advantageous in view of an optical image, particularly, at the time of formation of an isolated space pattern having an ultrafine space width (for example, a space width of 30 nm or less) but, on the other hand, because of a very fine space width, the above-described problem is likely to be manifested, leading to a decarease in the resolution.

The present inventors have made intensive studies by taking the above-described problem into account, as a result, it has been found that in a pattern forming method of performing exposure by using an electron beam or an extreme-ultraviolet ray and at the same time, performing development by using an organic developer, when a step of forming a protective film from a protective composition is implemented before exposure, surprisingly, the resolution can be enhanced at the time of formation of an isolated space pattern having an ultrafine space width (for example, a space width of 30 nm or less). This is presumed to occur because compared with a case of not forming a protective layer on a resist film, the acid in the surface layer part of the exposed area of the resist film can diffuse into the protective film and diffusion of the acid into the surface layer part of the unexposed area is suppressed.

As a result, it is thought that, first, the acid concentration distribution in the thickness direction of the exposed area of the resist film can be more uniform and a reaction for making the resist film insoluble or sparingly soluble in an organic solvent-containing developer by using the acid as a catalyst can proceed more uniformly with respect to the thickness direction of the resist film. Then, it is expected that formation of the above-described reverse tapered shape or T-top shape in the cross-section of a region defining an isolated space pattern is lessened and the resolution particularly at the time of formation of an isolated space pattern having an ultrafine space width is enhanced.

In addition, the present inventors have found that in the case of forming an isolated space pattern having the above-described ultrafine space width by a positive pattern forming method using an alkali developer, even when a step of forming a protective film from a protective film composition is implemented before exposure, the resolution is scarcely enhanced.

This is presumed to occur because the positive pattern forming method is a pattern forming method of dissolving the exposed area by development and therefore, diffusion of the acid in the surface layer part of the exposed area into the surface layer part of the unexposed area is not a factor contributing to the formation of a reverse tapered or T-top shape in the cross-section of a region defining an isolated space pattern.

### <Pattern Forming Method>

The pattern forming method of the present invention includes the following steps:

(i) a step of forming a resist film from an actinic ray-sensitive or radiation-sensitive resin composition containing a resin capable of increasing the polarity by an action of an acid to decrease the solubility in an organic solvent-containing developer and a compound capable of decomposing upon irradiation with an actinic ray or radiation to generate an acid,

(ii) a step of forming, on the resist film, a protective film from a protective film composition,

(iii) a step of exposing the resist film having a protective film to an electron beam or an extreme-ultraviolet ray, and

(iv) a step of developing the resist film by using the organic solvent-containing developer.

The pattern forming method of the present invention may further include (v) a step of performing development by using a positive developer to form a resist pattern. By including this step, a pattern with resolution equivalent to double the spatial frequency can be formed.

In the step (i) of forming a resist film from an actinic ray-sensitive or radiation-sensitive resin composition containing a resin capable of increasing the polarity by an action of an acid to decrease the solubility in an organic solvent-containing developer and a compound capable of decomposing upon irradiation with an actinic ray or radiation to generate an acid, any method may be used as long as the resist composition can be coated on a substrate, and conventionally known methods such as spin coating method, spray coating method, roller coating method and dipping method can be used. The resist composition is preferably coated by a spin coating method. After coating the resist composition, the substrate is heated (pre-baked), if desired, whereby a film deprived of an insoluble residual solvent can be uniformly formed. The pre-bake temperature is not particularly limited but is preferably from 50 to 160° C., more preferably from 60 to 140° C.

In the present invention, the substrate on which the film is formed is not particularly limited, and a substrate generally used in the production process of a semiconductor such as IC, in the production process of a circuit board of a liquid crystal device, a thermal head, etc., or in the lithography process for other photo applications, for example, an inorganic substrate such as silicon, SiN, SiO₂ and SiN, and a coating-type inorganic substrate such as SOG, can be used.

Before forming the resist film, an antireflection film may be previously provided by coating on the substrate.

As the antireflection film, either an inorganic film type such as titanium, titanium dioxide, titanium nitride, chromium oxide, carbon and amorphous silicon, or an organic film type composed of a light absorber and a polymer material, can be used. In addition, as the organic antireflection film, a commercially available organic antireflection film such as DUV30 Series and DUV-40 Series produced by Brewer Science, Inc., AR-2, AR-3 and AR-5 produced by Shipley Co., Ltd., and ARC Series, e.g., ARC29A, produced by Nissan Chemical Industries, Ltd., may also be used.

After the step (i) of forming a resist film but before the step (iii) of exposing the resist film having a protective film to an electron beam or an extreme-ultraviolet ray, the step (ii) of forming, on the resist film, a protective film (hereinafter, sometimes referred to as “topcoat”) from a protective film composition is performed. The function required of the topcoat includes suitability for coating on top of the resist film. The topcoat is preferably unmixable with the resist and uniformly coatable as an overlayer of the resist.

In order to uniformly coat a protective film on top of the resist film without dissolving the resist film, the protective film composition preferably contains a solvent incapable of dissolving the resist film. A solvent differing in the component from the later-described organic solvent-containing developer is more preferably used as the solvent incapable of dissolving the resist film. The method for coating the protective film composition is not particularly limited, and, for example, a spin coating method may be applied.

The thickness of the topcoat is not particularly limited, but in view of transparency to an exposure light source, the topcoat is usually formed with a thickness of 1 to 300 nm, preferably from 10 to 150 nm.

After the formation of topcoat, the substrate is heated, if desired.

In view of resolution, the refractive index of the topcoat is preferably close to the refractive index of the resist film.

Among others, in the case where the protective film composition is the later-described aqueous composition, the pattern forming method of the present invention may further include a separation step (a step of removing the protective film by bringing the protective film formed on the resist film into contact with a solvent and dissolving the protective film in the solvent) between the steps (iii) and (iv).

In the separation step, water is preferably used as the solvent for dissolving the protective film.

The separation time of the protective film is preferably from 5 to 300 seconds, more preferably from 10 to 180 seconds.

The topcoat may also be removed using, for example, an aqueous alkali solution.

The aqueous alkali solution that can be used includes, specifically, an aqueous solution of tetramethylammonium hydroxide.

In the step (iii) of exposing the resist film having a protective film to an electron beam or an extreme-ultraviolet ray, the resist film may be exposed by a generally well-known method. Preferably, the resist film is irradiated with an actinic ray or radiation through a predetermined mask. The exposure dose may be appropriately set but is usually from 1 to 100 mJ/cm². The step (iii) is preferably performed without intervention of an immersion medium.

The light source used for the exposure apparatus in the present invention includes EUV light (13.5 nm), an electron beam, etc. Among these, EUV light is preferably used.

The pattern forming method of the present invention may have a plurality of exposure steps. In this case, the plurality of times of exposure may use the same light source or different light sources, but it is preferable to use EUV light (13.5 nm) for the first exposure.

After the exposure step above, (vi) a heating step (baking; sometimes referred to as PEB) is preferably performed, and the resist film is then developed and rinsed, whereby a good pattern can be obtained. The temperature of PEB is not particularly limited as long as a good resist pattern is obtained, but the temperature is usually from 40 to 160° C.

In the present invention, a resist pattern is formed by (iv) performing development using an organic solvent-containing developer.

The step (iv) of performing development by using an organic solvent-containing developer is preferably a step of simultaneously removing an insoluble portion of the resist film.

In the case of performing negative development, an organic developer containing an organic solvent is preferably used.

As the organic developer usable when performing negative development, a polar solvent such as ketone-based solvent, ester-based solvent, alcohol-based solvent, amide-based solvent and ether-based solvent, or a hydrocarbon-based solvent can be used, and a developer containing at least one organic solvent selected from the group consisting of a ketone-based solvent, an ester-based solvent and an ether-based solvent is preferably used. As for the organic developer, for example, a ketone-based solvent such as 1-octanone, 2-octanone, 1-nonanone, 2-nonanone, acetone, 4-heptanone, 1-hexanone, 2-hexanone, diisobutyl ketone, cyclohexanone, methylcyclohexanone, phenylacetone, methyl ethyl ketone, methyl isobutyl ketone, acetyl acetone, acetonyl acetone, ionone, diacetonyl alcohol, acetyl carbinol, acetophenone, methyl naphthyl ketone, isophorone and propylene carbonate, and an ester-based solvent such as methyl acetate, butyl acetate, ethyl acetate, isopropyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate and propyl lactate, may be used.

The alcohol-based solvent includes, for example, an alcohol such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol and n-decanol, a glycol-based solvent such as ethylene glycol, diethylene glycol and triethylene glycol, and a glycol ether-based solvent such as ethylene glycol monomethyl ether, propylene glycol monomethyl ether, ethylene glycol, diethylene glycol monomethyl ether, triethylene glycol monoethyl ether and methoxymethyl butanol.

The ether-based solvent includes dioxane, tetrahydrofuran, etc., in addition to the above-described glycol ether-based solvent.

The amide-based solvent which can be used includes N-methyl-2-pyrrolidone, N,N-dimethylacetamide, N,N-dimethylformamide, hexamethylphosphoric triamide, 1,3-dimethyl-2-imidazolidinone, etc.

The hydrocarbon-based solvent includes, for example, an aromatic hydrocarbon-based solvent such as toluene and xylene, and an aliphatic hydrocarbon-based solvent such as pentane, hexane, octane and decane.

A plurality of these solvents may be mixed, or the solvent may be used by mixing it with a solvent other than those described above or with water.

The developing method includes, for example, a method of raising the developer on the substrate surface by the effect of a surface tension and keeping it still for a fixed time, thereby performing the development (puddling method), a method of spraying the developer on the substrate surface (spraying method), and a method of continuously ejecting the developer on the substrate spinning at a constant speed while scanning a developer ejecting nozzle at a constant speed (dynamic dispense method).

The vapor pressure at 20° C. of the organic solvent-containing developer is preferably 5 kPa or less, more preferably 3 kPa or less, and most preferably 2 kPa or less. By setting the vapor pressure of the organic solvent-containing developer to 5 kPa or less, evaporation of the developer on a substrate or in a development cup is suppressed and the temperature uniformity in the wafer plane is enhanced, as a result, the dimensional uniformity in the wafer plane is improved.

Specific examples of the organic developer having a vapor pressure of 5 kPa or less at 20° C. include a ketone-based solvent such as 1-octanone, 2-octanone, 1-nonanone, 2-nonanone, 4-heptanone, 2-hexanone, diisobutyl ketone, cyclohexanone, methylcyclohexanone, phenylacetone and methyl isobutyl ketone, an ester-based solvent such as butyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, butyl formate, propyl formate, ethyl lactate, butyl lactate and propyl lactate, an alcohol-based solvent such as n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol and n-decanol, a glycol-based solvent such as ethylene glycol, diethylene glycol and triethylene glycol, a glycol ether-based solvent such as ethylene glycol monomethyl ether, propylene glycol monomethyl ether, ethylene glycol, propylene glycol, diethylene glycol monomethyl ether, triethylene glycol monoethyl ether and methoxymethyl butanol, an ether-based solvent such as tetrahydrofuran, an amide-based solvent such as N-methyl-2-pyrrolidone, N,N-dimethylacetamide and N,N-dimethylformamide, an aromatic hydrocarbon-based solvent such as toluene and xylene, and an aliphatic hydrocarbon-based solvent such as octane and decane.

Specific examples of the organic developer having a vapor pressure of 2 kPa or less at 20° C., which is a most preferable range, include a ketone-based solvent such as 1-octanone, 2-octanone, 1-nonanone, 2-nonanone, 4-heptanone, 2-hexanone, diisobutyl ketone, cyclohexanone, methylcyclohexanone and phenylacetone, an ester-based solvent such as butyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, ethyl lactate, butyl lactate and propyl lactate, an alcohol-based solvent such as n-butyl alcohol, sec-butyl alcohol, tert-butyl alcohol, isobutyl alcohol, n-hexyl alcohol, n-heptyl alcohol, n-octyl alcohol and n-decanol, a glycol-based solvent such as ethylene glycol, diethylene glycol and triethylene glycol, a glycol ether-based solvent such as ethylene glycol monomethyl ether, propylene glycol monomethyl ether, ethylene glycol, propylene glycol, diethylene glycol monomethyl ether, triethylene glycol monoethyl ether and methoxymethyl butanol, an amide-based solvent such as N-methyl-2-pyrrolidone, N,N-dimethylacetamide and N,N-dimethylformamide, an aromatic hydrocarbon-based solvent such as xylene, and an aliphatic hydrocarbon-based solvent such as octane and decane.

In the developer usable when performing negative development, an appropriate amount of a surfactant may be added, if desired.

The surfactant is not particularly limited but, for example, ionic or nonionic, fluorine-containing and/or silicon-containing surfactants can be used. These fluorine-containing and/or silicon-containing surfactants include, for example, surfactants described in JP-A-62-36663, JP-A-61-226746, JP-A-61-226745, JP-A-62-170950, JP-A-63-34540, JP-A-7-230165, JP-A-8-62834, JP-A-9-54432, JP-A-9-5988 and U.S. Pat. Nos. 5,405,720, 5,360,692, 5,529,881, 5,296,330, 5,436,098, 5,576,143, 5,294,511 and 5,824,451. A nonionic surfactant is preferred. The nonionic surfactant is not particularly limited, but use of a fluorine-containing surfactant or a silicon-containing surfactant is more preferred.

The amount of the surfactant used is usually from 0.001 to 5 mass %, preferably from 0.005 to 2 mass %, more preferably from 0.01 to 0.5 mass %, relative to the total amount of the developer.

In the organic developer, a basic compound may also be incorporated as described particularly in [0032] to [0063] of JP-A-2013-11833. The basic compound also includes the later-described basic compound (D) that may be incorporated into the actinic ray-sensitive or radiation-sensitive resin composition.

As regards the developing method, for example, a method of dipping the substrate in a bath filled with the developer for a fixed time (dipping method), a method of raising the developer on the substrate surface by the effect of a surface tension and keeping it still for a fixed time, thereby performing the development (puddling method), a method of spraying the developer on the substrate surface (spraying method), and a method of continuously ejecting the developer on the substrate spinning at a constant speed while scanning a developer ejecting nozzle at a constant speed (dynamic dispense method) may be applied.

After the step of performing negative development, a step of stopping the development while replacing the solvent with another solvent may be practiced.

The pattern forming method preferably includes, after the negative development, a step of rinsing the resist film by using an organic solvent-containing rinsing solution for negative development.

The rinsing solution used in the rinsing step after negative development is not particularly limited as long as it does not dissolve the resist pattern, and a solution containing a general organic solvent may be used. A rinsing solution containing at least one kind of an organic solvent selected from a hydrocarbon-based solvent, a ketone-based solvent, an ester-based solvent, an alcohol-based solvent, an amide-based solvent and an ether-based solvent, is preferably used as the rinsing solution.

Specific examples of the hydrocarbon-based solvent, ketone-based solvent, ester-based solvent, alcohol-based solvent, amide-based solvent and ether-based solvent are the same as those described above for the hydrocarbon-based solvent, ketone-based solvent, ester-based solvent, alcohol-based solvent, amide-based solvent and ether-based solvent in an organic developer.

More preferably, a step of rinsing the resist film by using a rinsing solution containing at least one kind of an organic solvent selected from a ketone-based solvent, an ester-based solvent, an alcohol-based solvent and an amide-based solvent is preformed after the negative development; still more preferably, a step of rinsing the resist film by using a rinsing solution containing an alcohol-based solvent or an ester-based solvent is performed after the negative development; yet still more preferably, a step of rinsing the resist film by using a rinsing solution containing an alcohol (preferably a monohydric alcohol) is performed after the negative development. The monohydric alcohol used in the rinsing step after the negative development includes a linear, branched or cyclic monohydric alcohol, and specifically, 1-butanol, 2-butanol, 3-methyl-1-butanol, tert-butyl alcohol, 1-pentanol, 2-pentanol, 1-hexanol, 1-heptanol, 1-octanol, 2-hexanol, 2-heptanol, 2-octanol, 3-hexanol, 3-heptanol, 3-octanol, 4-octanol, etc. may be used. Preferred are 1-hexanol, 2-hexanol, 1-pentanol, 4-methyl-2-pentanol (methyl isobutyl carbinol), and 3-methyl-1-butanol.

A plurality of these components may be mixed, or the solvent may be used by mixing it with an organic solvent other than those described above.

The water content percentage in the rinsing solution is preferably 10 mass % or less, more preferably 5 mass % or less, still more preferably 3 mass % or less. By setting the water content percentage to 10 mass % or less, good development characteristics can be obtained.

The vapor pressure at 20° C. of the rinsing solution used after the negative development is preferably from 0.05 to 5 kPa, more preferably from 0.1 to 5 kPa, and most preferably from 0.12 to 3 kPa. By setting the vapor pressure of the rinsing solution to a range of 0.05 to 5 kPa, the temperature uniformity in the wafer plane is enhanced and moreover, swelling attributable to permeation of the rinsing solution is suppressed, as a result, the dimensional uniformity in the wafer plane is improved.

The rinsing solution may also be used after adding thereto an appropriate amount of a surfactant.

In the rinsing step, the wafer subjected to negative development is rinsed using a rinsing solution containing the above-described organic solvent. The method for rinsing treatment is not particularly limited, but, for example, a method of continuously ejecting the rinsing solution on the substrate spinning at a constant speed (spin coating method), a method of dipping the substrate in a bath filled with the rinsing solution for a fixed time (dipping method), and a method of spraying the rinsing solution on the substrate surface (spraying method) can be applied. Above all, it is preferable to perform the rinsing treatment by the spin coating method and after the rinsing, remove the rinsing solution from the substrate surface by spinning the substrate at a rotational speed of 2,000 to 4,000 rpm.

In the present invention, a resist pattern is preferably formed by (v) further performing development using a positive developer.

As for the positive developer, an alkali developer is preferably used. As the alkali developer, an alkaline aqueous solution of, for example, inorganic alkalis such as sodium hydroxide, potassium hydroxide, sodium carbonate, sodium silicate, sodium metasilicate and aqueous ammonia, primary amines such as ethylamine and n-propylamine, secondary amines such as diethylamine and di-n-butylamine, tertiary amines such as triethylamine and methyldiethylamine, alcohol amines such as dimethylethanolamine and triethanolamine, quaternary ammonium salts such as tetramethylammonium hydroxide, tetraethylammonium hydroxide, tetra-n-propylammonium hydroxide, tetra-n-butylammonium hydroxide and benzyltrimethylammonium hydroxide, or cyclic amines such as pyrrole and piperidine, can be used. Among these, an aqueous solution of tetraethylammonium hydroxide is preferably used.

Furthermore, the alkali developer above may also be used after adding thereto an appropriate amount of alcohols or a surfactant.

The alkali concentration of the alkali developer is usually from 0.01 to 20 mass %.

The pH of the alkali developer is usually from 10.0 to 15.0.

The time for which the development is performed using an alkali developer is usually from 10 to 300 seconds.

The alkali concentration (and pH) of the alkali developer and the development time can be appropriately adjusted according to the pattern formed.

In the following, the protective film composition in the step (ii) is first described.

The protective film composition for use in the pattern forming method of the present invention is preferably used by dissolving a resin in a solvent so as to uniformly form the protective film composition on the resist film.

In order to form a good pattern without dissolving the resist film, the protective film composition of the present invention preferably contains a solvent incapable of dissolving the resist film, and is it more preferable to use a solvent differing in the component from the organic solvent-containing developer. In view of volatility and coatability, the boiling point of the solvent is preferably from 90 to 200° C.

In the present invention, from the standpoint of uniformly coating the protective film, the solvent is used to afford a solid content concentration of 0.01 to 20 mass %, preferably from 0.1 to 15 mass %, and most preferably from 1 to 10 mass %.

The protective film composition for use in the pattern forming method of the present invention is typically an aqueous composition, i.e., a protective film composition containing a water-soluble resin in an aqueous solution.

In the case where the protective film composition for use in the pattern forming method of the present invention is an aqueous composition, the pH thereof is preferably from 1 to 10, more preferably from 2 to 8, still more preferably from 3 to 7.

The water-soluble resin includes a natural polymer, a semisynthetic polymer, and a synthetic polymer and is preferably a synthetic polymer.

The natural polymer includes a starch (e.g., corn starch), sugars (e.g., mannan, pectin), algae (e.g., agar, alginic acid), a plant mucilage (various gums), a bacteria mucilage (e.g., dextran, pullulan), and a protein (e.g., glue, gelatin).

The semisynthetic polymer includes a cellulose-based polymer (e.g., carboxymethyl cellulose, hydroxyethyl cellulose), and a starch-based polymer (e.g., oxidized starch, modified starch).

The synthetic polymer includes sodium polyacrylate, polyacrylamide, polyvinyl alcohol, polyethyleneimine, polyethylene oxide, polyvinylpyrrolidone, etc. and is preferably polyvinyl alcohol, polyvinylpyrrolidone or polyacrylamide.

In the protective film composition for use in the pattern forming method of the present invention, the content of the water-soluble resin is preferably from 0.5 to 20 mass %, more preferably from 1 to 15 mass %, still more preferably from 2 to 10 mass %, relative to the total amount of the protective film composition.

The water-soluble resin is more preferably an amphiphatic resin, i.e., a resin capable of dissolving in water and an organic solvent. As the amphiphatic resin, any known amphiphatic resin may be employed.

It is thought that when an amphiphatic resin is used by dissolving it in the protective film composition for use in the pattern forming method of the present invention, the protective film can be separated with an organic solvent-containing developer in the development step using an organic developer, making it possible to perform the development and the separation of protective film at the same time, as a result, a step of separating a protective film formed from an aqueous protective film composition by using an aqueous solution is not required.

The protective film composition may be an organic solvent-based composition, i.e., a composition where solid contents in the later-described protective film composition are dissolved in an organic solvent.

The solvent that can be used is not particularly limited as long as it can dissolve a resin (preferably the later-described resin (X)) and does not dissolve the resist film, but an alcohol-based solvent, a fluorine-based solvent or a hydrocarbon-based solvent is preferably used, and it is more preferable to use a non-fluorinated alcohol-based solvent. By using this solvent, the non-dissolving property for the resist film is further enhanced and when the protective film composition is coated on the resist film, a protective film can be more uniformly formed without dissolving the resist film.

In view of coatability, the alcohol-based solvent is preferably a monohydric alcohol, more preferably a monohydric alcohol having a carbon number of 4 to 8. As the monohydric alcohol having a carbon number of 4 to 8, a linear, branched or cyclic alcohol may be used, but a linear or branched alcohol is preferred. As such an alcohol-based solvent, for example, 1-butanol, 2-butanol, 3-methyl-1-butanol, isobutyl alcohol, tert-butyl alcohol, 1-pentanol, 2-pentanol, 1-hexanol, 1-heptanol, 1-octanol, 2-hexanol, 2-heptanol, 2-octanol, 3-hexanol, 3-heptanol, 3-octanol, and 4-octanol can be used. Among these, preferred are 1-butanol, 1-hexanol, 1-pentanol and 3-methyl-1-butanol.

The fluorine-based solvent includes, for example, 2,2,3,3,4,4-hexafluoro-1-butanol, 2,2,3,3,4,4,5,5-octafluoro-1-pentanol, 2,2,3,3,4,4,5,5,6,6-decafluoro-1-hexanol, 2,2,3,3,4,4-hexafluoro-1,5-pentanediol, 2,2,3,3,4,4,5,5-octafluoro-1,6-hexanediol, 2,2,3,3,4,4,5,5,6,6,7,7-dodecafluoro-1,8-octanediol, 2-fluoroanisole, 2,3-difluoroanisole, perfluorohexane, perfluoroheptane, perfluoro-2-pentanone, perfluoro-2-butyltetrahydrofuran, perfluorotetrahydrofuran, perfluorotributylamine, and perfluorotetrapentylamine. Among these, a fluorinated alcohol and a fluorinated hydrocarbon-based solvent may be suitably used.

The hydrocarbon-based solvent includes an aromatic hydrocarbon-based solvent such as toluene, xylene and anisole, and an aliphatic hydrocarbon-based solvent such as n-heptane, n-nonane, n-octane, n-decane, 2-methylheptane, 3-methylheptane, 3,3-dimethylhexane and 2,3,4-trimethylpentane.

One of these solvents may be used alone, or a plurality thereof may be mixed and used.

In the case of mixing a solvent other than those recited above, the mixing ratio thereof is usually from 0 to 30 mass %, preferably from 0 to 20 mass %, more preferably from 0 to 10 mass %, relative to the total amount of solvents in the protective film composition. By mixing a solvent other than those recited above, the solubility for the resist film, the solubility of the resin in the protective film composition, the elution characteristics from the resist film, etc. can be appropriately adjusted.

The organic solvent-based composition as the protective film composition typically contains a resin.

The resin is preferably a resin (X) containing a repeating unit derived from a monomer having at least one fluorine atom and/or at least one silicon atom, more preferably a water-insoluble resin (X′) containing a repeating unit derived from a monomer containing at least one fluorine atom and/or at least one silicon atom. By containing a repeating unit derived from a monomer having at least one fluorine atom and/or at least one silicon atom, good solubility in an organic solvent-containing developer is obtained, and the effects of the present invention are sufficiently exerted.

The fluorine atom or silicon atom in the resin (X) may be present in the main chain of the resin or may be substituted on the side chain.

The resin (X) is preferably a resin having, as the fluorine atom-containing partial structure, a fluorine atom-containing alkyl group, a fluorine atom-containing cycloalkyl group or a fluorine atom-containing aryl group.

The fluorine atom-containing alkyl group (preferably having a carbon number of 1 to 10, more preferably a carbon number of 1 to 4) is a linear or branched alkyl groups with at least one hydrogen atom being substituted for by a fluorine atom and may further have another substituent.

The fluorine atom-containing cycloalkyl group is a monocyclic or polycyclic cycloalkyl group with at least one hydrogen atom being substituted for by a fluorine atom and may further have another substituent.

The fluorine atom-containing aryl group includes those where at least one hydrogen atom of an aryl group such as phenyl group and naphthyl group is substituted for by a fluorine atom, and may further have another substituent.

Specific examples of the fluorine atom-containing alkyl group, fluorine atom-containing cycloalkyl group and fluorine atom-containing aryl group are illustrated below, but the present invention is not limited thereto.

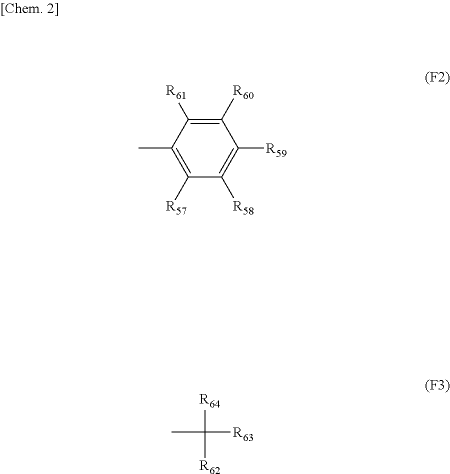

In formulae (F2) and (F3), each of R₅₇ to R₆₄ independently represents a hydrogen atom, a fluorine atom or an alkyl group, provided that out of R₅₇ to R₆₁ and out of R₆₂ to R₆₄, at least one member represents a fluorine atom or an alkyl group (preferably having a carbon number of 1 to 4) with at least one hydrogen atom being substituted for by a fluorine atom. It is preferred that all of R₅₇ to R₆₁ are a fluorine atom. Each of R₆₂ and R₆₃ is preferably an alkyl group (preferably having a carbon number of 1 to 4) with at least one hydrogen atom being substituted for by a fluorine atom, more preferably a perfluoroalkyl group having a carbon number of 1 to 4. R₆₂ and R₆₃ may combine with each other to form a ring.

Specific examples of the group represented by formula (F2) include a p-fluorophenyl group, a pentafluorophenyl group, and a 3,5-di(trifluoromethyl)phenyl group.

Specific examples of the group represented by formula (F3) include a trifluoroethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-tert-butyl group, a perfluoroisopentyl group, a perfluorooctyl group, a perfluoro(trimethyl)hexyl group, a 2,2,3,3-tetrafluorocyclobutyl group, and a perfluorocyclohexyl group. A hexafluoroisopropyl group, a heptafluoroisopropyl group, a hexafluoro(2-methyl)isopropyl group, an octafluoroisobutyl group, a nonafluoro-tert-butyl group and a perfluoroisopentyl group are preferred, and a hexafluoroisopropyl group and a heptafluoroisopropyl group are more preferred.

The resin (X) is preferably a resin having, as the silicon atom-containing partial structure, an alkylsilyl structure (preferably a trialkylsilyl group) or a cyclic siloxane structure.

The alkylsilyl structure or cyclic siloxane structure specifically includes, for example, groups represented by the following formulae (CS-1) to (CS-3):

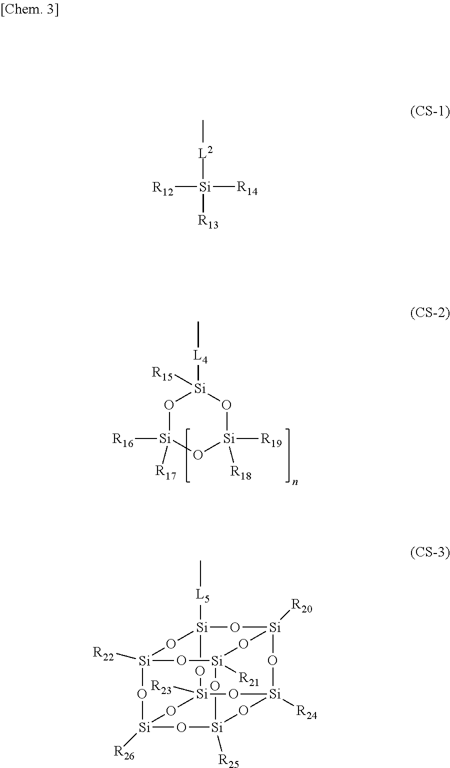

In formulae (CS-1) to (CS-3), each of R₁₂ to R₂₆ independently represents a linear or branched alkyl group (preferably having a carbon number of 1 to 20) or a cycloalkyl group (preferably having a carbon number of 3 to 20).

Each of L₃ to L₅ represents a single bond or a divalent linking group. The divalent linking group includes a single group selected from the group consisting of an alkylene group, a phenyl group, an ether group, a thioether group, a carbonyl group, an ester group, an amide group, a urethane group and a urea group, or a combination of two or more of these groups.

n represents an integer of 1 to 5.

The resin (X) includes a resin containing at least one repeating unit selected from the group consisting of repeating units represented by the following formulae (C-I) to (C-V):

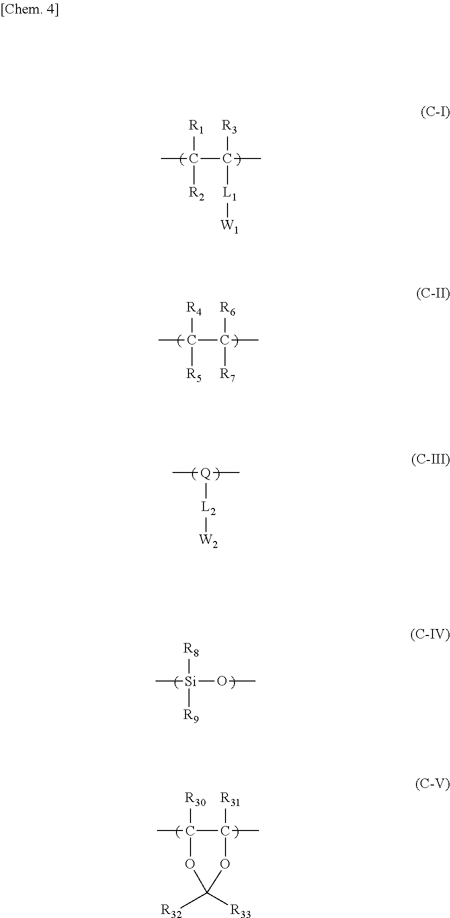

In formulae (C-I) to (C-V), each of R₁ to R₃ independently represents a hydrogen atom, a fluorine atom, a linear or branched alkyl group having a carbon number of 1 to 4, or a linear or branched, fluorinated alkyl group having a carbon number of 1 to 4.

Each of W₁ and W₂ represents an organic group having at least either a fluorine atom or a silicon atom.

Each of R₄ to R₇ independently represents a hydrogen atom, a fluorine atom, a linear or branched alkyl group having a carbon number of 1 to 4, or a linear or branched, fluorinated alkyl group having a carbon number of 1 to 4, provided that at least one of R₄ to R₇ represents a fluorine atom. R₄ and R₅, or R₆ and R₇ may form a ring.

R₈ represents a hydrogen atom, or a linear or branched alkyl group having a carbon number of 1 to 4.

R₉ represents a linear or branched alkyl group having a carbon number of 1 to 4, or a linear or branched, fluorinated alkyl group having a carbon number of 1 to 4.

Each of L₁ and L₂ represents a single bond or a divalent linking group, and the divalent linking group is the same as that of L₃ to L₅.

Q represents a monocyclic or polycyclic, cyclic aliphatic group, i.e., an atomic group containing two bonded carbon atoms (C—C) and forming an alicyclic structure.

Each of R₃₀ and R₃₁ independently represents a hydrogen atom or a fluorine atom.

Each of R₃₂ and R₃₃ independently represents an alkyl group, a cycloalkyl group, a fluorinated alkyl group or a fluorinated cycloalkyl group.

Here, the repeating unit represented by formula (C-V) has at least one fluorine atom in at least one member of R₃₀, R₃₁, R₃₂ and R₃₃.

The resin (X) preferably contains a repeating unit represented by formula (C-I), more preferably a repeating unit represented by the following formulae (C-Ia) to (C-Id):

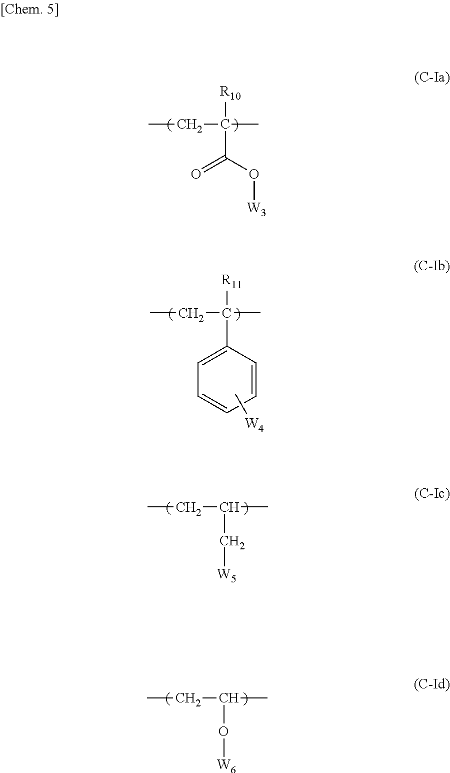

In formulae (C-Ia) to (C-Id), each of R₁₀ and R₁₁ represents a hydrogen atom, a fluorine atom, a linear or branched alkyl group having a carbon number of 1 to 4, or a linear or branched, fluorinated alkyl group having a carbon number of 1 to 4.

Each of W₃ to W₆ represents an organic group having at least either one or more fluorine atoms or one or more silicon atoms.

In the case where each of W₁ to W₆ is a fluorine atom-containing organic group, the organic group is preferably a fluorinated, linear or branched alkyl or cycloalkyl group having a carbon number of 1 to 20, or a fluorinated, linear, branched or cyclic alkyl ether group having a carbon number of 1 to 20.

The fluorinated alkyl group of W₁ to W₆ includes a trifluoroethyl group, a pentafluoropropyl group, a hexafluoroisopropyl group, a hexafluoro(2-methyl)isopropyl group, a heptafluorobutyl group, a heptafluoroisopropyl group, an octafluoroisobutyl group, a nonafluorohexyl group, a nonafluoro-tert-butyl group, a perfluoroisopentyl group, a perfluorooctyl group, a perfluoro(trimethyl)hexyl group, etc.

In the case where each of W₁ to W₆ is a silicon atom-containing organic group, the organic group preferably has an alkylsilyl structure or a cyclic siloxane structure. Specifically, this organic group includes groups represented by formulae (CS-1) to (CS-3).

Specific examples of the repeating unit represented by formula (C-I) are illustrated below. X represents a hydrogen atom, —CH₃, —F or —CF₃.

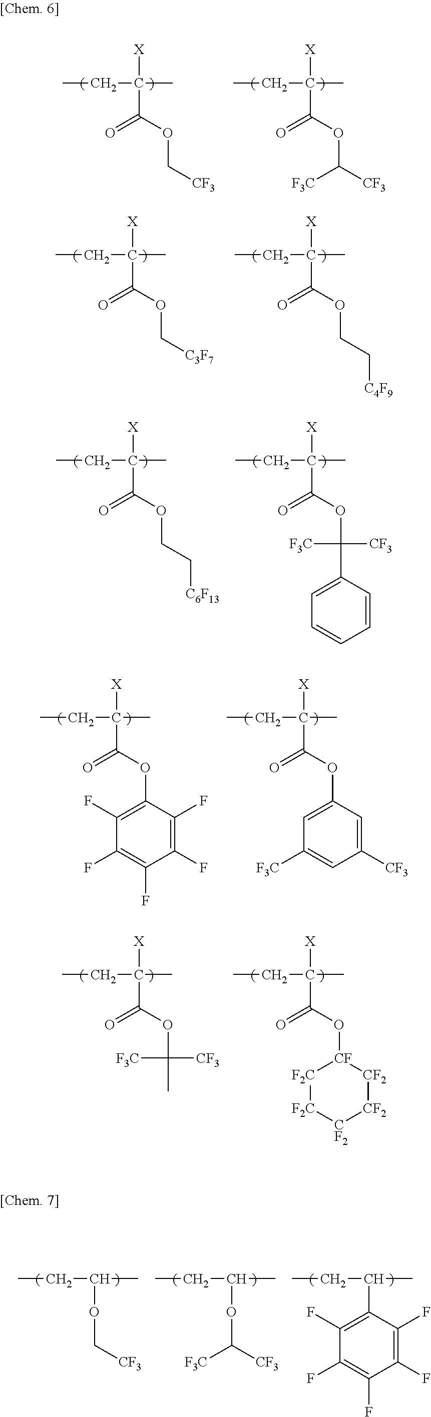

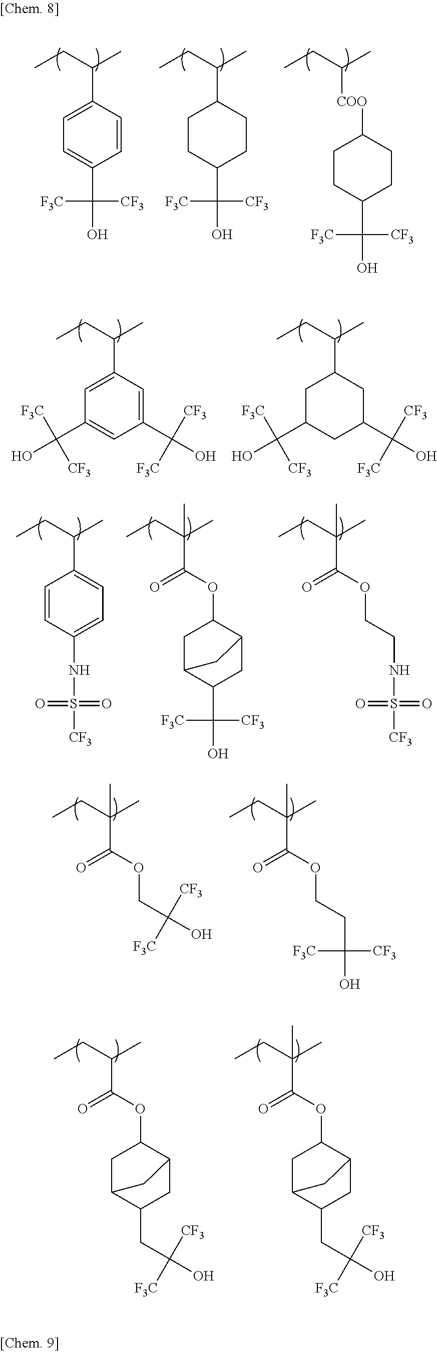

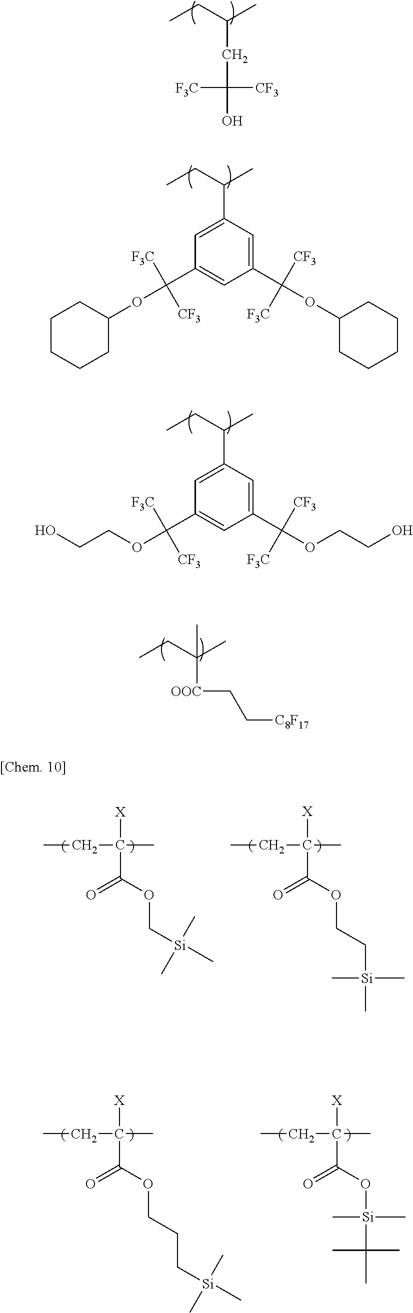

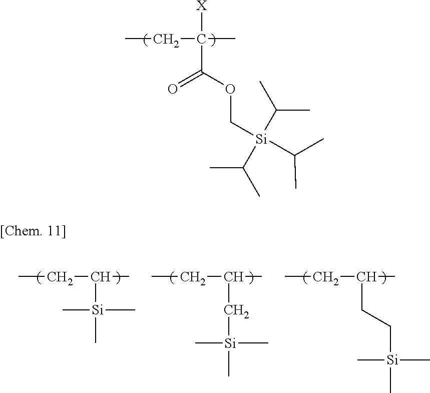

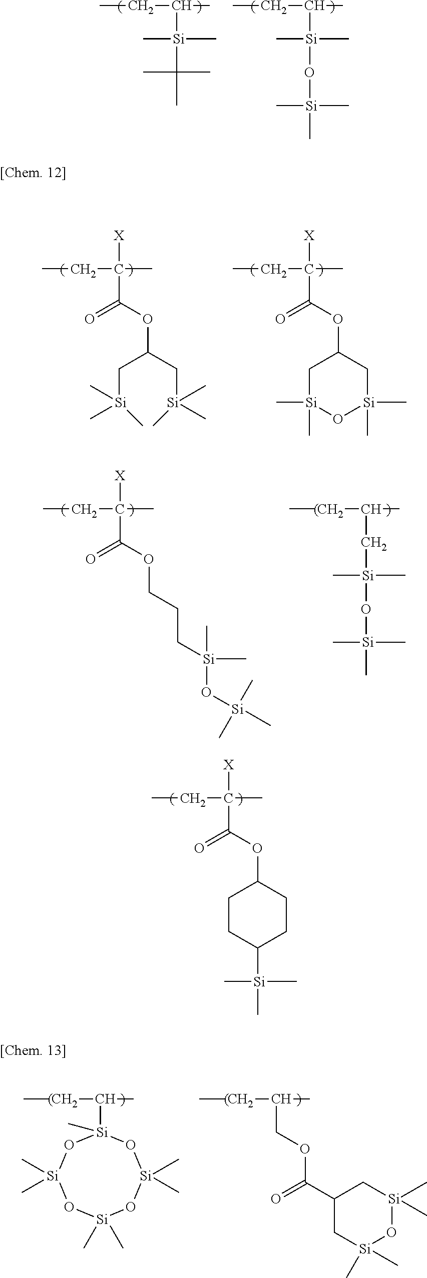

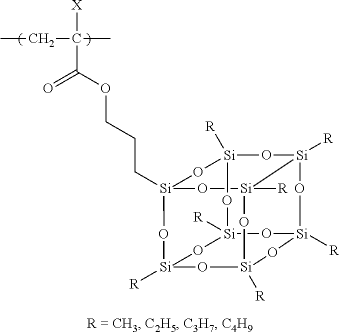

In order to adjust the solubility in an organic solvent-containing developer, the resin (X) may contain a repeating unit represented by the following formula (Ia):

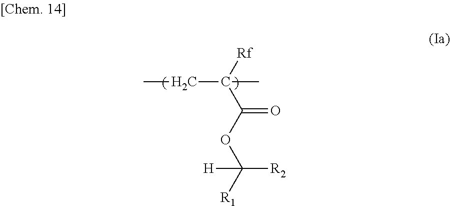

In formula (Ia), Rf represents a fluorine atom or an alkyl group with at least one hydrogen atom being substituted for by a fluorine atom.

R₁ represents an alkyl group.

R₂ represents a hydrogen atom or an alkyl group.

The alkyl group with at least one hydrogen atom being substituted for by a fluorine atom, of Rf in formula (Ia), is preferably an alkyl group having a carbon number of 1 to 3, more preferably a trifluoromethyl group.

The alkyl group of R₁ is preferably a linear or branched alkyl group having a carbon number of 3 to 10, more preferably a branched alkyl group having a carbon number of 3 to 10.

R₂ is preferably a linear or branched alkyl group having a carbon number of 1 to 10, more preferably a linear or branched alkyl group having a carbon number of 3 to 10.

Specific examples of the repeating unit represented by formula (Ia) are illustrated below, but the present invention is not limited thereto.

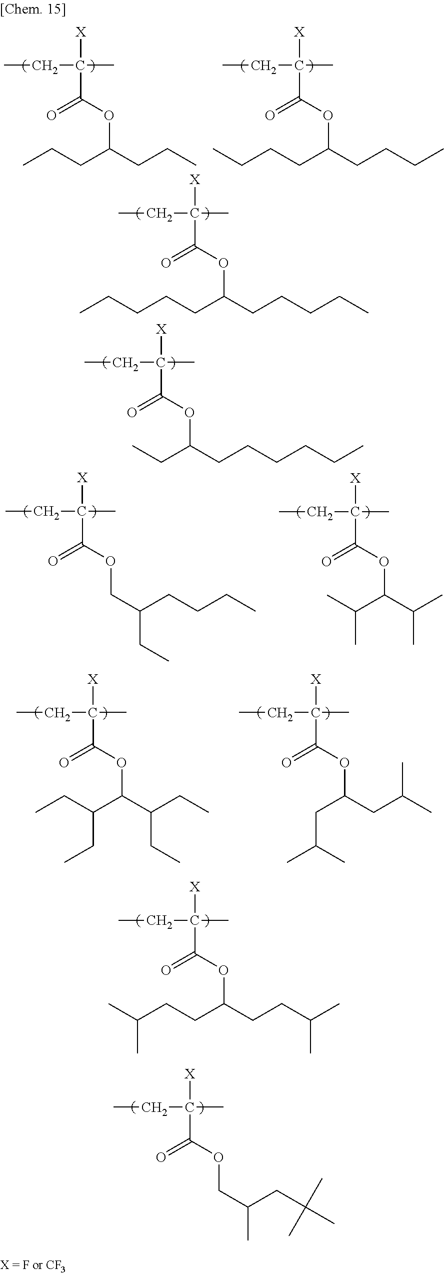

The resin (X) may further contain a repeating unit represented by the following formula (CIII):

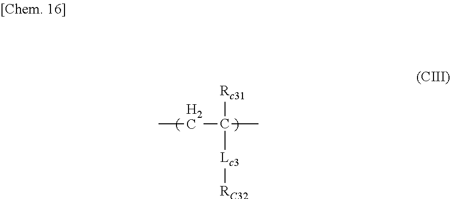

In formula (CIII), R_{c31} represents a hydrogen atom, an alkyl group (which may be substituted with a fluorine atom, etc.), a cyano group or a —CH₂—O-Rac₂ group, wherein Rac₂ represents a hydrogen atom, an alkyl group or an acyl group. R_{c31} is preferably a hydrogen atom, a methyl group, a hydroxymethyl group or a trifluoromethyl group, more preferably a hydrogen atom or a methyl group.

R_{c32} represents a group having an alkyl group, a cycloalkyl group, an alkenyl group, a cycloalkenyl group or an aryl group. These groups may be substituted with a fluorine atom, a silicon atom-containing group, etc.

L_{ca} represents a single bond or a divalent linking group.

The alkyl group of R_{c32} in formula (CIII) is preferably a linear or branched alkyl group having a carbon number of 3 to 20.

The cycloalkyl group is preferably a cycloalkyl group having a carbon number of 3 to 20.

The alkenyl group is preferably an alkenyl group having a carbon number of 3 to 20.

The cycloalkenyl group is preferably a cycloalkenyl group having a carbon number of 3 to 20.

The aryl group is preferably a phenyl group or a naphthyl group, i.e., an aryl group having a carbon number of 6 to 20, and these groups may have a substituent.

R_{c32} is preferably an unsubstituted alkyl group or an alkyl group substituted with a fluorine atom.

The divalent linking group of L_{c3} is preferably an alkylene group (preferably having a carbon number of 1 to 5), an oxy group, a phenylene group or an ester bond (a group represented by —COO—).

The resin (X) may have a lactone group, an ester group, an acid anhydride, or the same group as the acid-decomposable group in the resin (A). The resin (X) may contain a repeating unit represented by the following formula (VIII):

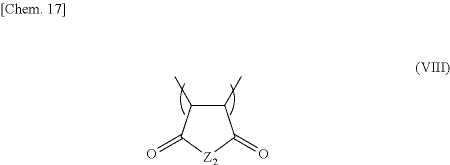

In formula (VIII), Z₂ represents —O— or —N(R₄₁)—. R₄₁ represents a hydrogen atom, a hydroxyl group, an alkyl group or —OSO₂—R₄₂. R₄₂ represents an alkyl group, a cycloalkyl group or a camphor residue. The alkyl group of R₄₁ and R₄₂ may be substituted with a halogen atom (preferably a fluorine atom), etc.

Specific examples of the repeating unit represented by formula (VIII) are illustrated below, but the present invention is not limited thereto.

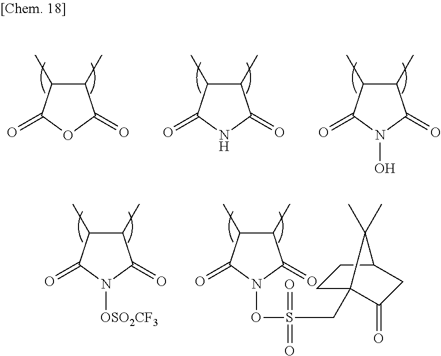

The resin (X) is preferably any one resin selected from the following resins (X-1) to (X-6).

(X-1) A resin containing (a) a repeating unit having a fluoroalkyl group (preferably having a carbon number of 1 to 4), preferably a resin containing only the repeating unit (a).

(X-2) A resin containing (b) a repeating unit having a trialkylsilyl group or a cyclic siloxane structure, preferably a resin containing only the repeating unit (b).

(X-3) A resin containing (a) a repeating unit having a fluoroalkyl group (preferably having a carbon number of 1 to 4) and (c) a repeating unit having a branched alkyl group (preferably having a carbon number of 4 to 20), a cycloalkyl group (preferably having a carbon number of 4 to 20), a branched alkenyl group (preferably having a carbon number of 4 to 20), a cycloalkenyl group (preferably having a carbon number of 4 to 20) or an aryl group (preferably having a carbon number of 4 to 20), preferably a copolymer resin of the repeating unit (a) and the repeating unit (c).

(X-4) A resin containing (b) a repeating unit having a trialkylsilyl group or a cyclic siloxane structure and (c) a repeating unit having a branched alkyl group (preferably having a carbon number of 4 to 20), a cycloalkyl group (preferably having a carbon number of 4 to 20), a branched alkenyl group (preferably having a carbon number of 4 to 20), a cycloalkenyl group (preferably having a carbon number of 4 to 20) or an aryl group (preferably having a carbon number of 4 to 20), preferably a copolymer resin of the repeating unit (b) and the repeating unit (c).

(X-5) A resin containing (a) a repeating unit having a fluoroalkyl group (preferably having a carbon number of 1 to 4) and (b) a repeating unit having a trialkylsilyl group or a cyclic siloxane structure, preferably a copolymer resin of the repeating unit (a) and the repeating unit (b).

(X-6) A resin containing (a) a repeating unit having a fluoroalkyl group (preferably having a carbon number of 1 to 4), (b) a repeating unit having a trialkylsilyl group or a cyclic siloxane structure, and (c) a repeating unit having a branched alkyl group (preferably having a carbon number of 4 to 20), a cycloalkyl group (preferably having a carbon number of 4 to 20), a branched alkenyl group (preferably having a carbon number of 4 to 20), a cycloalkenyl group (preferably having a carbon number of 4 to 20) or an aryl group (preferably having a carbon number of 4 to 20), preferably a copolymer resin of the repeating unit (a), the repeating unit (b) and the repeating unit (c).

As the repeating unit (c) having a branched alkyl group, a cycloalkyl group, a branched alkenyl group, a cycloalkenyl group or an aryl group in the resins (X-3), (X-4) and (X-6), an appropriate functional group may be introduced by taking into account the hydrophilicity/hydrophobicity, interactive property, etc.

(X-7) A resin further containing a repeating unit having an alkali-soluble group (preferably a repeating unit having an alkali-soluble group whose pKa is 4 or more), in addition to the repeating units constituting each of the resins (X-1) to (X-6).

(X-8) A resin containing only a repeating unit having an alkali-soluble group containing a fluoroalcohol group.

In the resins (X-3), (X-4), (X-6) and (X-7), the content of (a) the repeating unit having a fluoroalkyl group and/or (b) the repeating unit having a trialkylsilyl group or a cyclic siloxane structure is preferably from 10 to 99 mol %, more preferably from 20 to 80 mol %.

By having an alkali-soluble group in the resin (X-7), not only ease of separation when using an organic solvent-containing developer but also ease of separation when using another peeling liquid, for example, an alkaline aqueous solution, as the peeling liquid are enhanced.

The resin (X) is preferably a solid at ordinary temperature (25° C.), and the glass transition temperature (Tg) thereof is preferably from 50 to 200° C., more preferably from 80 to 160° C.

Being a solid at 25° C. means that the melting point is 25° C. or more.

The glass transition temperature (Tg) can be measured by scanning calorimetry (Differential Scanning calorimeter) and may be measured, for example, by analyzing the value of change in the specific volume when the sample temperature is once raised and after cooling, again raised at 5° C./min.

The resin (X) is preferably soluble in an organic solvent-containing solvent (preferably a developer containing an ester-based solvent).

In the case where the resin (X) contains a silicon atom, the silicon atom content is preferably from 2 to 50 mass %, more preferably from 2 to 30 mass %, relative to the molecular weight of the resin (X). In addition, the silicon atom-containing repeating unit preferably accounts for 10 to 100 mass %, more preferably from 20 to 100 mass %, of the resin (X).

By setting the silicon atom content and the content of the silicon atom-containing repeating unit to the ranges above, both the ease of separation of the protective film when using an organic solvent-containing developer and the immiscibility with the resist film can be enhanced.

By setting the fluorine atom content and the content of the fluorine atom-containing repeating unit to the ranges above, both the ease of separation of the protective film when using an organic solvent-containing developer and the immiscibility with the resist film can be enhanced.

In the case where the resin (X) contains a fluorine atom, the fluorine atom content is preferably from 5 to 80 mass %, more preferably from 10 to 80 mass %, relative to the molecular weight of the resin (X). In addition, the fluorine atom-containing repeating unit preferably accounts for 10 to 100 mass %, more preferably from 30 to 100 mass %, of the resin (X).

The weight average molecular weight of the resin (X) is, in terms of standard polystyrene, preferably from 1,000 to 100,000, more preferably from 1,000 to 50,000, still more preferably from 2,000 to 15,000, yet still more preferably from 3,000 to 15,000.

In the resin (X), it is of course preferred that the amount of impurities such as metal is small, but from the standpoint of reducing the elution from the protective film to the immersion liquid, the amount of residual monomers is preferably from 0 to 10 mass %, more preferably from 0 to 5 mass %, still more preferably from 0 to 1 mass %. Furthermore, the molecular weight distribution (Mw/Mn, sometimes referred to as “polydispersity”) is preferably from 1 to 5, more preferably from 1 to 3, still more preferably from 1 to 1.5.

As the resin (X), various commercially products may be used, or the resin may be synthesized by a conventional method (for example, radical polymerization). The general synthesis method includes, for example, a batch polymerization method of dissolving monomer species and an initiator in a solvent and heating the solution, thereby effecting the polymerization, and a dropping polymerization method of adding dropwise a solution containing monomer species and an initiator to a heated solvent over 1 to 10 hours. A dropping polymerization method is preferred. The reaction solvent includes, for example, ethers such as tetrahydrofuran, 1,4-dioxane and diisopropyl ether, ketones such as methyl ethyl ketone and methyl isobutyl ketone, an ester solvent such as ethyl acetate, an amide solvent such as dimethylformamide and dimethylacetamide, and the later-described solvent capable of dissolving the composition of the present invention, such as propylene glycol monomethyl ether acetate, propylene glycol monomethyl ether and cyclohexanone.

Specific examples of the resin (X) are illustrated below, but the present invention is not limited thereto.

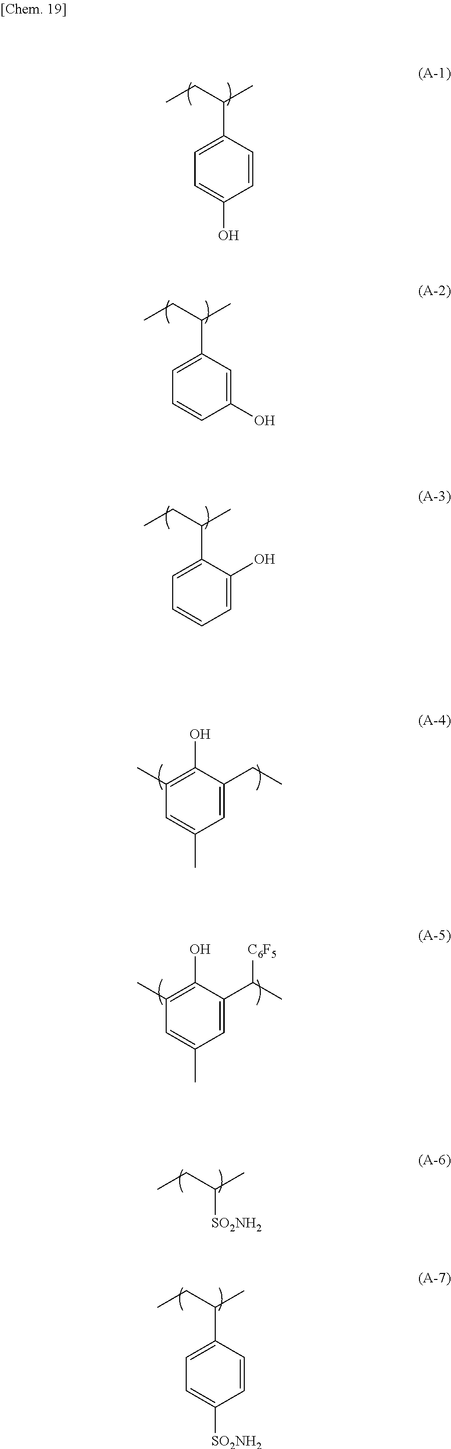

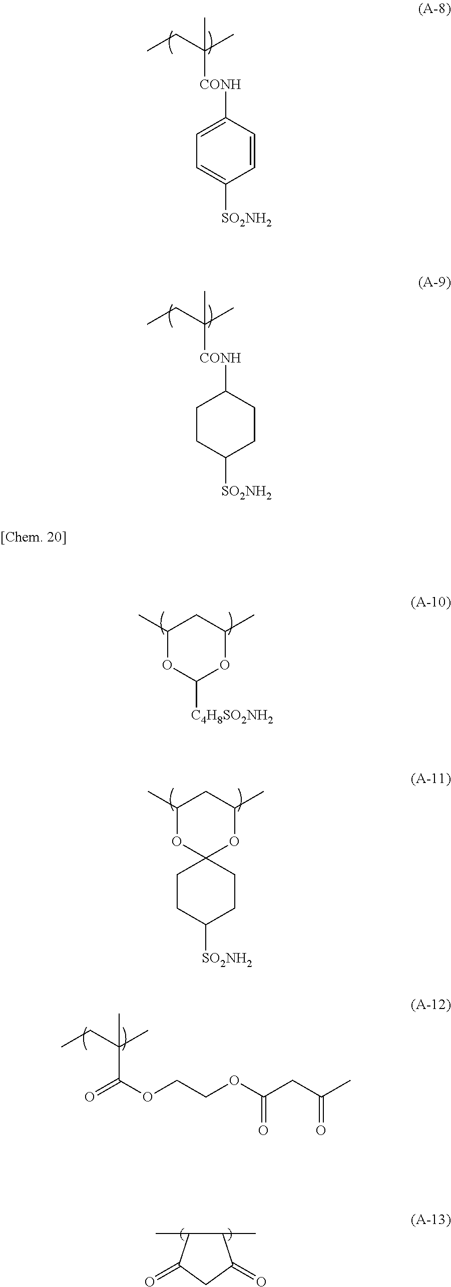

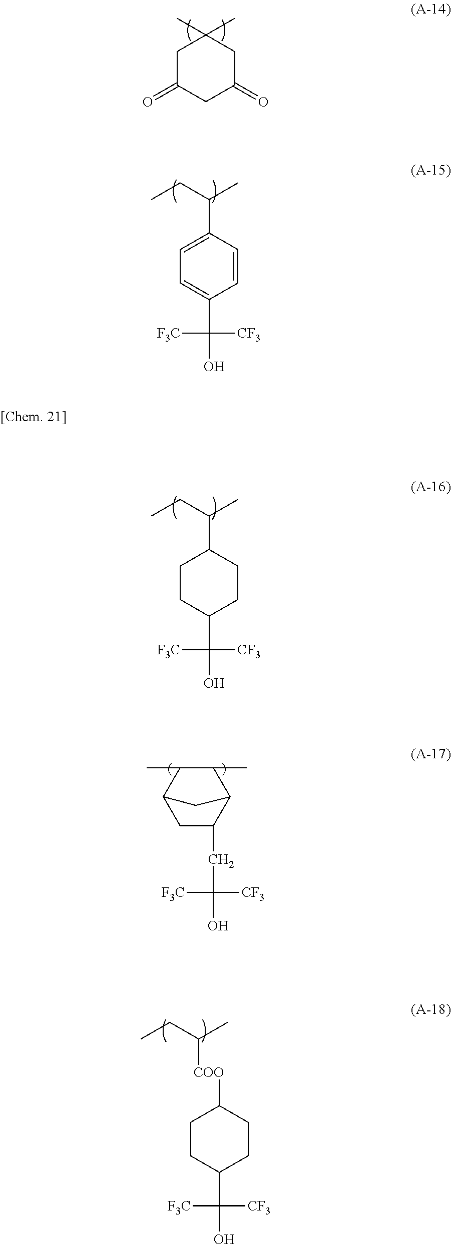

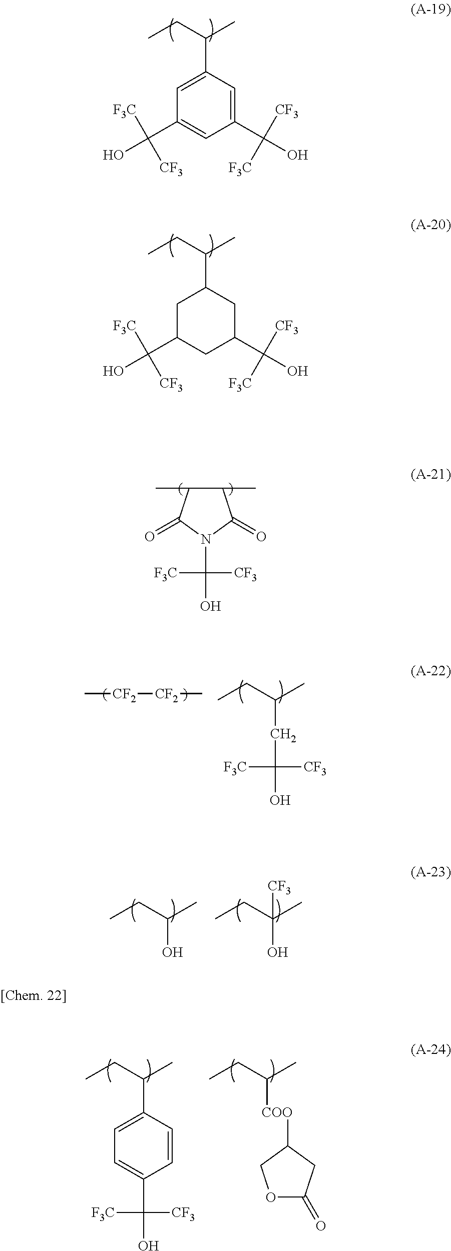

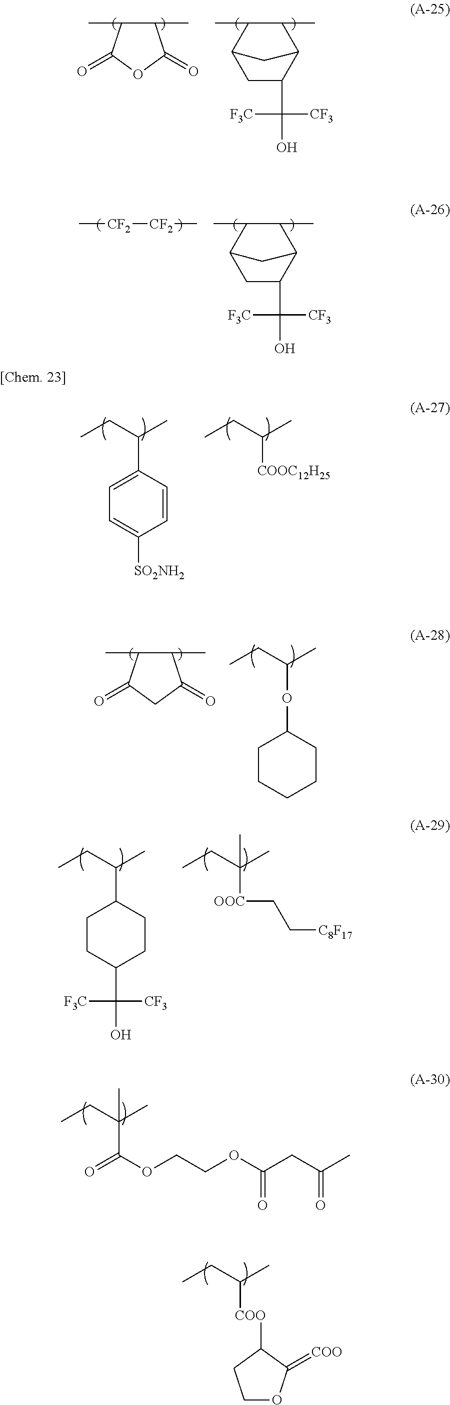

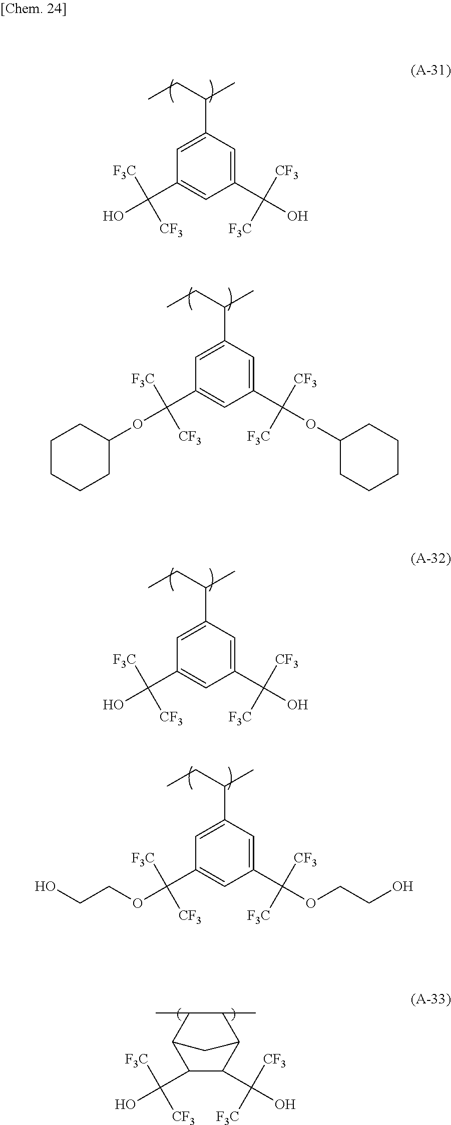

The content of the resin is preferably from 0.5 to 20 mass %, more preferably from 1 to 15 mass %, still more preferably from 2 to 10 mass %, relative to the total amount of an organic solvent-based composition as the protective film composition.

The protective film composition of the present invention preferably further contains a surfactant. The surfactant is not particularly limited as long as the protective film composition can be uniformly deposited and the surfactant can be dissolved in the solvent of the protective film composition, and any of an anionic surfactant, a cationic surfactant and a nonionic surfactant can be used.

The amount of the surfactant added is preferably from 0.001 to 20 mass %, more preferably from 0.01 to 10 mass %.

One kind of a surfactant may be used alone, or two or more kinds of surfactants may be used in combination.

As the surfactant, for example, a surfactant selected from an alkyl cationic surfactant, an amide-type quaternary cationic surfactant, an ester-type quaternary cationic surfactant, an amine oxide-based surfactant, a betaine-based surfactant, an alkoxylate-based surfactant, a fatty acid ester-based surfactant, an amide-based surfactant, an alcohol surfactant, an ethylenediamine-based surfactant, and fluorine- and/or silicon-containing surfactants (a fluorine-containing surfactant, a silicon-containing surfactant and a surfactant containing both fluorine atom and silicon atom) may be suitably used.

Specific examples of the surfactant include polyoxyethylene alkyl ethers such as polyoxyethylene lauryl ether, polyoxyethylene stearyl ether, polyoxyethylene cetyl ether and polyoxyethylene oleyl ether, polyoxyethylene alkylaryl ethers such as polyoxyethylene octylphenol ether and polyoxyethylene nonylphenol ether, polyoxyethylene-polyoxypropylene block copolymers, sorbitan fatty acid esters such as sorbitan monolaurate, sorbitan monopalmitate, sorbitan monostearate, sorbitan monooleate, sorbitan trioleate and sorbitan tristearate, surfactants such as polyoxyethylene sorbitan monolaurate, polyoxyethylene sorbitan monopalmitate, polyoxyethylene sorbitan monostearate, polyoxyethylene sorbitan trioleate and polyoxyethylene sorbitan tristearate, and commercially available surfactants recited below, and such a surfactant can be used it is.

The commercially available surfactant that can be used includes, for example, a fluorine-containing surfactant or a silicon-containing surfactant, such as EFtop EF301 and EF303 (produced by Shin-Akita Kasei K.K.); Florad FC430, 431 and 4430 (produced by Sumitomo 3M Inc.); Megaface F171, F173, F176, F189, F113, F110, F177, F120 and R08 (produced by DIC Corporation); SurfIon S-382, SC101, 102, 103, 104, 105 and 106 (produced by Asahi Glass Co., Ltd.); and Troysol S-366 (produced by Troy Chemical Industries, Inc.); GF-300 and GF-150 (produced by Toagosei Co., Ltd.); SurfIon S-393 (produced by Seimi Chemical Co., Ltd.); EFtop EF121, EF122A, EF122B, RF122C, EF125M, EF135M, EF351, 352, EF801, EF802 and EF601 (produced by JEMCO Inc.); PF636, PF656, PF6320 and PF6520 (produced by OMNOVA Solutions Inc.); and FTX-204D, 208G, 218G, 230G, 204D, 208D, 212D, 218 and 222D (produced by NEOS). In addition, Polysiloxane Polymer KP-341 (produced by Shin-Etsu Chemical Co., Ltd.) may also be used as a silicon-containing surfactant.

As the rinsing solution in the rinsing treatment performed after the positive development step, pure water is used, and the pure water may also be used after adding thereto an appropriate amount of a surfactant.

After the development treatment or rinsing treatment, a treatment of removing the developer or rinsing solution adhering on the pattern by a supercritical fluid may be performed.

Furthermore, after the rinsing treatment or the treatment with a supercritical fluid, a heating treatment for removing water remaining in the pattern may be performed.

The resist composition for negative development, which can be used in the present invention, is described below.

### <Actinic Ray-Sensitive or Radiation-Sensitive Resin Composition>

The actinic ray-sensitive or radiation-sensitive resin composition used for the formation of a resist film in the pattern forming method of the present invention is described. The actinic ray-sensitive or radiation-sensitive resin composition contains a resin capable of increasing the polarity by an action of an acid to decrease the solubility in an organic solvent-containing developer.

### [1] Resin Capable of Increasing the Polarity by an Action of an Acid to Decrease the Solubility in an Organic Solvent-Containing Developer

The resin capable of increasing the polarity by an action of an acid to decrease the solubility in an organic solvent-containing developer (hereinafter, sometimes referred to as “resin (P)”) preferably contains (A) a repeating unit capable of decomposing upon irradiation with an actinic ray or radiation to generate an acid (hereinafter, sometimes referred to as “repeating unit (A)”).

The repeating unit (A) preferably has a group capable of decomposing upon irradiation with an actinic ray or radiation to generate an acid, and the group capable of decomposing upon irradiation with an actinic ray or radiation to generate an acid includes, for example, groups represented by —COOA0 and —O—B0. Furthermore, the group containing such a group includes groups represented by —R0-COOA0 and —Ar—O—B0. Here, A0 represents a —C(R01)(R02)(R03), —Si(R01)(R02)(R03) or —C(R04)(R05-O—R06 group. B0 represents an A0 or —CO—O-A0 groups. Each of R01, R02, R03, R04 and R05, which may be the same as or different from one another, represents a hydrogen atom, an alkyl group, a cycloalkyl group, an alkenyl group or an aryl group, and R06 represents an alkyl group or an aryl group. However, at least two members out of R01 to R03 are a group except for a hydrogen atom, and out of R01 to R03 and out of R04 to R06, two groups may combine to form a ring. R0 represents a divalent aliphatic or aromatic hydrocarbon group that may have a substituent, and —Ar— represents a monocyclic or polycyclic, divalent aromatic group that may have a substituent.

The repeating unit (A) is preferably a repeating unit having at least one group where a hydrogen atom of a phenolic hydroxyl group is substituted for by a group capable of leaving by an action of an acid.

The repeating unit (A) is, for example, preferably a repeating structural unit represented by the following formula (I):

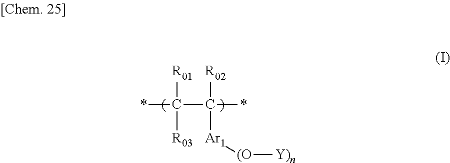

wherein each of R₀₁, R₀₂ and R₀₃ independently represents a hydrogen atom, an alkyl group, a cycloalkyl group, a halogen atom, a cyano group or an alkoxycarbonyl group, R₀₃ may represent an alkylene group and combine with Ar₁ to form a 5- or 6-membered ring,

Ar₁ represented an aromatic ring group,

each of n Ys independently represents a hydrogen atom or a group capable of leaving by an action of an acid, provided that at least one Y represents a group capable of leaving by an action of an acid, and

n represents an integer of 1 to 4.

The alkyl group of R₀₁ to R₀₃ in the formula is preferably an alkyl group having a carbon number of 20 or less, such as methyl group, ethyl group, propyl group, isopropyl group, n-butyl group, sec-butyl group, hexyl group, 2-ethylhexyl group, octyl group and dodecyl group, which may have a substituent, and more preferably an alkyl group having a carbon number of 8 or less.

As the alkyl group contained in the alkoxycarbonyl group, the same alkyl group as in R₀₁ to R₀₃ above is preferred.

The cycloalkyl group includes a cycloalkyl group that may be either monocyclic or polycyclic. The cycloalkyl group is preferably a monocyclic cycloalkyl group having a carbon number of 3 to 8, such as cyclopropyl group, cyclopentyl group and cyclohexyl group, which may have a substituent.

The halogen atom includes a fluorine atom, a chlorine atom, a bromine atom, and an iodine atom, with a fluorine atom being preferred.

In the case where R₀₃ represents an alkylene group, the alkylene group is preferably an alkylene group having a carbon number of 1 to 8, such as methylene group, ethylene group, propylene group, butylene group, hexylene group and octylene group.

The aromatic ring group of Ar₁ is preferably an aromatic ring group having a carbon number of 6 to 14 and specifically includes a benzene ring, a toluene ring, a naphthalene ring, etc.

Each of n Ys independently represents a hydrogen atom or a group capable of leaving by an action of an acid, provided that at least one member out of n members represents a group capable of leaving by an action of an acid.

The group Y capable of leaving by an action of an acid includes, for example, —C(R₃₆)(R₃₇)(R₃₈), —C(═O)—O—C(R₃₆)(R₃₇)(R₃₈), —C(R₀₁)(R₀₂)(OR₃₉), —C(R₂₁)(R₂₂)—C(═O)—O—C(R₃₆)(R₃₇)(R₃₈), and —CH(R₃₆)(Ar).

In the formulae, each of R₃₆ to R₃₉ independently represents an alkyl group, a cycloalkyl group, an aryl group, an aralkyl group or an alkenyl group. R₃₆ and R₃₇ may combine with each other to form a ring.

Each of R₂₁ and R₂₂ independently represents a hydrogen atom, an alkyl group, a cycloalkyl group, an aryl group, an aralkyl group or an alkenyl group.

Ar represents an aryl group.

Each of R₀₁ and R₀₂ independently represents a hydrogen atom, an alkyl group, a cycloalkyl group, an aryl group, an aralkyl group or an alkenyl group.

The alkyl group of R₃₆ to R₃₉, R₀₁, R₀₂, R₂₁ and R₂₂ is preferably an alkyl group having a carbon number of 1 to 8, and examples thereof include a methyl group, an ethyl group, a propyl group, an n-butyl group, a sec-butyl group, a hexyl group, and an octyl group.

The cycloalkyl group of R₃₆ to R₃₉, R₀₁ and R₀₂ may be monocyclic or polycyclic. The monocyclic cycloalkyl group is preferably a cycloalkyl group having a carbon number of 3 to 8, and examples thereof include a cyclopropyl group, a cyclobutyl group, a cyclopentyl group, a cyclohexyl group, and a cyclooctyl group. The polycyclic cycloalkyl group is preferably a cycloalkyl group having a carbon number of 6 to 20, and examples thereof include an adamantyl group, a norbornyl group, an isoboronyl group, a camphanyl group, a dicyclopentyl group, an α-pinel group, a tricyclodecanyl group, a tetracyclododecyl group, and an androstanyl group. Incidentally, a part of carbon atoms in the cycloalkyl group may be substituted with a heteroatom such as oxygen atom.

The aryl group as R₃₆ to R₃₉, R₀₁, R₀₂, R₂₁, R₂₂ and Ar is preferably an aryl group having a carbon number of 6 to 10, and examples thereof include a phenyl group, a naphthyl group, and an anthryl group.

The aralkyl group of R₃₆ to R₃₉, R₀₁, R₀₂, R₂₁ and R₂₂ is preferably an aralkyl group having a carbon number of 7 to 12, and examples thereof include a benzyl group, a phenethyl group, and a naphthylmethyl group.

The alkenyl group of R₃₆ to R₃₉, R₀₁ and R₀₂ is preferably an alkenyl group having a carbon number of 2 to 8, and examples thereof include a vinyl group, an allyl group, a butenyl group, and a cyclohexenyl group.

The ring formed by combining R₃₆ and R₃₇ with each other may be either monocyclic or polycyclic. The monocyclic ring is preferably a cycloalkane structure having a carbon number of 3 to 8, and examples thereof include a cyclopropane structure, a cyclobutane structure, a cyclopentane structure, a cyclohexane structure, a cycloheptane structure, and a cyclooctane structure. The polycyclic ring is preferably a cycloalkane structure having a carbon number of 6 to 20, and examples thereof include an adamantane structure, a norbornane structure, a dicyclopentane structure, a tricyclodecane structure, and a tetracyclododecane structure. Incidentally, a part of carbon atoms in the cycloalkane structure may be substituted with a heteroatom such as oxygen atom.

Each of the groups as R₃₆ to R₃₉, R₀₁, R₀₂, R₀₃, R₂₁, R₂₂, Ar and Ar₁ may have a substituent, and the substituent includes, for example, an alkyl group, a cycloalkyl group, an aryl group, an amino group, an amido group, a ureido group, a urethane group, a hydroxyl group, a carboxyl group, a halogen atom, an alkoxy group, a thioether group, an acyl group, an acyloxy group, an alkoxycarbonyl group, a cyano group, and a nitro group. The carbon number of the substituent is preferably 8 or less.

The group Y capable of leaving by an action of an acid is more preferably a structure represented by the following formula (II):

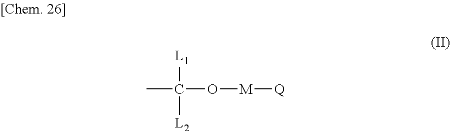

wherein each of L₁ and L₂ independently represents a hydrogen atom, an alkyl group, a cycloalkyl group, an aryl group or an aralkyl group,

M represents a single bond or a divalent linking group,

Q represents an alkyl group, a cycloalkyl group, an alicyclic group that may contain a heteroatom, an aromatic ring group that may contain a heteroatom, an amino group, an ammonium group, a mercapto group, a cyano group or an aldehyde group, and

any two members of Q, M and L₁ may combine to form a 5- or 6-membered ring.

The alkyl group as L₁ and L₂ is, for example, an alkyl group having a carbon number of 1 to 8, and specifically, preferred are a methyl group, an ethyl group, a propyl group, an n-butyl group, a sec-butyl group, a hexyl group and an octyl group.

The cycloalkyl group as L₁ and L₂ is, for example, a cycloalkyl group having a carbon number of 3 to 15, and specifically, preferred are a cyclopentyl group, a cyclohexyl group, a norbornyl group and an adamantyl group.

The aryl group as L₁ and L₂ is, for example, an aryl group having a carbon number of 6 to 15, and specifically, preferred are a phenyl group, a tolyl group, a naphthyl group, an anthryl group, etc.

The aralkyl group as L₁ and L₂ is, for example, an aralkyl group having a carbon number of 6 to 20 and includes a benzyl group, a phenethyl group, etc.

The divalent linking group as M is, for example, an alkylene group (e.g., methylene, ethylene, propylene, butylene, hexylene, octylene), a cycloalkylene group (e.g., cyclopentylene, cyclohexylene), an alkenylene group (e.g., ethylene, propenylene, butenylene), an arylene group (e.g., phenylene, tolylene, naphthylene), —S—, —O—, —CO—, SO₂, N(R0)-, or a divalent linking group formed by combining a plurality of these members. R0 is a hydrogen atom or an alkyl group (for example, an alkyl group having a carbon number of 1 to 8, and specifically, a methyl group, an ethyl group, a propyl group, an n-butyl group, a sec-butyl group, a hexyl group, an octyl group, etc.).

The alkyl group and cycloalkyl group as Q are the same as respective groups of L1 and L2 above.

The alicyclic group and aromatic ring group in the alicyclic group that may contain a heteroatom and the aromatic group that may contain a heteroatom, as Q, include, for example, the above-described cycloalkyl group and aryl group as L1 and L2 and preferably have a carbon number of 3 to 15.

The heteroatom-containing alicyclic group and the heteroatom-containing aromatic ring group include, for example, a group having a heterocyclic structure such as thiirane, cyclothiolane, thiophene, furan, pyrrole, benzothiophene, benzofuran, benzopyrrole, triazine, imidazole, benzimidazole, triazole, thiadiazole, thiazole and pyrrolidone, but the groups are not limited thereto as long as the ring is a structure generally called a heterocyclic ring (a ring formed of carbon and a heteroatom or a ring formed of a heteroatom).

The 5- or 6-membered ring that may be formed by combining any two members of Q, M and L₁ includes, for example, a case where any two members of Q, M and L₁ combine to form, for example, a propylene group or a butylene group and thereby form a 5- or 6-membered ring structure containing an oxygen atom.

Each of the groups represented by L₁, L₂, M and Q in formula (II) may also have a substituent, and this substituent includes, for example, those recited above as the substituent that may be substituted on R₃₆ to R₃₉, R₀₁, R₀₂, R₀₃, Ar and Ar₁. The carbon number of the substituent is preferably 8 or less.

The group represented by -M-Q is preferably a group composed of 1 to 30 carbons, more preferably a group composed of 5 to 20 carbons.

Specific examples of the repeating unit represented by formula (I) are illustrated below, but the present invention is not limited thereto.

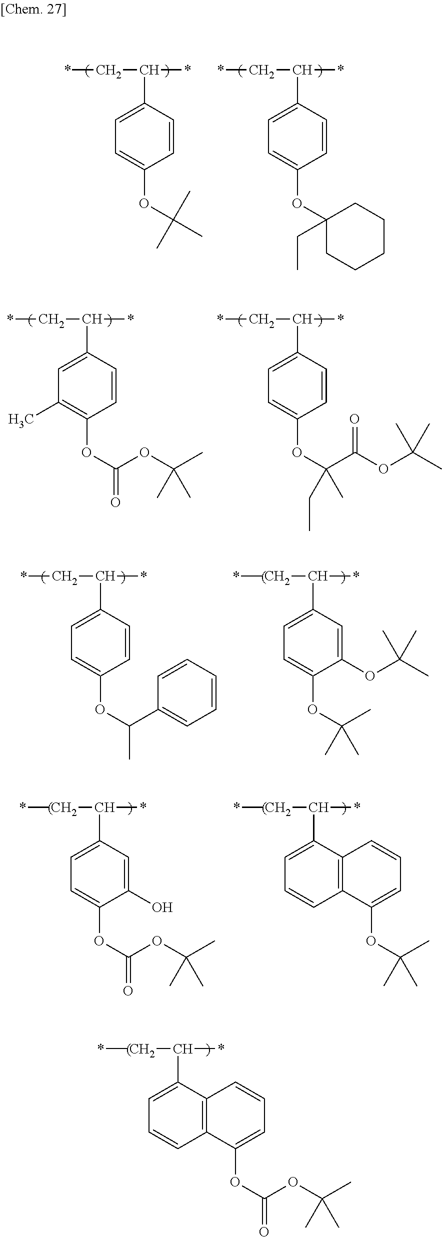

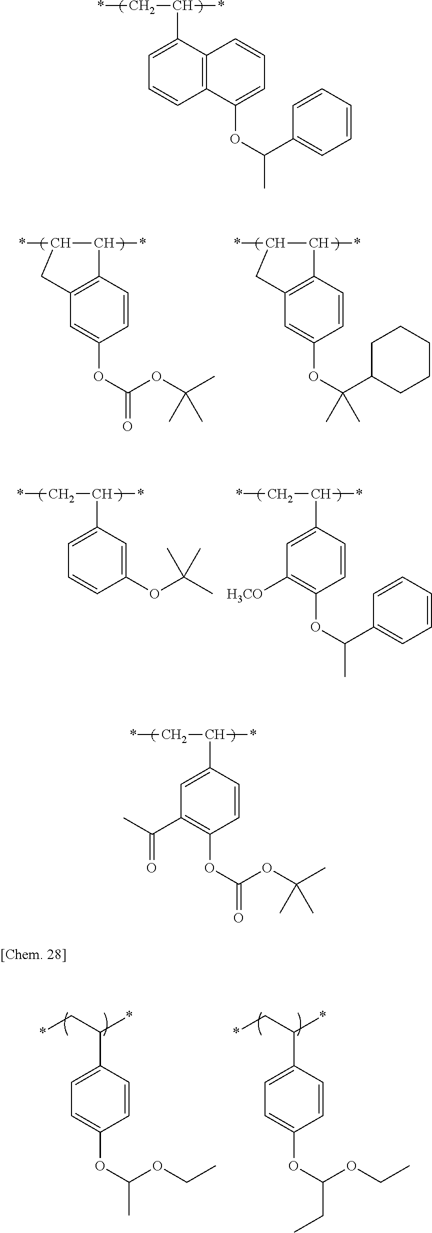

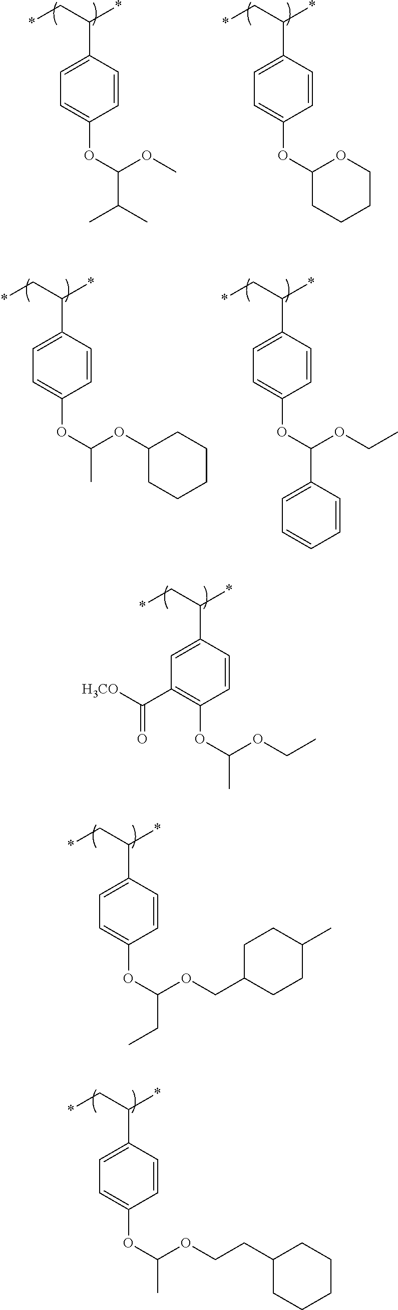

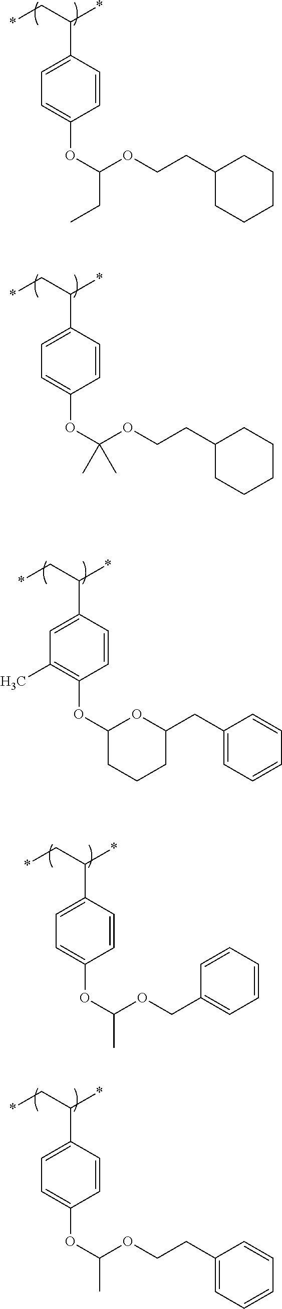

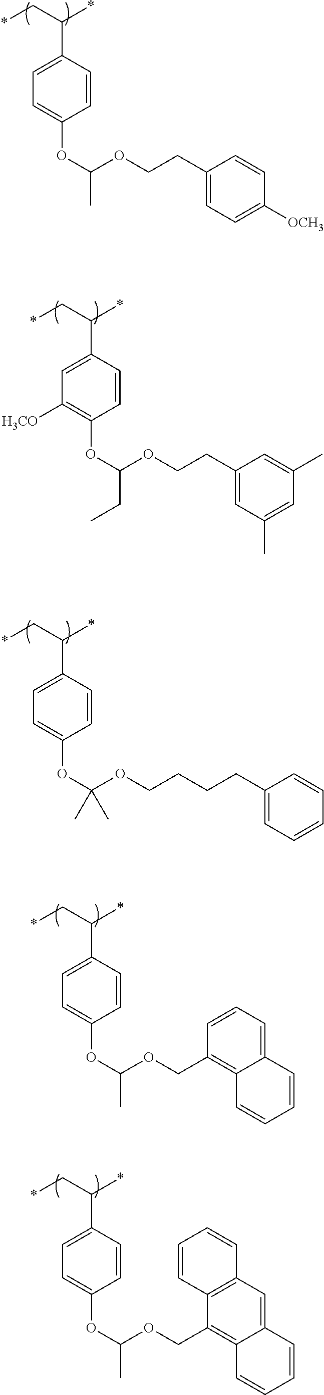

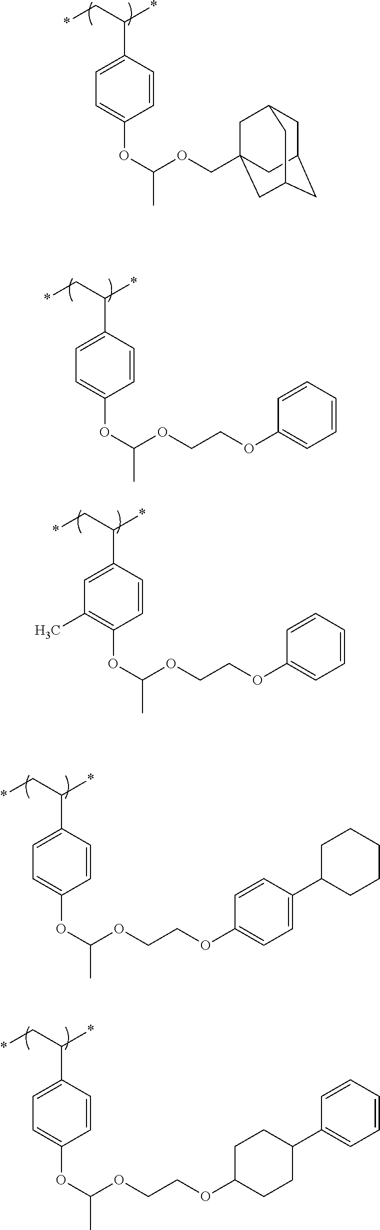

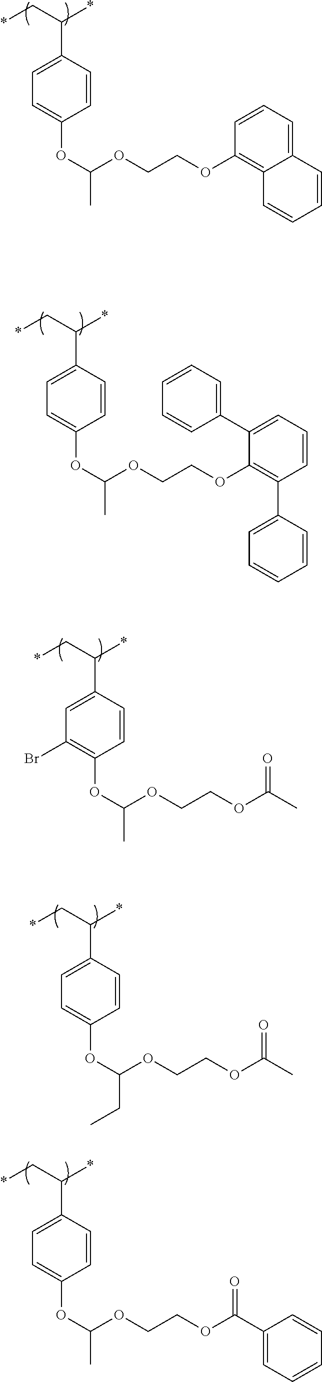

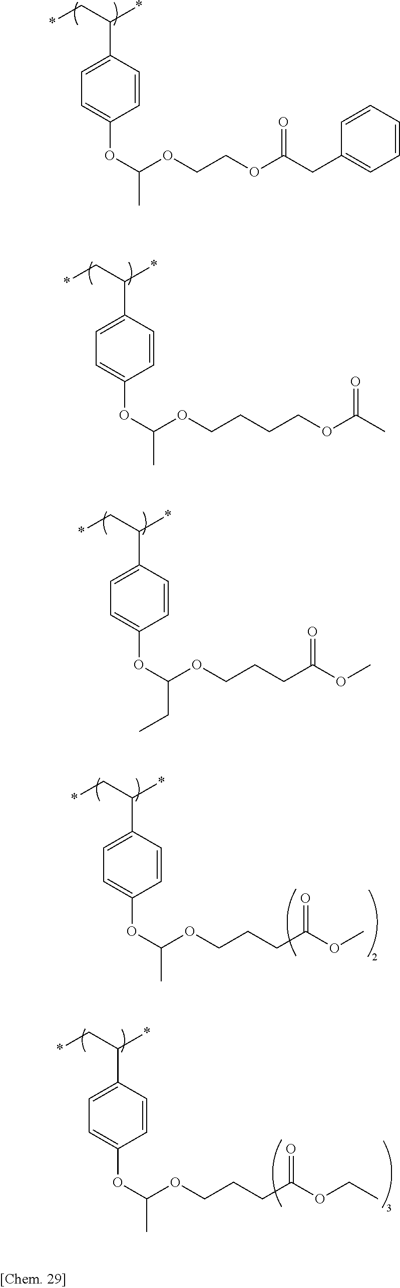

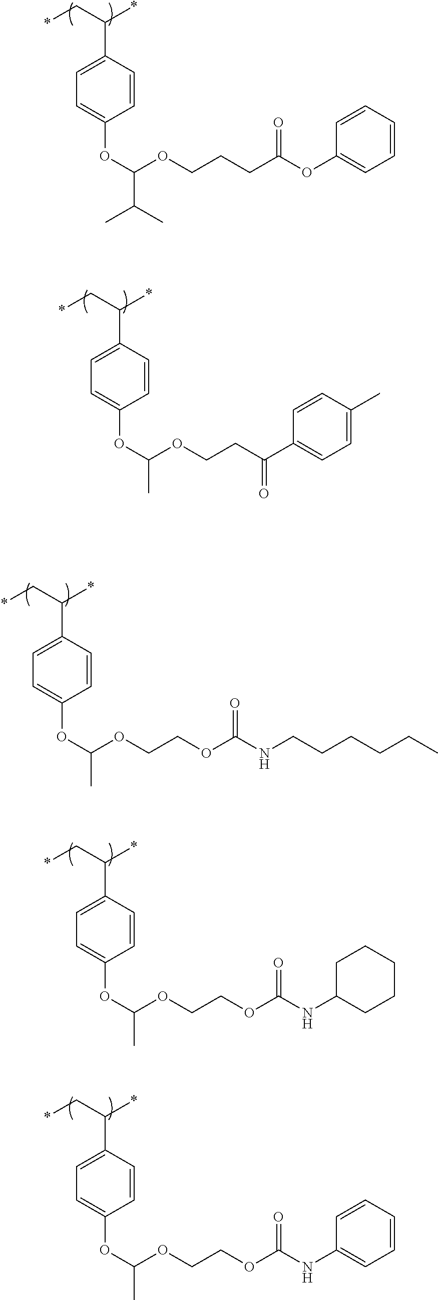

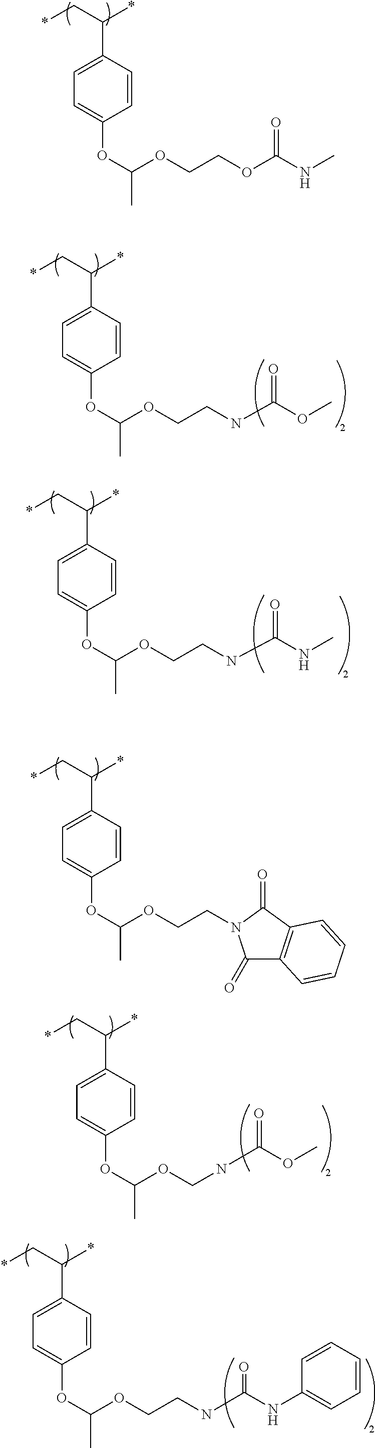

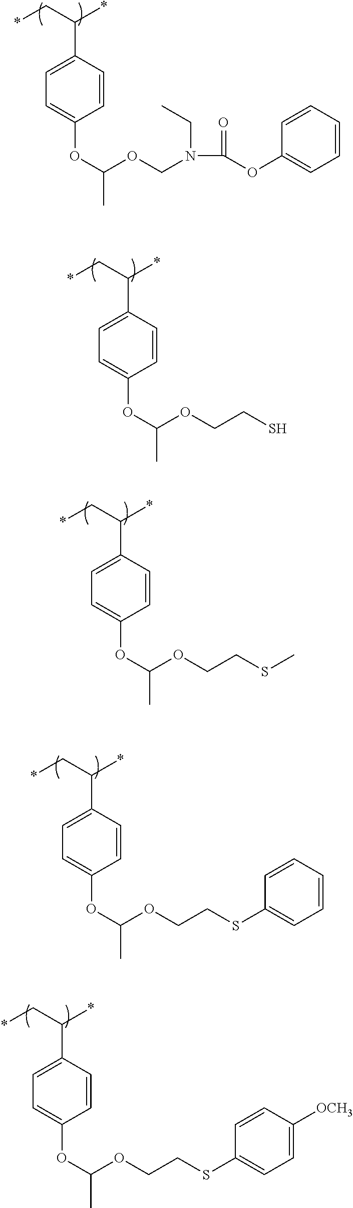

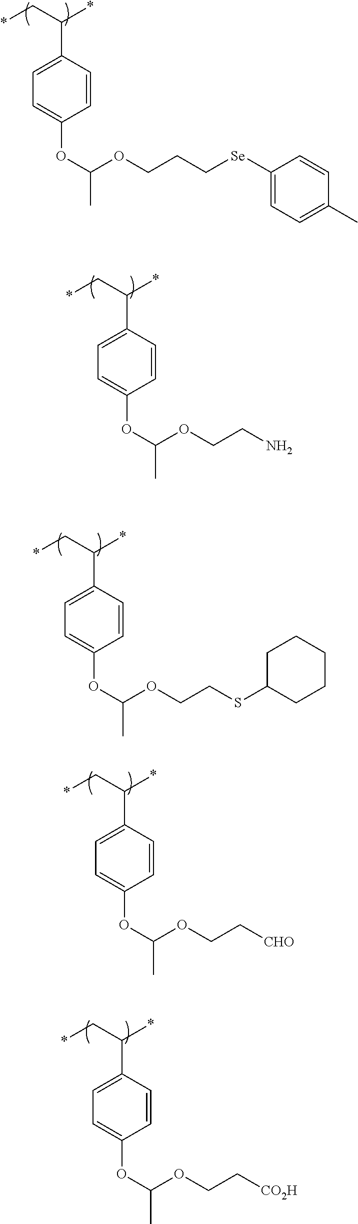

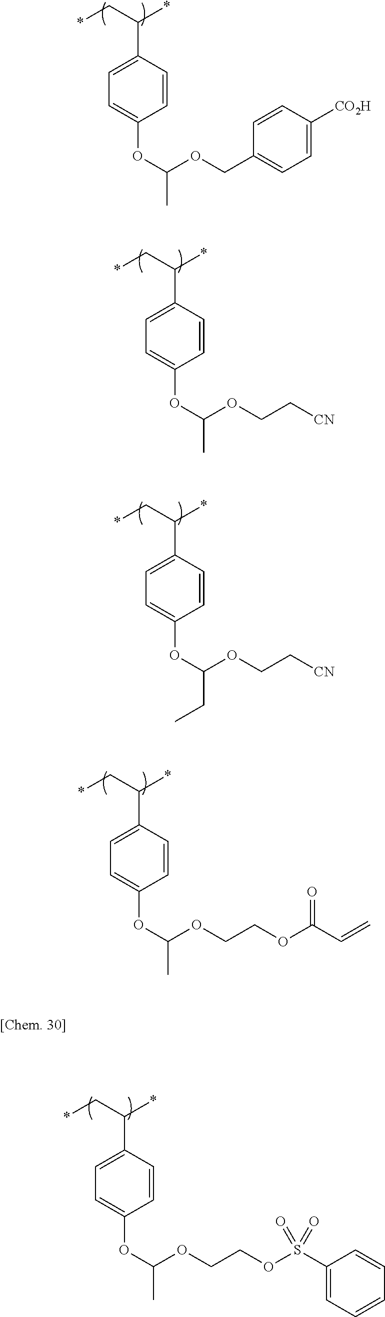

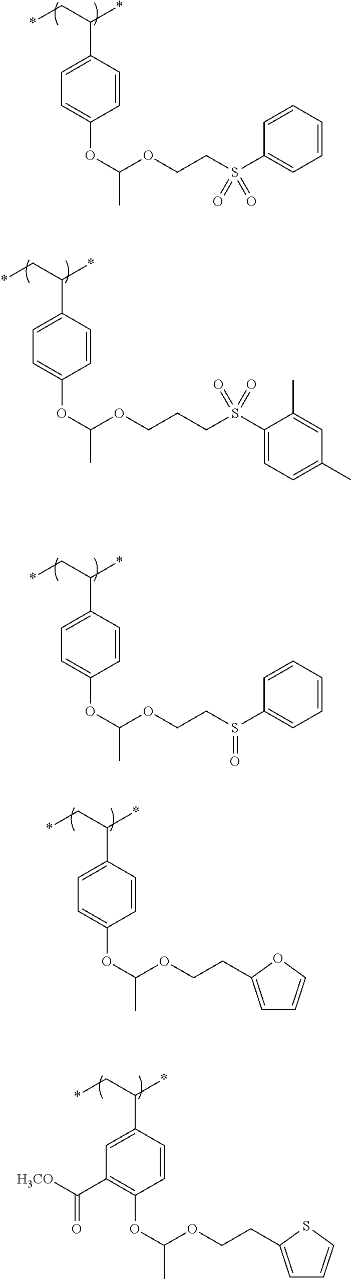

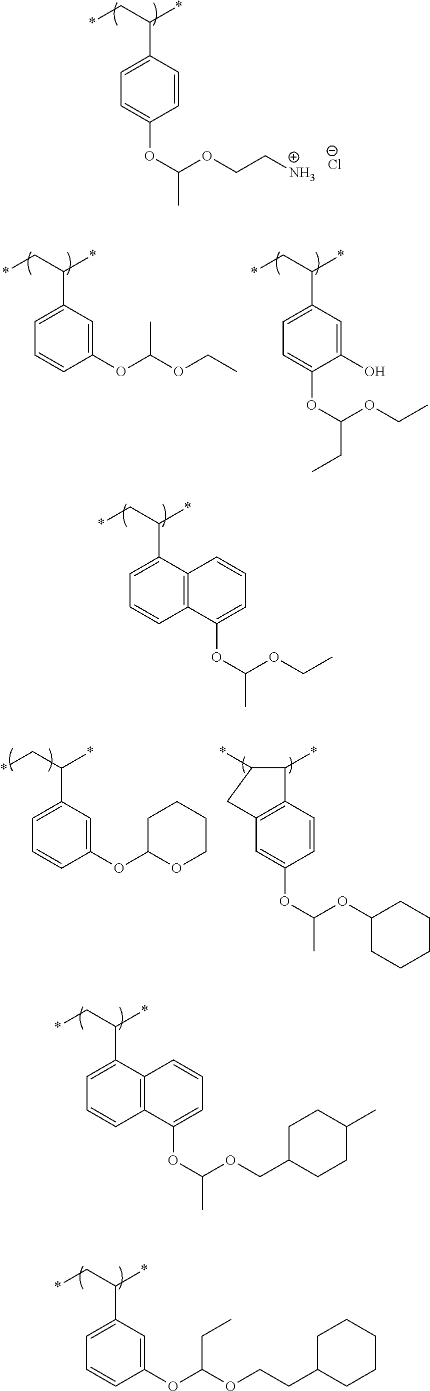

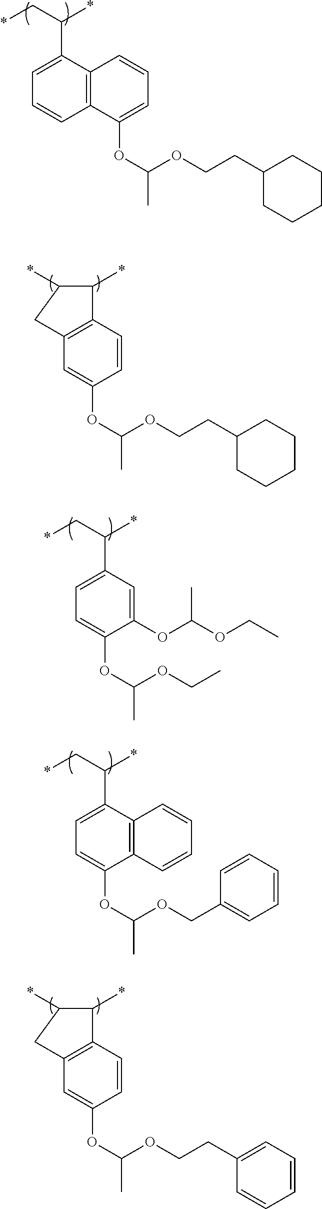

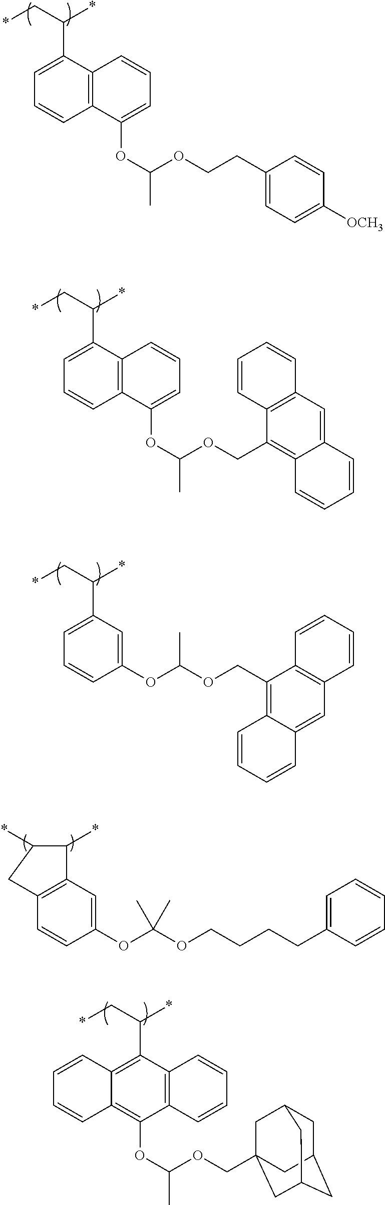

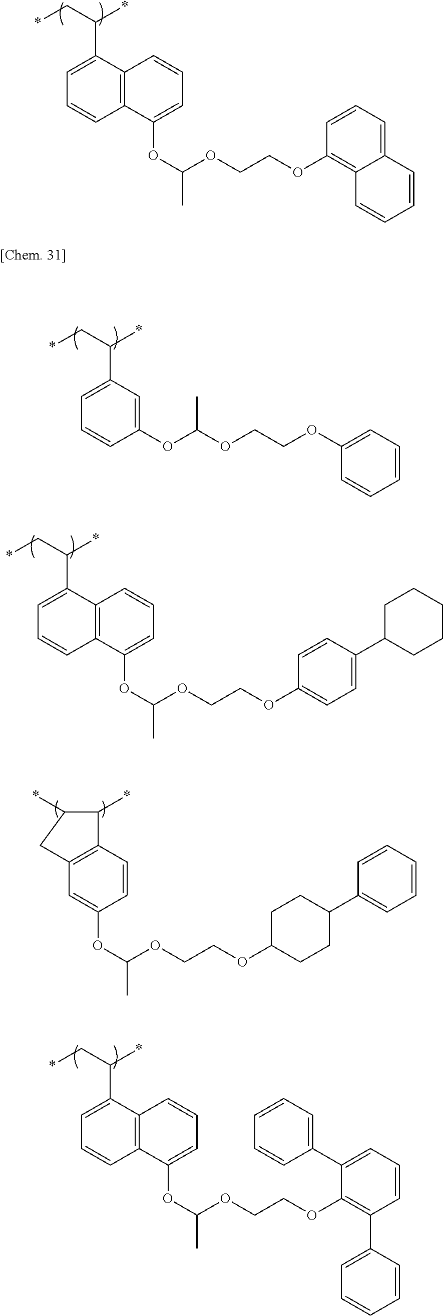

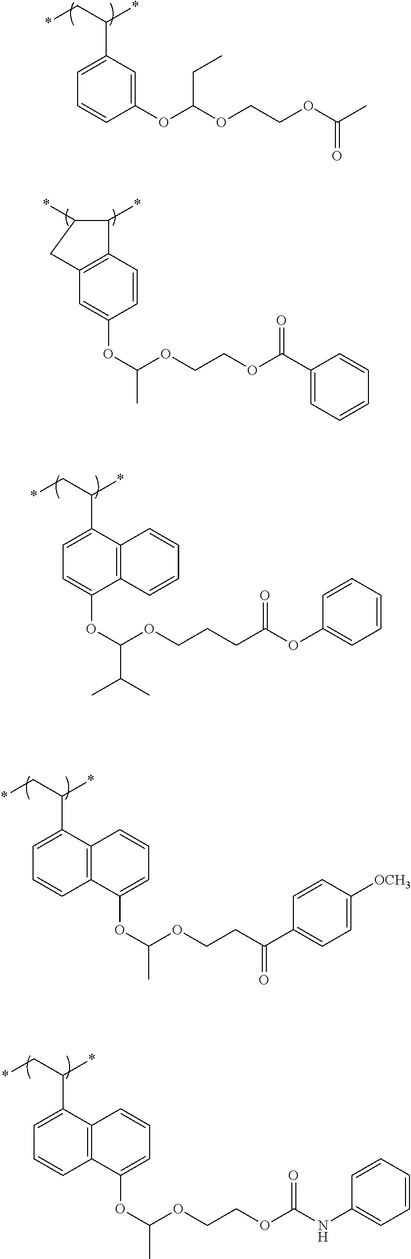

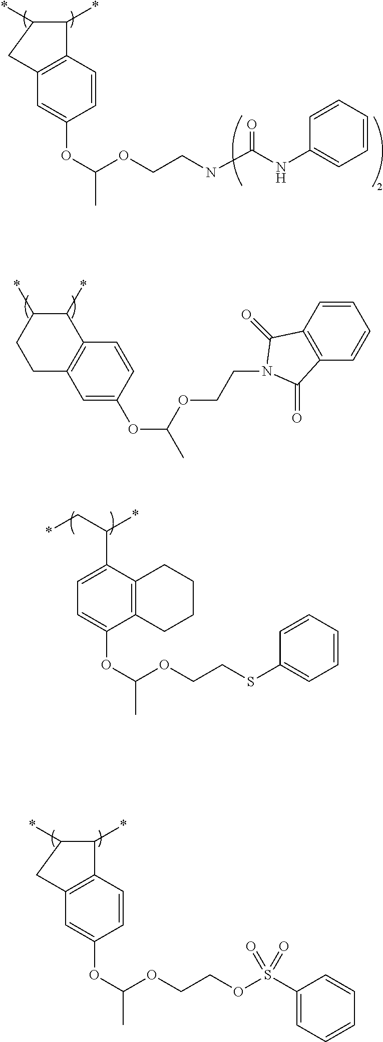

The content of the repeating unit (A) in the resin (P) of the present invention is preferably from 3 to 90 mol %, preferably from 5 to 80 mol %, still more preferably from 7 to 70 mol %, relative to all repeating units.

The ratio (number of moles of A/number of moles of B) between the repeating unit (A) and the repeating unit (A) in the resin (P) is preferably from 0.04 to 1.0, more preferably from 0.05 to 0.9, still more preferably from 0.06 to 0.8.

### (3) Repeating Unit Represented by the Following Formula (VI)

The resin (P) for use in the present invention preferably further contains a repeating unit represented by the following formula (VI) (hereinafter, sometimes referred to as “repeating unit (B)”):

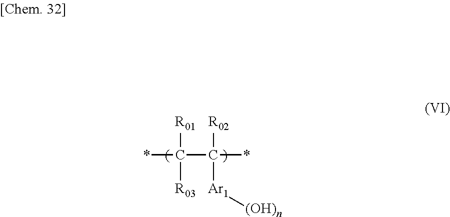

wherein each of R₀₁, R₀₂ and R₀₃ independently represents a hydrogen atom, an alkyl group, a cycloalkyl group, a halogen atom, a cyano group or an alkoxycarbonyl group, R₀₃ may represent an alkylene group and combine with Ar₁ to form a 5- or 6-membered ring,

Ar₁ represented an aromatic ring group, and

n represents an integer of 1 to 4.

Specific examples of R₀₁, R₀₂, R₀₃ and Ar₁ in formula (VI) are the same as those of R₀₁, R₀₂, R₀₃ and Ar₁ in formula (I).

Specific examples of the repeating unit represented by formula (VI) are illustrated below, but the present invention is not limited thereto.

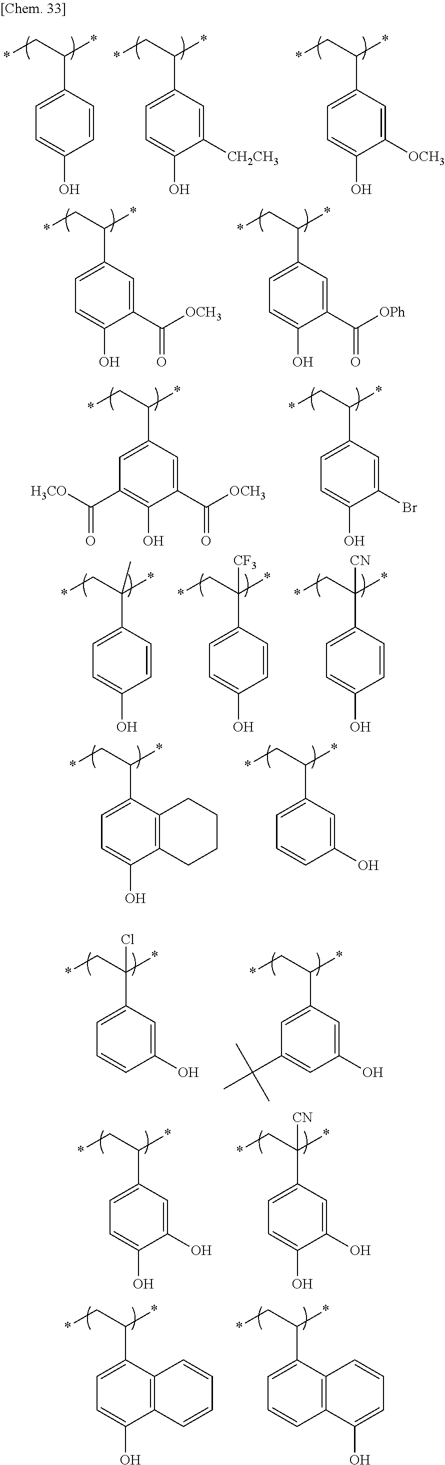

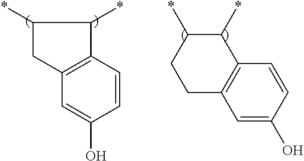

The content of the repeating unit (B) in the resin for use in the present invention is preferably from 3 to 90 mol %, more preferably from 5 to 80 mol %, still more preferably from 7 to 70 mol %, relative to all repeating units.

(4) Form, Polymerization Method, Molecular Weight, Etc. Of Resin (P) of the Present Invention

The form of the resin (P) may be any form of a random type, a block type, a comb type and a star type.

The resin (P) according to the present invention containing the repeating unit (A), the resin (P) according to the present invention containing the repeating units (A) and (B), or the resin (P) according to the present invention containing the repeating units (A), (B) and (C) can be synthesized, for example, by radical, cationic or anionic polymerization of unsaturated monomers corresponding to respective structures. In addition, the target resin can also be obtained by polymerizing unsaturated monomers corresponding to precursors of respective structures and then performing a polymer reaction.

The resin (P) according to the present invention preferably contains from 0.5 to 80 mol % of the repeating unit (A), from 3 to 90 mol % of the repeating unit (A), from 3 to 90 mol % of the repeating unit (B).

The molecular weight of the resin (P) according to the present invention is not particularly limited, but the weight average molecular weight is preferably from 1,000 to 100,000, more preferably from 1,500 to 70,000, still more preferably from 2,000 to 50,000. Here, the weight average molecular weight of the resin indicates a molecular weight in terms of polystyrene as measured by GPC (carrier: THF or N-methyl-2-pyrrolidone (NMP)).

The polydispersity (Mw/Mn) is preferably from 1.00 to 5.00, more preferably from 1.03 to 3.50, still more preferably from 1.05 to 2.50.

For the purpose of enhancing the performance of the resin according to the present invention, the resin may further contain a repeating unit derived from another polymerizable monomer as long as the dry etching resistance is not significantly impaired.

In the resin, the content of the repeating unit derived from another polymerizable monomer is generally 50 mol % or less, preferably 30 mol % or less, relative to all repeating units. The another polymerizable monomer that can be used includes the following. For example, the monomer is a compound having one addition-polymerizable unsaturated bond, selected from (meth)acrylic acid esters, (meth)acrylamides, an allyl compound, vinyl ethers, vinyl esters, styrenes, and crotonic acid esters.

Specifically, the (meth)acrylic acid esters include, for example, methyl (meth)acrylate, ethyl (meth)acrylate, propyl (meth)acrylate, tert-butyl (meth)acrylate, amyl (meth)acrylate, cyclohexyl (meth)acrylate, ethylhexyl (meth)acrylate, octyl (meth)acrylate, tert-octyl (meth)acrylate, 2-chloroethyl (meth)acrylate, 2-hydroxyethyl (meth)acrylate, glycidyl (meth)acrylate, benzyl (meth)acrylate, and phenyl (meth)acrylate.

The (meth)acrylamides include, for example, (meth)acrylamide, N-alkyl(meth)acrylamide (the alkyl group includes an alkyl group having a carbon number of 1 to 10, e.g., methyl, ethyl, propyl, butyl, tert-butyl, heptyl, octyl, cyclohexyl, benzyl, hydroxyethyl, benzyl), N-aryl(meth)acrylamide (the aryl group includes, for example, a phenyl group, a tolyl group, a nitrophenyl group, a naphthyl group, a cyanophenyl group, a hydroxyphenyl group, and a carboxyphenyl group), N,N-dialkyl(meth)acrylamide (the alkyl group includes an alkyl group having a carbon number of 1 to 10, e.g., methyl, ethyl, butyl, isobutyl, ethylhexyl, cyclohexyl), N,N-aryl(meth)acrylamide (the aryl group includes, for example, a phenyl group), N-methyl-N-phenylacrylamide, N-hydroxyethyl-N-methylacrylamide, and N-2-acetamidoethyl-N-acetylacrylamide.

The allyl compound includes, for example, allyl esters (e.g., allyl acetate, allyl caproate, allyl caprylate, allyl laurate, allyl palmitate, allyl stearate, allyl benzoate, allyl acetoacetate, allyl lactate), and allyloxyethanol.

The vinyl ethers include, for example, an alkyl vinyl ether (e.g., hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethylene glycol vinyl ether, dimethylaminoethyl vinyl ether, diethylaminoethyl vinyl ether, butylaminoethyl vinyl ether, benzyl vinyl ether, tetrahydrofurfuryl vinyl ether), and a vinyl aryl ether (e.g., vinyl phenyl ether, vinyl tolyl ether, vinyl chlorophenyl ether, vinyl-2,4-dichlorophenyl ether, vinyl naphthyl ether, vinyl anthranyl ether).

The vinyl esters include, for example, vinyl butyrate, vinyl isobutyrate, vinyl trimethylacetate, vinyl diethylacetate, vinyl valate, vinyl caproate, vinyl chloroacetate, vinyl dichloroacetate, vinyl methoxyacetate, vinyl butoxyacetate, vinyl phenylacetate, vinyl acetoacetate, vinyl lactate, vinyl β-phenylbutyrate, vinyl cyclohexylcarboxylate, vinyl benzoate, vinyl salicylate, vinyl chlorobenzoate, vinyl tetrachlorobenzoate, and vinyl naphthoate.

The styrenes include, for example, styrene, an alkylstyrene (e.g., methylstyrene, dimethylstyrene, trimethylstyrene, ethylstyrene, diethylstyrene, isopropylstyrene, butylstyrene, hexylstyrene, cyclohexylstyrene, decylstyrene, benzylstyrene, chloromethylstyrene, trifluoromethylstyrene, ethoxymethylstyrene, acetoxymethylstyrene), an alkoxystyrene (e.g., methoxystyrene, 4-methoxy-3-methylstyrene, dimethoxystyrene), an alkylcarbonyloxystyrene (e.g., 4-acetoxystyrene, 4-cyclohexylcarbonyloxystyrene), an arylcarbonyloxystyrene (e.g., 4-phenylcarbonyloxystyrene), a halogen styrene (e.g., chlorostyrene, dichlorostyrene, trichlorostyrene, tetrachlorostyrene, pentachlorostyrene, bromostyrene, dibromostyrene, iodostyrene, fluorostyrene, trifluorostyrene, 2-bromo-4-trifluoromethylstyrene, 4-fluoro-3-trifluoromethylstyrene), cyanostyrene, and carboxystyrene.

The crotonic acid esters include, for example, an alkyl crotonate (e.g., butyl crotonate, hexyl crotonate, glycerin monocrotonate).

The dialkyl itaconates include, for example, dimethyl itaconate, diethyl itaconate, and dibutyl itaconate.

The dialkyl esters of maleic acid or fumaric acid include, for example, dimethyl maleate and dibutyl fumarate. Other examples include maleic anhydride, maleimide, acrylonitrile, methacrylonitrile, and maleylonitrile. In addition, an addition-polymerizable unsaturated compound generally copolymerizable with the repeating unit according to the present invention may be used without any particular limitation.

It is also preferred that the resin (P) for use in the present invention further contains a repeating unit having a monocyclic or polycyclic, alicyclic hydrocarbon structure (hereinafter, sometimes referred to as “alicyclic hydrocarbon-based acid-decomposable repeating unit”).

The alkali-soluble group contained in the alicyclic hydrocarbon-based acid-decomposable repeating unit includes, for example, a group having a phenolic hydroxyl group, a carboxylic acid group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, or a tris(alkylsulfonyl)methylene group.

Preferable alkali-soluble groups include a carboxylic acid group, a fluorinated alcohol group (preferably hexafluoroisopropanol), and a sulfonic acid group.

The group preferred as the group capable of decomposing by an action of an acid (acid-decomposable group) is a group where a hydrogen atom of the alkali-soluble group above is substituted for by a group capable of leaving by the action of an acid.

The group capable of leaving by an action of an acid includes, for example, —C(R₃₆)(R₃₇)(R₃₈), —C(R₃₆)(R₃₇)(OR₃₉), and —C(R₀₁)(R₀₂)(OR₃₉).

In the formulae, each of R₃₆ to R₃₉ independently represents an alkyl group, a cycloalkyl group, an aryl group, an aralkyl group or an alkenyl group. R₃₆ and R₃₇ may combine with each other to form a ring.

Each of R₀₁ and R₀₂ independently represents a hydrogen atom, an alkyl group, a cycloalkyl group, an aryl group, an aralkyl group or an alkenyl group.

The acid-decomposable group is preferably a cumyl ester group, an enol ester group, an acetal ester group, a tertiary alkyl ester group, etc., more preferably a tertiary alkyl ester group.

As for the alicyclic hydrocarbon-based acid-decomposable repeating unit of the present invention, the resin is preferably a resin containing at least one repeating unit selected from the group consisting of repeating units having alicyclic hydrocarbon-containing partial structures represented by the following formulae (pI) to (pV) and a repeating unit represented by the following formula (II-AB):

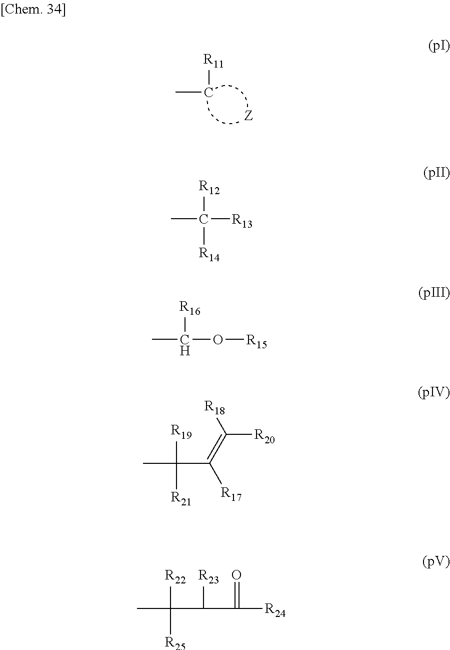

In formulae (pI) to (pV), Rᵢᵢ represents a methyl group, an ethyl group, an n-propyl group, an isopropyl group, an n-butyl group, an isobutyl group or a sec-butyl group. Z represents an atomic group necessary for forming a cycloalkyl group together with the carbon atom.

Each of R₁₂ to R₁₆ independently represents a linear or branched alkyl group having a carbon number of 1 to 4 or a cycloalkyl group. However, at least one of R₁₂ to R₁₄ and either R₁₅ or R₁₆ represent a cycloalkyl group.

Each of R₁₇ to R₂₁ independently represents a hydrogen atom, a linear or branched alkyl group having a carbon number of 1 to 4, or a cycloalkyl group. However, at least one of R₁₇ to R₂₁ represents a cycloalkyl group, and either R₁₉ or R₂₁ represents a linear or branched alkyl group having a carbon number of 1 to 4 or a cycloalkyl group.

Each of R₂₂ to R₂₅ independently represents a hydrogen atom, a linear or branched alkyl group having a carbon number of 1 to 4, or a cycloalkyl group. However, at least one of R₂₂ to R₂₅ represents a cycloalkyl group. R₂₃ and R₂₄ may combine with each other to form a ring.

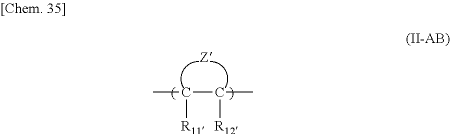

In formula (II-AB), each of R₁₁′ and R₁₂′ independently represents a hydrogen atom, a cyano group, a halogen atom or an alkyl group.

Z′ represents an atomic group necessary for forming an alicyclic structure including two carbon atoms (C—C) to which Z′ is bonded.

Formula (II-AB) is preferably the following formula (II-AB1) or (II-AB2):

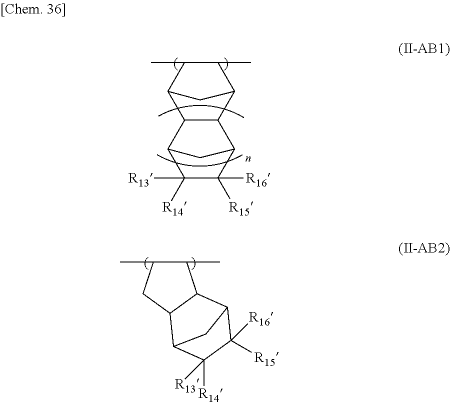

In formulae (II-AB1) and (II-AB2), each of R₁₃′ to R₁₆′ independently represents a hydrogen atom, a halogen atom, a cyano group, —COOH, —COOR₅, a group capable of decomposing by an action of an acid, —C(═O)—X-A′-R₁₇′, an alkyl group or a cycloalkyl group. At least two members out of R₁₃′ to R₁₆′ may combine to form a ring.

Here, R₅ represents an alkyl group, a cycloalkyl group or a group having a lactone structure.

X represents an oxygen atom, a sulfur atom, —NH—, —NHSO₂— or —NHSO₂NH—.

A′ represents a single bond or a divalent linking group.

R₁₇′ represents —COOH, —COOR₅, —CN, a hydroxyl group, an alkoxy group, —CO—NH—R₆, —CO—NH—SO₂—R₆ or a group having a lactone structure.

R₆ represents an alkyl group or a cycloalkyl group.

n represents 0 or 1.

In formulae (pI) to (pV), the alkyl group of R₁₂ to R₂₅ is a linear or branched alkyl group having from 1 to 4 carbon atoms.

The cycloalkyl group of Rᵢᵢ to R₂₅ or the cycloalkyl group formed by Z together with the carbon atoms may be monocyclic or polycyclic and specifically includes a group having, for example, a monocyclo, bicyclo, tricyclo or tetracyclo structure and having a carbon number of 5 or more. The carbon number thereof is preferably from 6 to 30, more preferably from 7 to 25. These cycloalkyl groups may have a substituent.

Preferable cycloalkyl groups include an adamantyl group, a noradamantyl group, a decalin residue, a tricyclodecanyl group, a tetracyclododecanyl group, a norbornyl group, a cedrol group, a cyclopentyl group, a cyclohexyl group, a cycloheptyl group, a cyclooctyl group, a cyclodecanyl group, and a cyclododecanyl group. An adamantyl group, a norbornyl group, a cyclohexyl group, a cyclopentyl group, a tetracyclododecanyl group, and a tricyclodecanyl group are more preferred.

The substituent that may be further substituted on the alkyl group and cycloalkyl group above includes an alkyl group (having a carbon number of 1 to 4), a halogen atom, a hydroxyl group, an alkoxy group (having a carbon number of 1 to 4), a carboxyl group, and an alkoxycarbonyl group (having a carbon number of 2 to 6). The substituent that may be further substituent on these alkyl group, alkoxy group, alkoxycarbonyl group, etc. includes a hydroxyl group, a halogen atom, and an alkoxy group.

The structures represented by formulae (pI) to (pV) in the resin above may be used for the protection of an alkali-soluble group. The alkali-soluble group includes various groups known in this technical field.

Specifically, this configuration includes, for example, a structure where a hydrogen atom of a carboxylic acid group, a sulfonic acid group, a phenol group or a thiol group is substituted for by a structure represented by formulae (pI) to (pV). A structure where a hydrogen atom of a carboxylic acid group or a sulfonic acid group is substituted for by a structure represented by formulae (pI) to (pV) is preferred.

The repeating unit having an alkali-soluble group protected by a structure represented by formulae (pI) to (pV) is preferably a repeating unit represented by the following formula (pA):

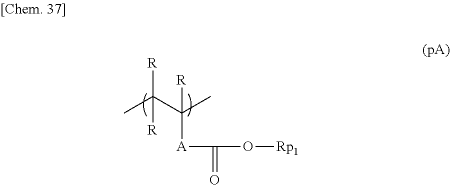

In the formula, R represents a hydrogen atom, a halogen atom or a linear or branched alkyl group having from 1 to 4 carbon atoms, and each R may be the same as or different from every other R.

A is a single group selected from the group consisting of a single bond, an alkylene group, an ether group, a thioether group, a carbonyl group, an ester group, an amido group, a sulfonamido group, a urethane group and a urea group, or a combination of two or more of these groups, and is preferably a single bond.

Rp₁ is a group represented by any one of formulae (pI) to (pV).

The repeating unit represented by formula (pA) is preferably a repeating unit composed of a 2-alkyl-2-adamantyl (meth)acrylate or a dialkyl(1-adamantyl)methyl (meth)acrylate, among others.

Specific examples of the repeating unit represented by formula (pA) are illustrated below, but the present invention is not limited thereto.

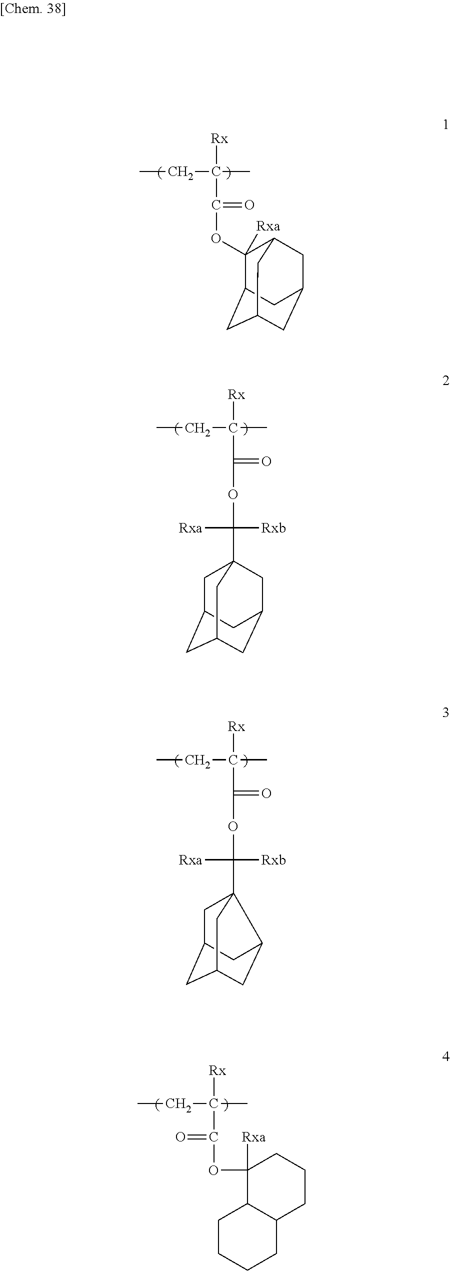

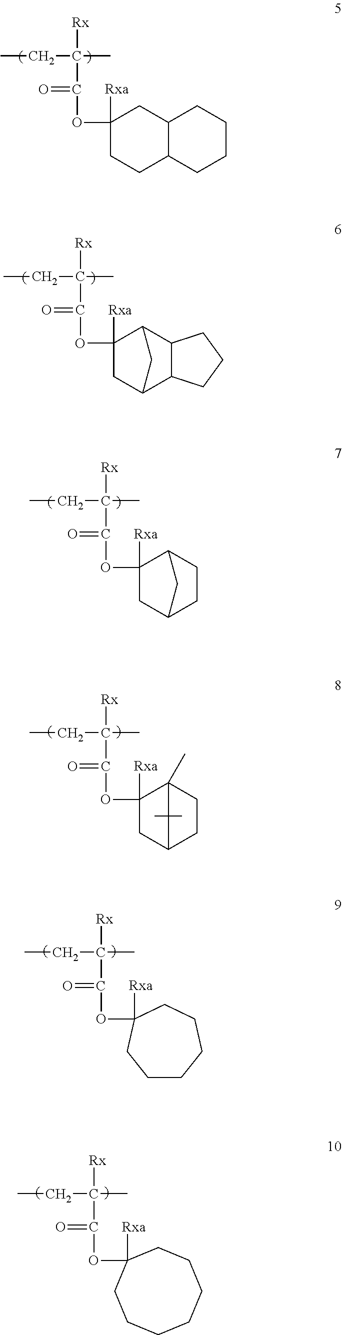

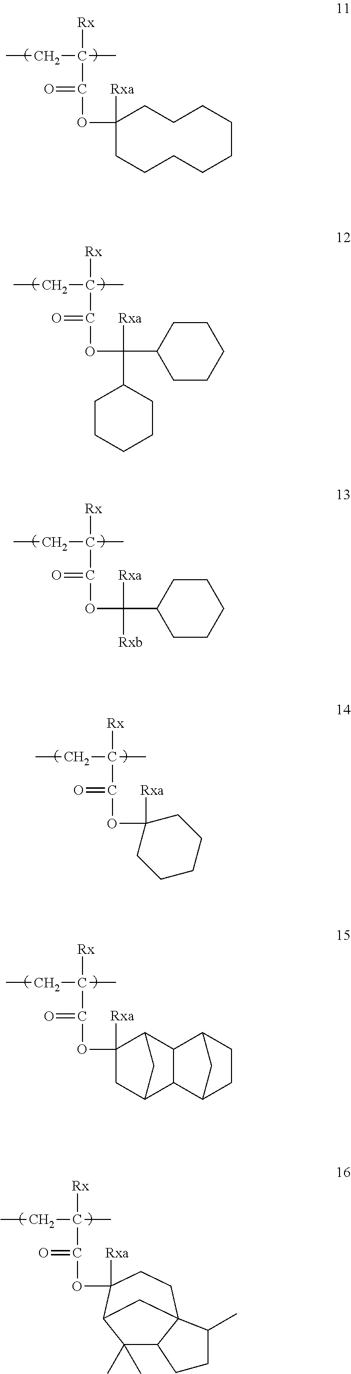

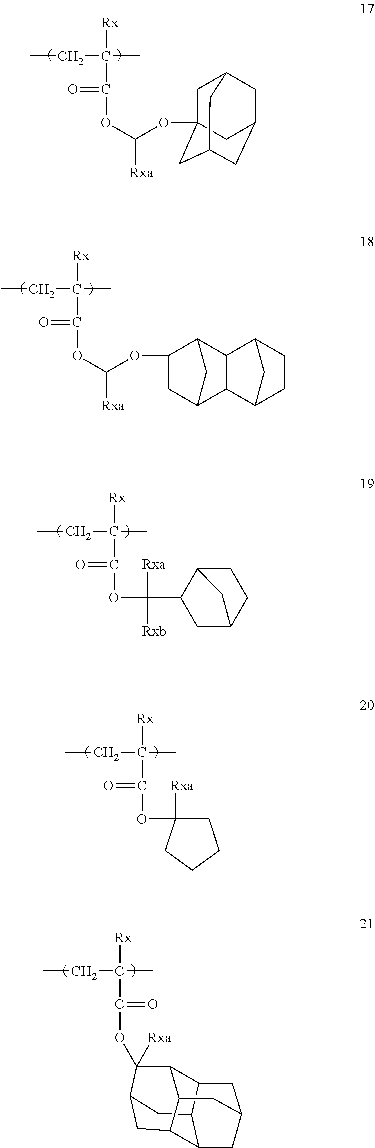

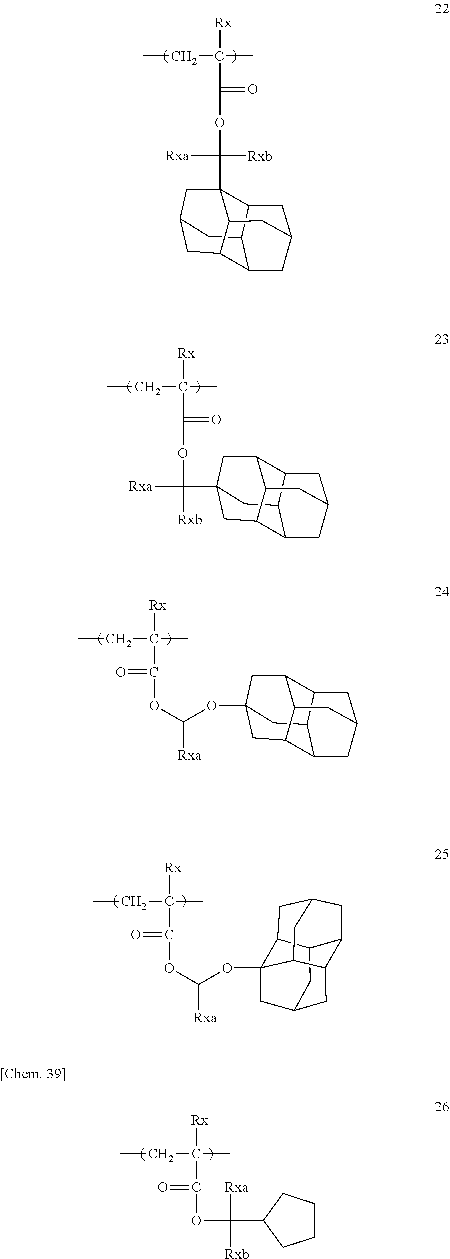

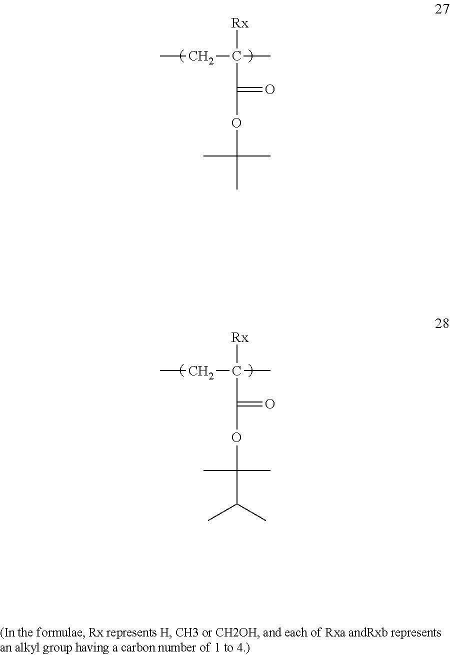

The halogen atom of R₁₁′ and R₁₂′ in formula (II-AB) includes a chlorine atom, a bromine atom, a fluorine atom, an iodine atom, etc.

The alkyl group of R₁₁′ and R₁₂′ includes a linear or branched alkyl group having a carbon number of 1 to 10.

The atomic group Z′ for forming an alicyclic structure is an atomic group for forming, in the resin, a repeating unit composed of an alicyclic hydrocarbon that may have a substituent, and, among others, is preferably an atomic group for forming a bridged alicyclic structure making up a bridged alicyclic hydrocarbon repeating unit.

Examples of the framework of the alicyclic hydrocarbon formed are the same as those of the alicyclic hydrocarbon group of R₁₂ to R₂₅ in formulae (pI) to (pV).

The framework of the alicyclic hydrocarbon may have a substituent, and the substituent includes R₁₃′ to R₁₆′ in formulae (II-AB1) and (II-AB2).

In the alicyclic hydrocarbon-based acid-decomposable repeating unit according to the present invention, the group capable of decomposing by an action of an acid may be contained in at least one repeating unit out of a repeating unit having an alicyclic hydrocarbon-containing partial structure represented by formulae (pI) to (pV), a repeating unit represented by formula (II-AB), and a repeating unit composed of the later-described copolymerization component. The group capable of decomposing by an action of an acid is preferably contained in a repeating unit having an alicyclic hydrocarbon-containing partial structure represented by formulae (pI) to (pV).

Each of the substituents R₁₃′ to R₁₆′ in formulae (II-AB1) and (II-AB2) may work out to a substituent of the atomic group Z for forming an alicyclic structure or a bridged alicyclic structure in formula (II-AB).

Specific examples of the repeating units represented by formulae (II-AB1) and (II-AB2) are illustrated below, but the present invention is not limited to these specific examples.

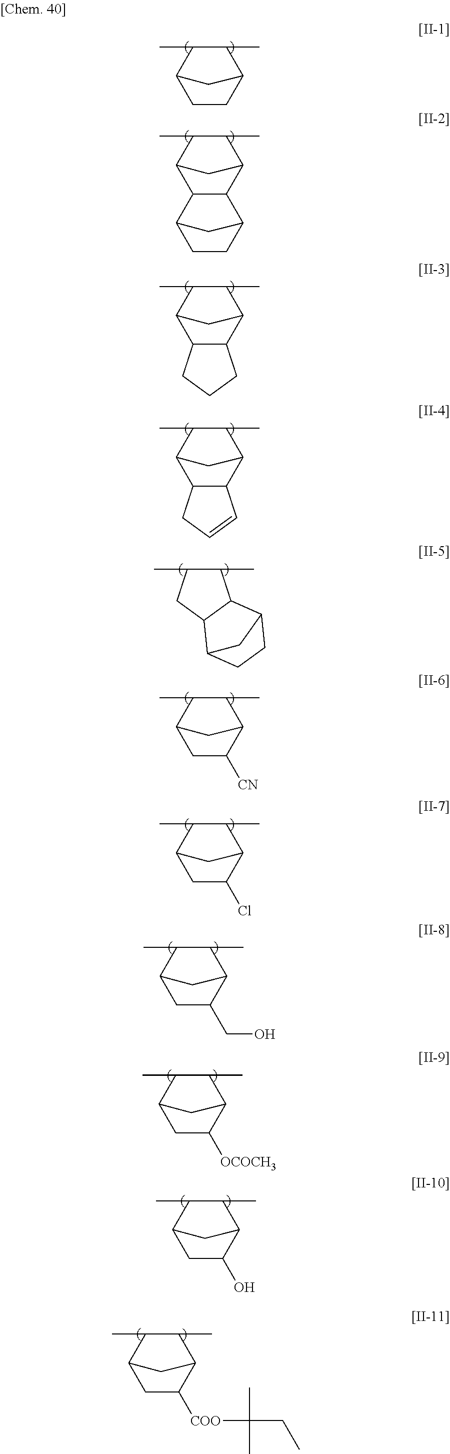

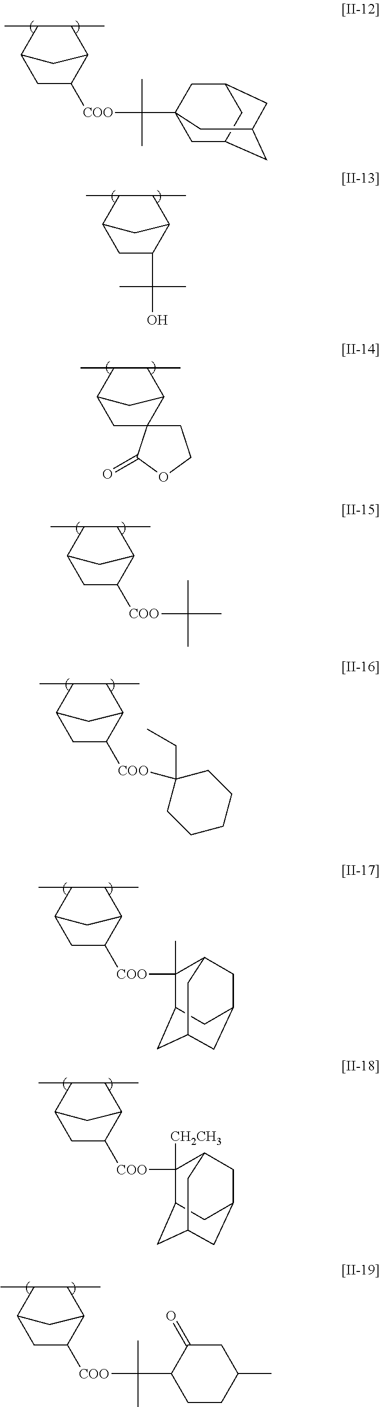

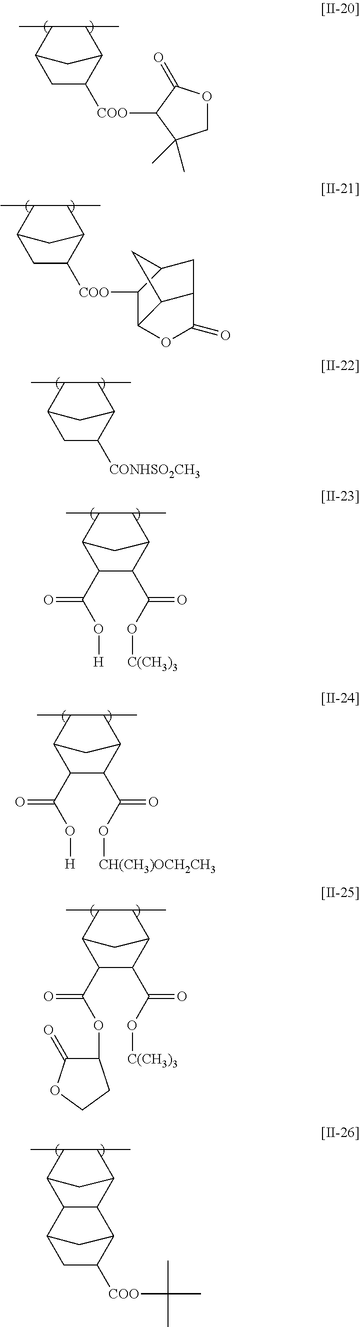

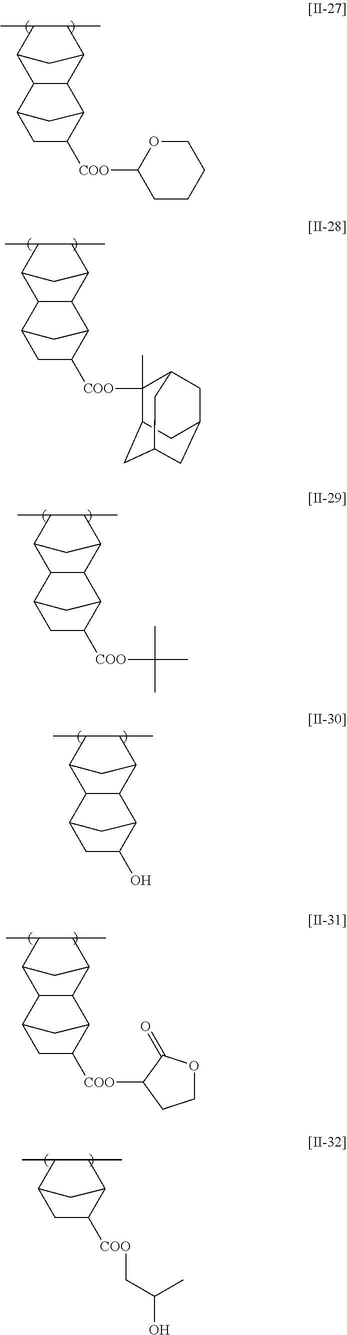

The resin (P) of the present invention preferably has a lactone group. As the lactone group, any group may be used as long as it contains a lactone structure, but the lactone group is preferably a group containing a 5- to 7-membered ring lactone structure, more preferably a group where another ring structure is fused to a 5- to 7-membered ring lactone structure to form a bicyclo or spiro structure. The resin (P) preferably contains a repeating unit having a group containing a lactone structure, more preferably a repeating unit having a group containing a lactone structure represented by any one of the following formulae (LC1-1) to (LC1-16). The group having a lactone structure may be bonded directly to the main chain. Preferable lactone structures are groups represented by formulae (LC1-1), (LC1-4), (LC1-5), (LC1-6), (LC1-13) and (LC1-14). By the use of a specific lactone structure, the line edge roughness and development defect are improved.

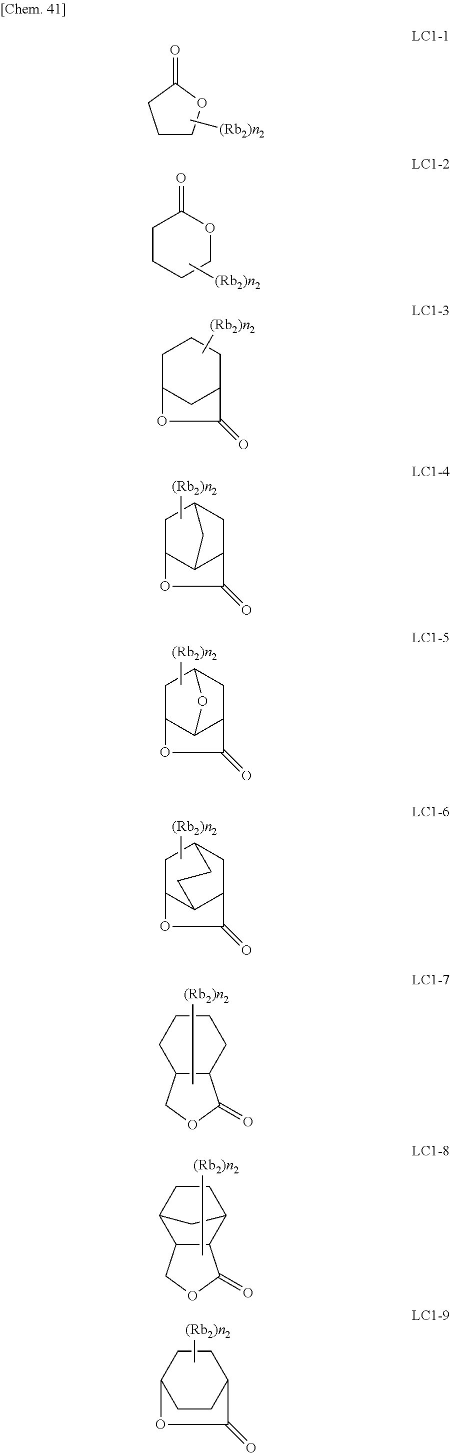

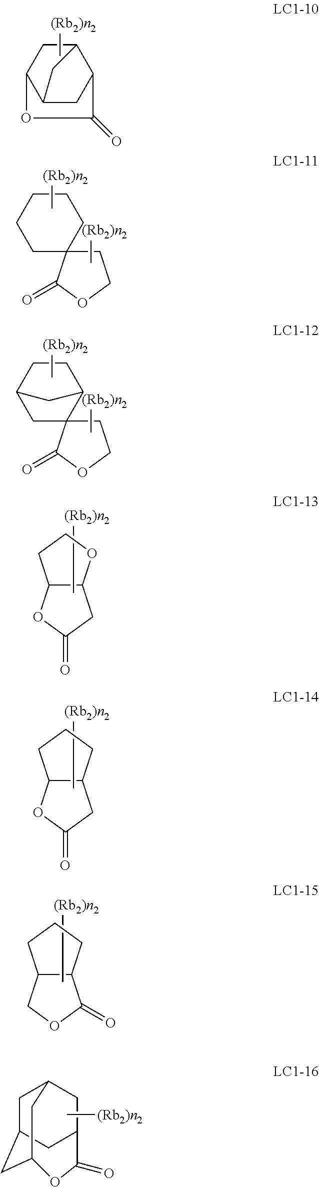

The lactone structure moiety may or may not have a substituent (Rb₂). Preferable substituents (Rb₂) include, for example, an alkyl group having a carbon number of 1 to 8, a cycloalkyl group having a carbon number of 4 to 7, an alkoxy group having a carbon number of 1 to 8, an alkoxycarbonyl group having a carbon number of 1 to 8, a carboxyl group, a halogen atom, a hydroxyl group, a cyano group, and an acid-decomposable group. n2 represents an integer of 0 to 4. When n2 is an integer of 2 or more, each Rb₂ may be the same as or different from every other Rb₂, and the plurality of Rb₂ may combine with each other to form a ring.

The repeating unit having a group containing a lactone structure represented by any one of formulae (LC1-1) to (LC1-16) includes, for example, a repeating unit where at least one of R₁₃′ to R₁₆′ in formula (II-AB1) or (II-AB2) has a group represented by formulae (LC1-1) to (LC1-16) (for example, R₅ of —COOR₅ has a group represented by formulae (LC1-1) to (LC1-16)), and a repeating unit represented by the following formula (AI).

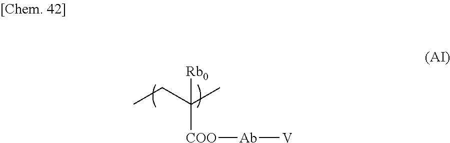

In formula (AI), R_{b0} represents a hydrogen atom, a halogen atom or an alkyl group having a carbon number of 1 to 4.

Preferable substituents that may be substituted on the alkyl group of R_{b0} include a hydroxyl group and a halogen atom.

The halogen atom of R_{b0} includes a fluorine atom, a chlorine atom, a bromine atom, and an iodine atom.

R_{b0} is preferably a hydrogen atom or a methyl group.

A_{b} represents a single bond, an alkylene group, a divalent linking group having a monocyclic or polycyclic alicyclic hydrocarbon structure, an ether group, an ester group, a carbonyl group, or a divalent group formed by combining these, and is preferably a single bond or a linking group represented by -Ab₁-CO₂—. Ab₁ is a linear or branched alkylene group or a monocyclic or polycyclic cycloalkylene group, preferably a methylene group, an ethylene group, a cyclohexylene group, an adamantylene group or a norbornylene group.

V represents a group represented by any one of formulae (LC1-1) to (LC1-16).

The repeating unit having a group containing a lactone structure usually has an optical isomer, and any optical isomer may be used. One optical isomer may be used alone, or a plurality of optical isomers may be mixed and used. In the case of mainly using one optical isomer, the optical purity (ee) thereof is preferably 90 or more, more preferably 95 or more.

Specific examples of the repeating unit having a group containing a lactone structure are illustrated below, but the present invention is not limited thereto.

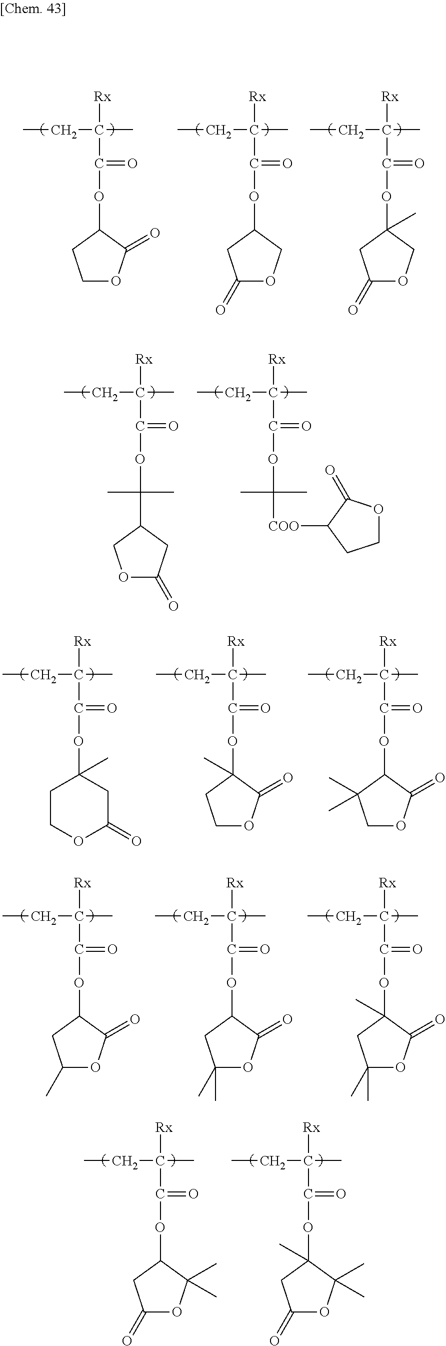

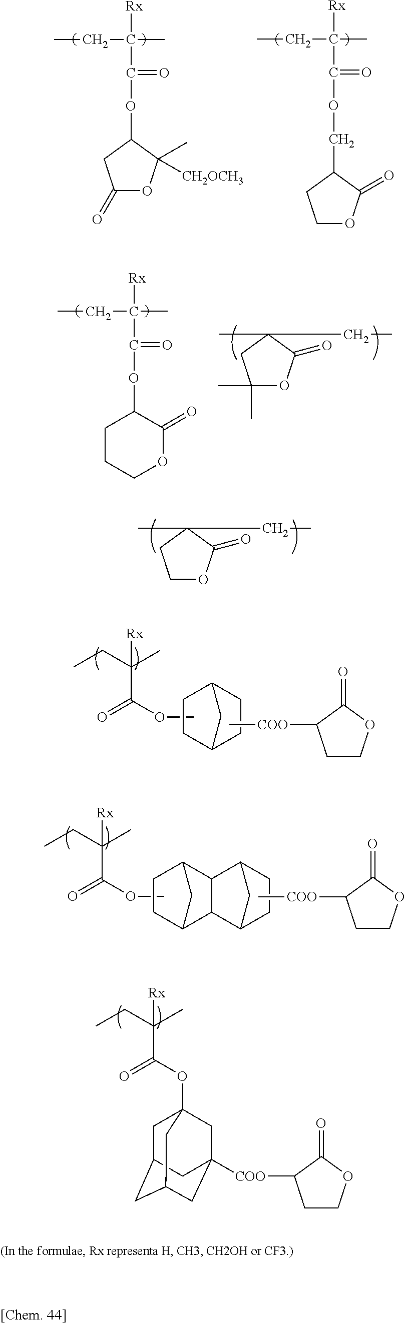

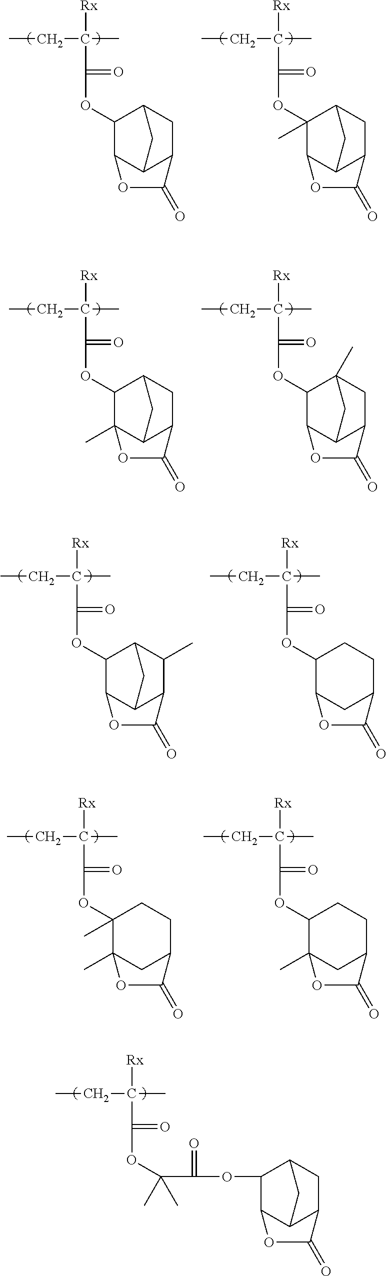

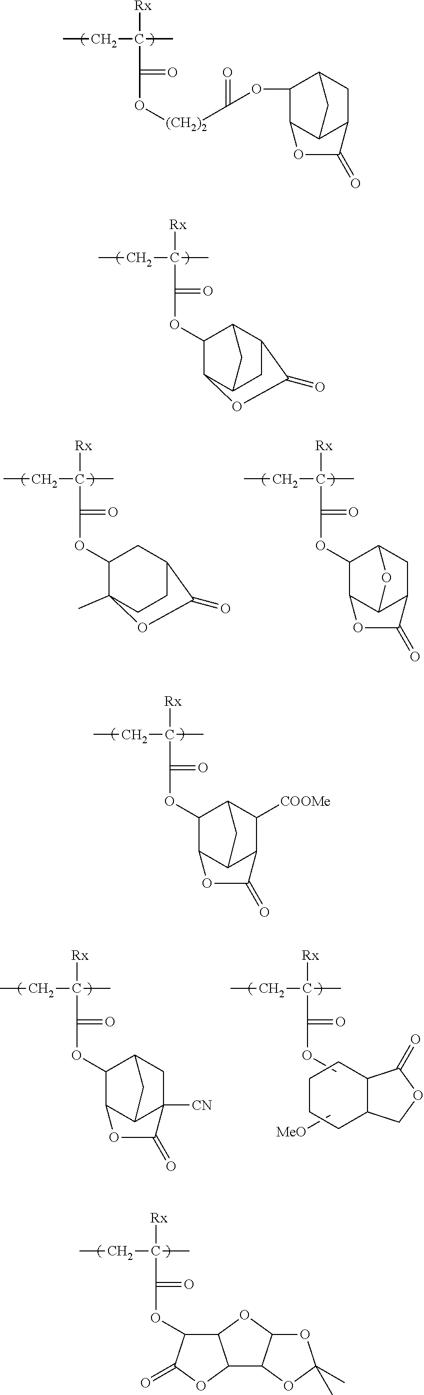

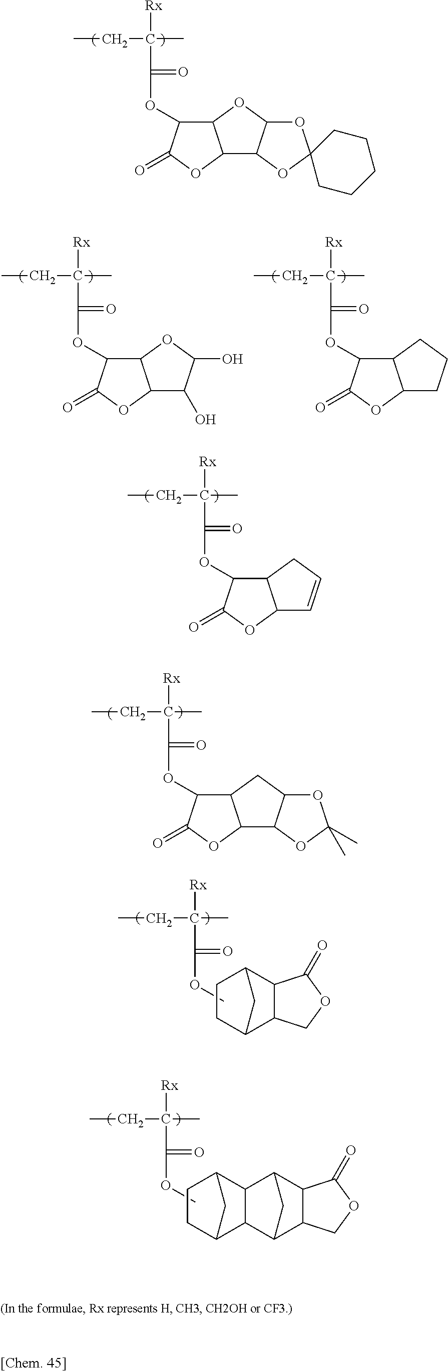

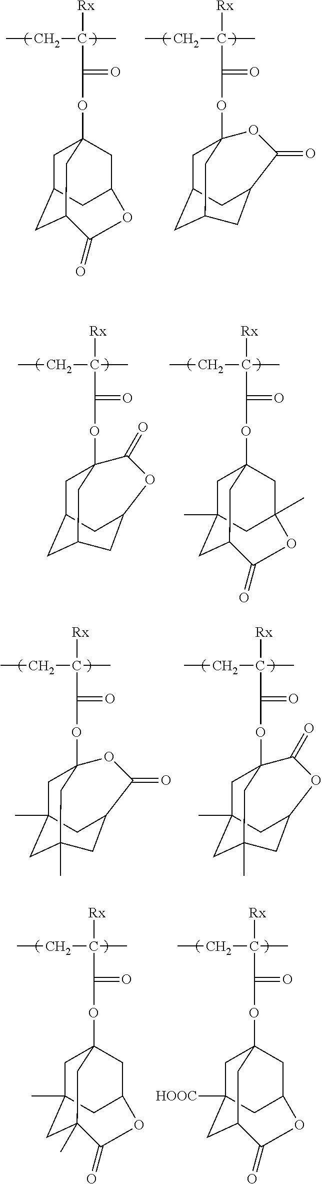

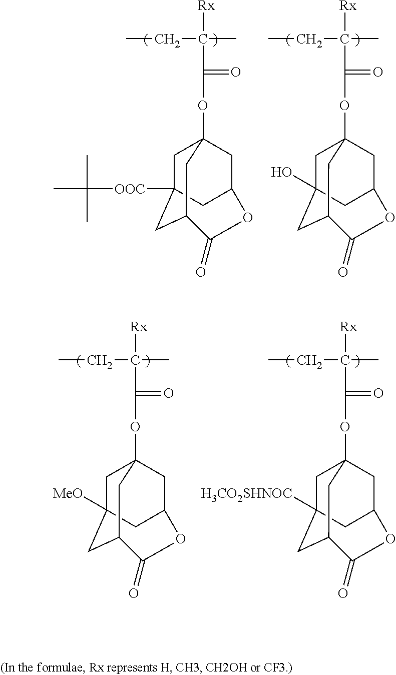

The resin (P) for use in the present invention preferably contains a repeating unit having an organic group containing a polar group, among others, a repeating unit having an alicyclic hydrocarbon structure substituted with a polar group. Thanks to this repeating unit, the adherence to substrate and the affinity for developer are enhanced. The alicyclic hydrocarbon structure of the polar group-substituted alicyclic hydrocarbon structure is preferably an adamantyl group, a diamantyl group or a norbornyl group is suitable. The polar group is preferably a hydroxyl group or a cyano group.

The alicyclic hydrocarbon structure substituted with a polar group is preferably a partial structure represented by the following formulae (VIIa) to (VIId):

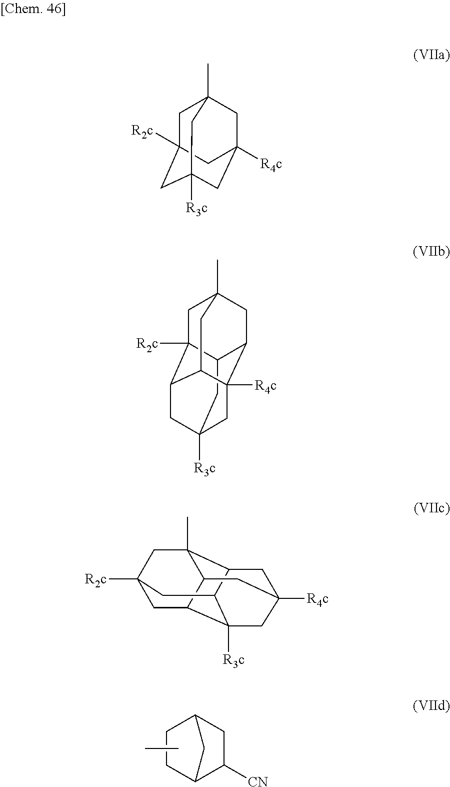

In formulae (VIIa) to (VIIc), each of R_{2C} to R_{4C} independently represents a hydrogen atom, a hydroxyl group or a cyano group, provided that at least one of R_{2C} to R_{4C} represents a hydroxyl group or a cyan group. Preferably, one or two members out of R_{2C} to R_{4C} are a hydroxyl group, with the remaining being a hydrogen atoms.

In formula (VIIa), it is more preferred that two members out of R_{2C} to R_{4C} are a hydroxyl group and the remaining is a hydrogen atom.

The repeating unit having a group represented by formulae (VIIa) to (VIld) includes, for example, a repeating unit where at least one of R₁₃′ to R₁₆′ in formula (II-AB1) or (II-AB2) has a group represented by formula (VII) (for example, R₅ of —COOR₅ is a group represented by formulae (VIIa) to (VIId)), and repeating units represented by the following formulae (AIIa) to (AIId):

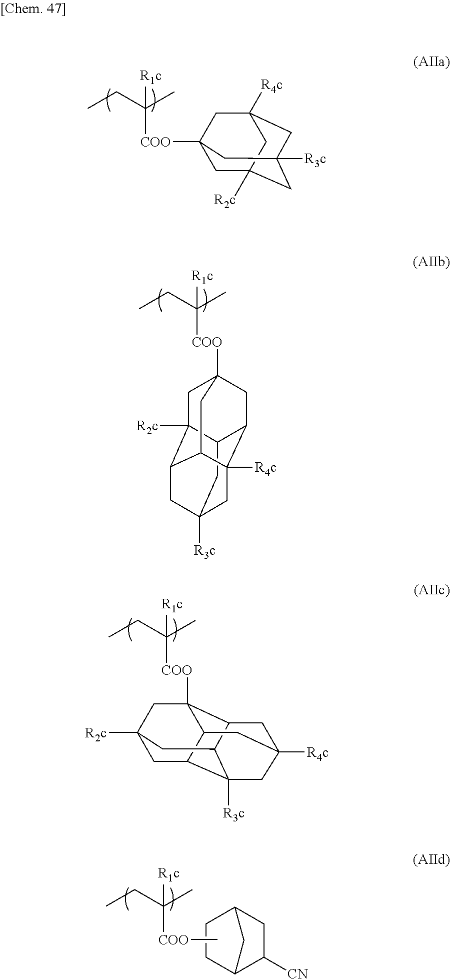

In formulae (AIIa) to (AIId), R_{1c} represents a hydrogen atom, a methyl group, a trifluoromethyl group or a hydroxymethyl group.

R_{2c} to R_{4c} have the same meanings as R_{2c} to R_{4c} in formulae (VIIa) to (VIIc).

Specific examples of the repeating unit having a structure represented by formulae (AIIa) to (AIId) are illustrated below, but the present invention is not limited thereto.

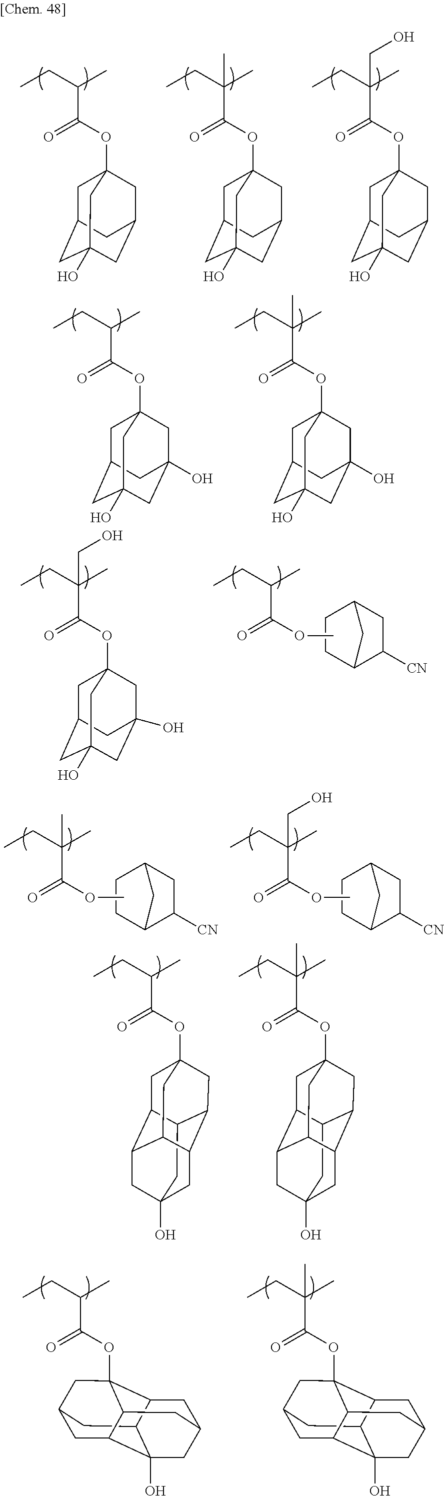

The resin (P) for use in the present invention may contain a repeating unit represented by the following formula (VIII):

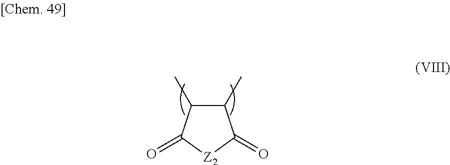

In formula (VIII), Z₂ represents —O— or —N(R₄₁)—. R₄₁ represents a hydrogen atom, a hydroxyl group, an alkyl group or —OSO₂—R₄₂. R₄₂ represents an alkyl group, a cycloalkyl group or a camphor residue. The alkyl group of R₄₁ and R₄₂ may be substituted with a halogen atom (preferably a fluorine atom), etc.

The resin (P) for use in the present invention preferably contains a repeating unit having an alkali-soluble group, more preferably a repeating unit having a carboxyl group. By containing such a repeating unit, the resolution increases in usage of forming contact holes. As the repeating unit having a carboxyl group, all of a repeating unit where a carboxyl group is directly bonded to the main chain of the resin, such as repeating unit by an acrylic acid or a methacrylic acid, a repeating unit where a carboxyl group is bonded to the main chain of the resin through a linking group, and a repeating unit where a carboxyl group is introduced into the polymer chain terminal by using an alkali-soluble group-containing polymerization initiator or chain transfer agent at the time of polymerization, are preferred. The linking group may have a monocyclic or polycyclic, cyclic hydrocarbon structure. In particular, a repeating unit by an acrylic acid or a methacrylic acid is preferred.

The resin (P) for use in the present invention may further contain a repeating unit having from 1 to 3 groups represented by formula (F1). Thanks to this repeating unit, the performance in terms of line edge roughness is improved.

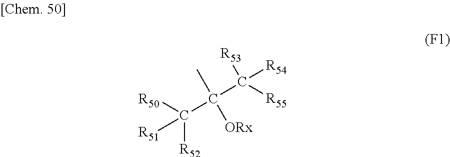

In formula (F1), each of R₅₀ to R₅₅ independently represents a hydrogen atom, a fluorine atom or an alkyl group, provided that at least one of R₅₀ to R₅₅ is a fluorine atom or an alkyl group with at least one hydrogen atom being substituted for by a fluorine atom.

Rx represents a hydrogen atom or an organic group (preferably an acid-decomposable protective group, an alkyl group, a cycloalkyl group, an acyl group or an alkoxycarbonyl group).

The alkyl group of R₅₀ to R₅₅ may be substituted with a halogen atom such as fluorine atom, a cyano group, etc. and is preferably an alkyl group having a carbon number of 1 to 3, and examples thereof include a methyl group and a trifluoromethyl group.

It is preferred that all of R₅₀ to R₅₅ are a fluorine atom.

As the organic group represented by Rx, an acid-decomposable protective group, and alkyl, cycloalkyl, acyl, alkylcarbonyl, alkoxycarbonyl, alkoxycarbonylmethyl, alkoxymethyl and 1-alkoxyethyl groups each of which may have a substituent, are preferred.

The repeating unit having a group represented by formula (F1) is preferably a repeating unit represented by the following formula (F2):

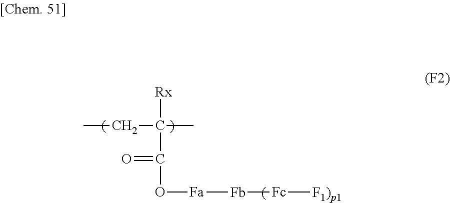

In formula (F2), Rx represents a hydrogen atom, a halogen atom, or an alkyl group having a carbon number of 1 to 4. The substituent that may be substituted on the alkyl group of Rx includes a hydroxyl group and a halogen atom.

Fa represents a single bond or a linear or branched alkylene group (preferably a single bond).

Fb represents a monocyclic or polycyclic, cyclic hydrocarbon group.

Fc represents a single bond or a linear or branched alkylene group (preferably a single bond or a methylene group).

F₁ represents a group represented by formula (F1).

P₁ represents 1 to 3.

The cyclic hydrocarbon group of Fb is preferably a cyclopentylene group, a cyclohexylene group or a norbornylene group.

Specific examples of the repeating unit having a group represented by formula (F1) are illustrated below, but the present invention is not limited thereto.

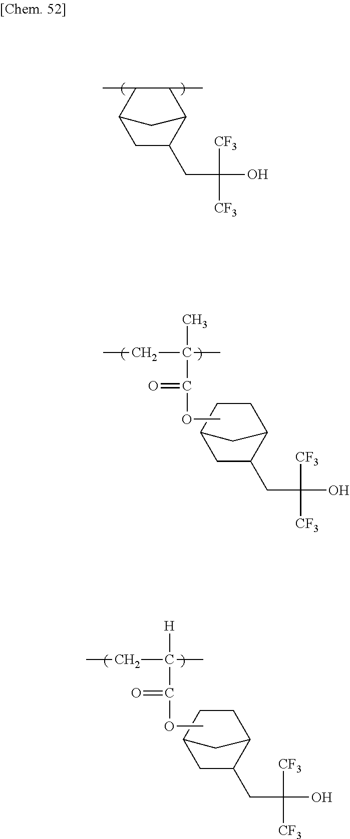

The resin (P) for use in the present invention may further contain a repeating unit having an alicyclic hydrocarbon structure and not exhibiting acid decomposability. Thanks to this repeating unit, elution of low molecular components from a resist film into an immersion liquid at the time of immersion exposure can be reduced. Such a repeating unit includes, for example, 1-adamantyl (meth)acrylate, tricyclodecanyl (meth)acrylate, and cyclohexyl (meth)acrylate.

The resin (P) for use in the present invention may contain, in addition to the above-described repeating structural units, various repeating structural units for the purpose of adjusting the dry etching resistance, suitability for standard developer, adherence to substrate, resist profile and properties generally required of a resist, such as resolution, heat resistance and sensitivity.

Such a repeating structural unit includes, but is not limited to, repeating structural units corresponding to the monomers described below.

Thanks to such a repeating structural unit, the performance required of the resin (P), particularly, (1) solubility in a coating solvent, (2) film-forming property (glass transition temperature), (3) solubility in a positive developer and an organic solvent-containing developer, (4) film loss (selection of hydrophilic, hydrophobic or alkali-soluble group), (5) adherence of unexposed area to substrate, (6) dry etching resistance, etc. can be subtly controlled.

The monomer includes, for example, a compound having one addition-polymerizable unsaturated bond, selected from acrylic acid esters, methacrylic acid esters, acrylamides, methacrylamides, allyl compounds, vinyl ethers and vinyl esters.

Other than these compounds, an addition-polymerizable unsaturated compound copolymerizable with monomers corresponding to the above-described various repeating structural units may be copolymerized.

In the resin (P), the molar ratio of respective repeating structural units contained is appropriately set to adjust the dry etching resistance of resist composition, suitability for standard developer, adherence to substrate, resist profile and performances generally required of a resist, such as resolution, heat resistance and sensitivity.

Preferred embodiments of the resin (P) for use in the present invention include the followings.

(1) An embodiment containing a repeating unit having an alicyclic hydrocarbon-containing partial structure represented by formulae (pI) to (pV) (side-chain type).

It is preferable to contain a (meth)acrylate repeating unit having a structure of (pI) to (pV).

(2) An embodiment containing a repeating unit represented by formula (II-AB) (main-chain type).

Here, the embodiment (2) further includes, for example, the following.

(3) An embodiment containing a repeating unit represented by formula (II-AB), a maleic anhydride derivative, and a (meth)acrylate structure (hybrid type).

In the resin (P), the content of the repeating unit having an acid-decomposable group is preferably from 10 to 60 mol %, more preferably from 20 to 50 mol %, still more preferably from 25 to 40 mol %, relative to all repeating structural units.

In the resin (P), the content of the repeating unit having an alicyclic hydrocarbon-containing partial structure represented by formulae (pI) to (pV) is preferably from 20 to 70 mol %, more preferably from 20 to 50 mol %, still more preferably from 25 to 40 mol %, relative to all repeating structural units.

In the resin (P), the content of the repeating unit represented by formula (II-AB) is preferably from 10 to 60 mol %, more preferably from 15 to 55 mol %, still more preferably from 20 to 50 mol %, relative to all repeating structural units.

In the resin (P), the content of the repeating unit having a lactone ring is preferably from 10 to 70 mol %, more preferably from 20 to 60 mol %, still more preferably from 25 to 40 mol %, relative to all repeating structural units.

In the resin (P), the content of the repeating unit having an organic group containing a polar group is preferably from 1 to 40 mol %, more preferably from 5 to 30 mol %, still more preferably from 5 to 20 mol %, relative to all repeating structural units.

The content of the repeating structural unit based on the monomer as the further copolymerization component in the resin may also be appropriately set according to the desired performance of the resist but, in general, is preferably 99 mol % or less, more preferably 90 mol % or less, still more preferably 80 mol % or less, relative to the total number of moles of the repeating structural unit having an alicyclic hydrocarbon-containing partial structure represented by formulae (pI) to (pV) and the repeating unit represented by formula (II-AB).

The resin (P) for use in the present invention is preferably a resin where all repeating units are composed of a (meth)acrylate-based repeating unit. In this case, any of a resin where all repeating units are a methacrylate-based repeating unit, a resin where all repeating units are an acrylate-based repeating unit, and a resin where all repeating units are a methacrylate-based repeating unit/acrylate-based repeating unit mixture, may be used, but the content of the acrylate-based repeating unit is preferably 50 mol % or less relative to all repeating units.

The resin (P) is preferably a copolymer containing at least three kinds of repeating units, i.e., a (meth)acrylate-based repeating unit having a lactone ring, a (meth)acrylate-based repeating unit having an organic group substituted with at least either a hydroxyl group or a cyano group, and a (meth)acrylate-based repeating unit having an acid-decomposable group.

A preferable resin is a ternary copolymer containing from 20 to 50 mol % of a repeating unit containing an alicyclic hydrocarbon-containing partial structure represented by formulae (pI) to (pV), from 20 to 50 mol % of a repeating unit having a lactone structure, and from 5 to 30% of a repeating unit having an alicyclic hydrocarbon structure substituted with a polar group, or a quaternary copolymer further containing from 0 to 20% of another repeating unit.

A more preferable resin is a ternary copolymer containing from 20 to 50 mol % of an acid-decomposable group-containing repeating unit represented by the following formulae (ARA-1) to (ARA-7), from 20 to 50 mol % of a lactone group-containing repeating unit represented by the following formulae (ARL-1) to (ARL-7), and from 5 to 30 mol % of a polar group-substituted alicyclic hydrocarbon structure-containing repeating unit represented by the following formulae (ARH-1) to (ARH-3), or a quaternary copolymer further containing from 5 to 20 mol % of a repeating unit having a carboxyl group or a structure represented by formula (F1) or a repeating unit having an alicyclic hydrocarbon structure and not exhibiting acid decomposability.

(In the formulae, Rxy₁ represents a hydrogen atom or a methyl group, each of Rxa₁ and Rxb₁ independently represents a methyl group or an ethyl group, and Rxc₁ represents a hydrogen atom or a methyl group.)

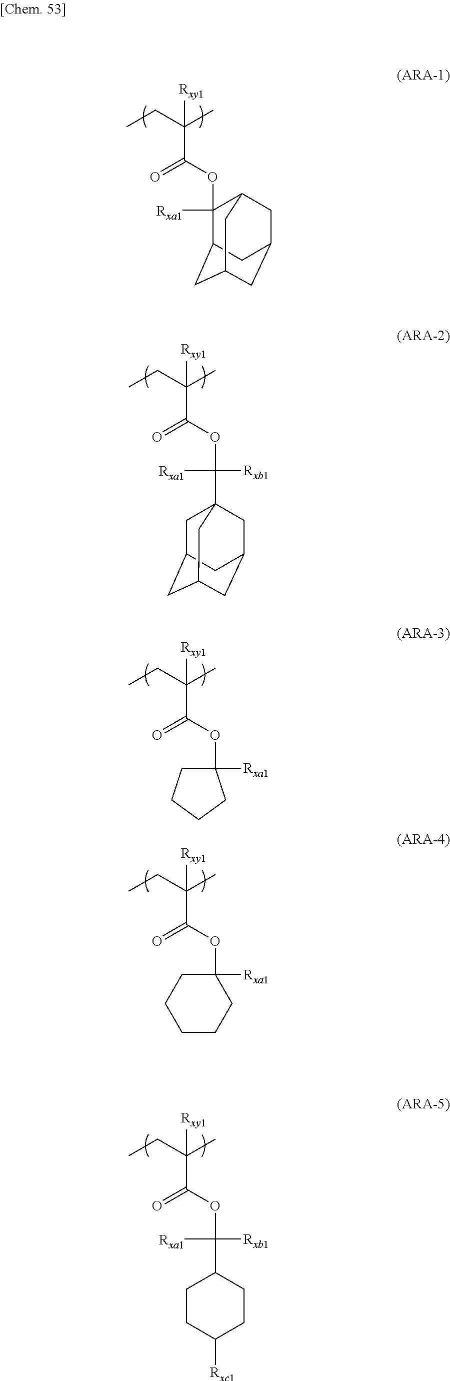

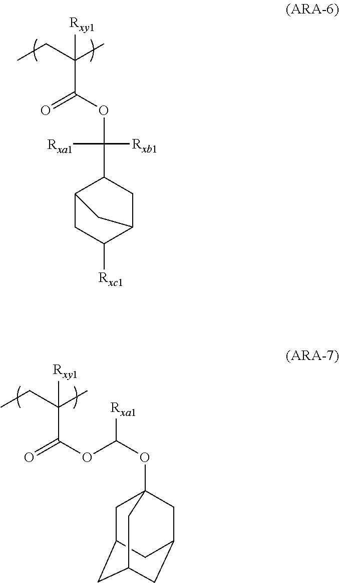

(In the formulae, Rxy₁ represents a hydrogen atom or a methyl group, Rxd₁ represents a hydrogen atom or a methyl group, and Rxe₁ represents a trifluoromethyl group, a hydroxyl group or a cyano group.)

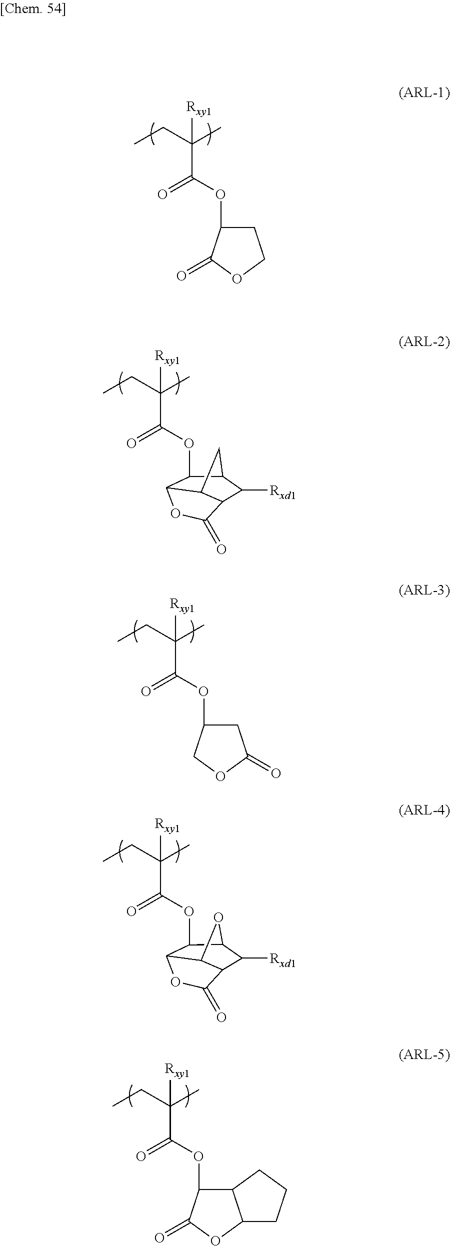

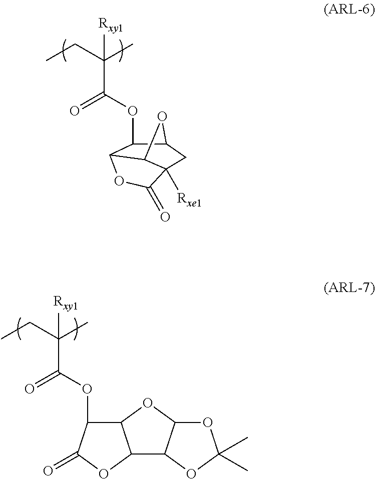

(In the formulae, Rxy₁ represents a hydrogen atom or a methyl group.)

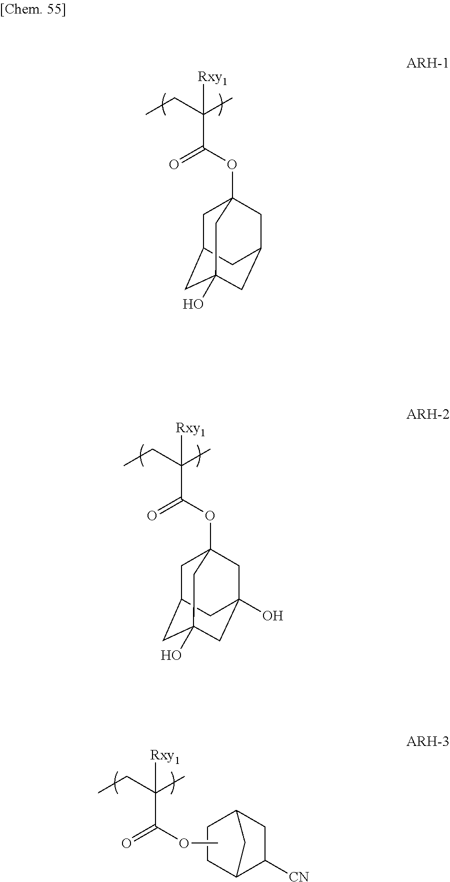

The resin (P) for use in the present invention can be synthesized by a conventional method (for example, radical polymerization). The general synthesis method includes, for example, a batch polymerization method of dissolving monomer species and an initiator in a solvent and heating the solution, thereby effecting the polymerization, and a dropping polymerization method of adding dropwise a solution containing monomer species and an initiator to a heated solvent over 1 to 10 hours. A dropping polymerization method is preferred. The reaction solvent includes, for example, ethers such as tetrahydrofuran, 1,4-dioxane and diisopropyl ether, ketones such as methyl ethyl ketone and methyl isobutyl ketone, an ester solvent such as ethyl acetate, an amide solvent such as dimethylformamide and dimethylacetamide, and the later-described solvent capable of dissolving the composition of the present invention, such as propylene glycol monomethyl ether acetate, propylene glycol monomethyl ether and cyclohexanone. The polymerization is more preferably performed using the same solvent as the solvent used in the resist composition of the present invention. By the use of the same solvent, production of particles during storage can be suppressed.

The polymerization reaction is preferably performed in an inert gas atmosphere such as nitrogen or argon. As for the polymerization initiator, the polymerization is started using a commercially available radical initiator (e.g., azo-based initiator, peroxide). The radical initiator is preferably an azo-based initiator, and an azo-based initiator having an ester group, a cyano group or a carboxyl group is preferred. Preferable initiators include azobisisobutyronitrile, azobisdimethylvaleronitrile and dimethyl 2,2′-azobis (2-methylpropionate). The initiator is added additionally or in parts, if desired. After the completion of reaction, the reaction solution is poured in a solvent, and the desired polymer is collected by a powder, solid or other recovery methods. The concentration at the time of reaction is from 5 to 50 mass %, preferably from 10 to 30 mass %, and the reaction temperature is usually from 10 to 150° C., preferably from 30 to 120° C., more preferably from 60 to 100° C.

The purification can be performed by applying an ordinary method, for example, a purification method in a solution state, such as liquid-liquid extraction of removing residual monomer or oligomer components by washing with water or combination of appropriate solvents, and ultrafiltration of removing by extraction only components having a molecular weight not more than a specific value; and a purification method in a solid state, such as reprecipitation of removing residual monomers, etc. by adding dropwise a resin solution into a poor solvent to coagulate the resin in the poor solvent, and washing of a filtered resin slurry with a poor solvent.

The weight average molecular weight of the resin according to the present invention is preferably from 1,000 to 200,000, more preferably from 1,000 to 20,000, and most preferably from 1,000 to 15,000, in terms of polystyrene as measured by GPC method. When the weight average molecular weight is from 1,000 to 200,000, reduction in the heat resistance or dry etching resistance can be prevented and at the same time, the film forming property can be prevented from deteriorating due to decrease in the developability or increase in the viscosity.

The polydispersity (molecular weight distribution) is usually from 1 to 5, preferably from 1 to 3, more preferably from 1.2 to 3.0, still more preferably from 1.2 to 2.0. As the polydispersity is smaller, the resolution and resist profile are more excellent, the side wall of the resist pattern is smoother, and the performance in terms of roughness is higher.

As for the resin (P) of the present invention, one kind of a resin may be used alone, or two or more kinds of resins may be used in combination. The content of the resin (P) is preferably from 30 to 100 mass %, more preferably from 50 to 100 mass %, still more preferably from 70 to 100 mass %, based on the total solid content of the actinic ray-sensitive or radiation-sensitive resin composition of the present invention.

In view of compatibility with the protective film composition, it is preferred that the resin (P) of the present invention, more preferably, the actinic ray-sensitive or radiation-sensitive resin composition of the present invention, contains no fluorine atom and no silicon atom.

[2] (B) Compound Capable of Decomposing Upon Irradiation with an Actinic Ray or Radiation to Generate an Acid

The actinic ray-sensitive or radiation-sensitive resin composition of the present invention contains a compound capable of decomposing upon irradiation with an actinic ray or radiation to generate and acid (hereinafter, sometimes referred to as “acid generator”).

The acid generator is not particularly limited as long as it is a known acid generator, but a compound capable of generating an organic acid, for example, at least one of a sulfonic acid, a bis(alkylsulfonyl)imide and a tris(alkylsulfonyl)methide, upon irradiation with an actinic ray or radiation is preferred.

More preferable compounds include compounds represented by the following formulae (ZI), (ZII) and (ZIII):

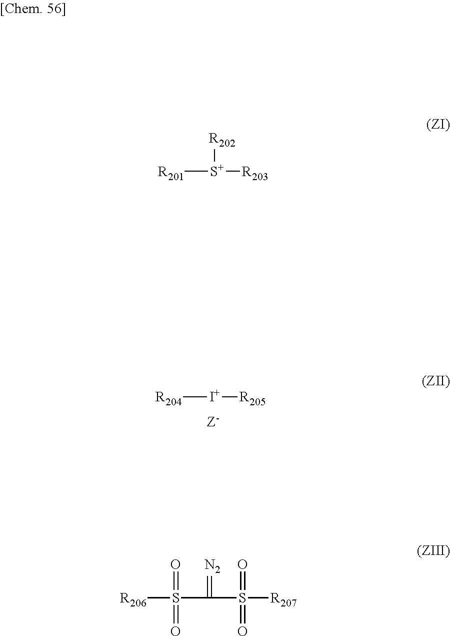

In formula (ZI), each of R₂₀₁, R₂₀₂ and R₂₀₃ independently represents an organic group.

The carbon number of the organic group as R₂₀₁, R₂₀₂ and R₂₀₃ is generally from 1 to 30, preferably from 1 to 20.

Two members out of R₂₀₁ to R₂₀₃ may combine to form a ring structure, and the ring may contain therein an oxygen atom, a sulfur atom, an ester bond, an amido bond or a carbonyl group. The group formed by combining two members out of R₂₀₁ to R₂₀₃ includes an alkylene group (for example, a butylene group and a pentylene group).

Z⁻ represents a non-nucleophilic anion.

The non-nucleophilic anion includes, for example, a sulfonate anion (e.g., aliphatic sulfonate anion, aromatic sulfonate anion, camphor sulfonate anion), a carboxylate anion (e.g., aliphatic carboxylate anion, aromatic carboxylate anion, aralkylcarboxylate anion), a sulfonylimide anion, a bis(alkylsulfonyl)imide anion, and a tris(alkylsulfonyl)methide anion.

The aliphatic moiety in the aliphatic sulfonate anion and aliphatic carboxylate anion may be an alkyl group or a cycloalkyl group and is preferably a linear or branched alkyl group having a carbon number of 1 to 30 or a cycloalkyl group having a carbon number of 3 to 30.

The aromatic group in the aromatic sulfonate anion and aromatic carboxylate anion is preferably an aryl group having a carbon number of 6 to 14, and examples thereof include a phenyl group, a tolyl group and a naphthyl group.

The above-described alkyl group, cycloalkyl group and aryl group may have a substituent. Specific examples thereof include a nitro group, a halogen atom such as fluorine atom, a carboxyl group, a hydroxyl group, an amino group, a cyano group, an alkoxy group (preferably having a carbon number of 1 to 15), a cycloalkyl group (preferably having a carbon number of 3 to 15), an aryl group (preferably having a carbon number of 6 to 14), an alkoxycarbonyl group (preferably having a carbon number of 2 to 7), an acyl group (preferably having a carbon number of 2 to 12), an alkoxycarbonyloxy group (preferably having a carbon number of 2 to 7), an alkylthio group (preferably having a carbon number of 1 to 15), an alkylsulfonyl group (preferably having a carbon number of 1 to 15), an alkyliminosulfonyl group (preferably having a carbon number of 2 to 15), an aryloxysulfonyl group (preferably having a carbon number of 6 to 20), an alkylaryloxysulfonyl group (preferably having a carbon number of 7 to 20), a cycloalkylaryloxysulfonyl group (preferably having a carbon number of 10 to 20), an alkyloxyalkyloxy group (preferably having a carbon number of 5 to 20), and a cycloalkylalkyloxyalkyloxy group (preferably having a carbon number of 8 to 20). As for the aryl group and ring structure in each group, the substituent thereon further includes an alkyl group (preferably having a carbon number of 1 to 15).

The aralkyl group in the aralkylcarboxylate anion is preferably an aralkyl group having a carbon number of 6 to 12, and examples thereof include a benzyl group, a phenethyl group, a naphthylmethyl group, a naphthylethyl group and a naphthylbutyl group.

The sulfonylimide anion includes, for example, saccharin anion.

The alkyl group in the bis(alkylsulfonyl)imide anion and tris(alkylsulfonyl)methide anion is preferably an alkyl group having a carbon number of 1 to 5, and examples of the substituent on this alkyl group include a halogen atom, a halogen atom-substituted alkyl group, an alkoxy group, an alkylthio group, an alkyloxysulfonyl group, an aryloxysulfonyl group, and a cycloalkylaryloxysulfonyl group, with a fluorine atom and a fluorine atom-substituted alkyl group being preferred.

The alkyl groups in the bis(alkylsulfonyl)imide anion may combine with each other to form a ring structure. Thanks to this configuration, the acid strength increases.

Other examples of the non-nucleophilic anion include a fluorinated phosphorus (e.g., PF₆⁻), a fluorinated boron (e.g., BF₄⁻), and a fluorinated antimony (e.g., SbF₆⁻).

The non-nucleophilic anion is preferably an aliphatic sulfonate anion substituted with a fluorine atom at least at the α-position of the sulfonic acid, an aromatic sulfonate anion substituted with a fluorine atom or a fluorine atom-containing group, a bis(alkylsulfonyl)imide anion in which the alkyl group is substituted with a fluorine atom, or a tris(alkylsulfonyl)methide anion in which the alkyl group is substituted with a fluorine atom. The non-nucleophilic anion is more preferably a perfluoroaliphatic sulfonate anion (more preferably having a carbon number of 4 to 8) or a fluorine atom-containing benzenesulfonate anion, still more preferably nonafluorobutanesulfonate anion, perfluorooctanesulfonate anion, pentafluorobenzenesulfonate anion or 3,5-bis(trifluoromethyl)benzenesulfonate anion.

As regards the acid strength, the pKa of the acid generated is preferably −1 or less for enhancing the sensitivity.

An anion represented by the following formula (AN1) is also a preferred embodiment of the non-nucleophilic anion:

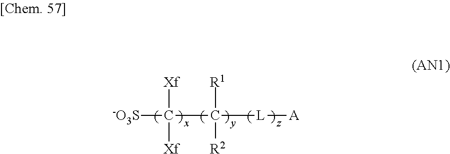

In the formula, each Xf independently represents a fluorine atom or an alkyl group substituted with at least one fluorine atom.

Each of R¹ and R² independently represents a hydrogen atom, a fluorine atom or an alkyl group, and when a plurality of R¹ or R² are present, each R¹ or R² may be the same as or different from every other R¹ or R².

L represents a divalent linking group, and when a plurality of L are present, each L may be the same as or different from every other L.

A represents a cyclic organic group.

x represents an integer of 1 to 20, y represents an integer of 0 to 10, and z represents an integer of 0 to 10.

Formula (AN1) is described in more detail.

The alkyl group in the fluorine atom-substituted alkyl group of Xf is preferably has a carbon number of 1 to 10, more preferably a carbon number of 1 to 4. The fluorine atom-substituted alkyl group of Xf is preferably a perfluoroalkyl group.

Xf is preferably a fluorine atom or a perfluoroalkyl group having a carbon number of 1 to 4. Specific examples of Xf include a fluorine atom, CF₃, C₂F₅, C₃F₇, C₄F₉, CH₂CF₃, CH₂CH₂CF₃, CH₂C₂F₅, CH₂CH₂C₂F₅, CH₂C₃F₇, CH₂CH₂C₃F₇, CH₂C₄F₉ and CH₂CH₂C₄F₉, with a fluorine atom and CF₃ being preferred. In particular, it is preferred that both Xf are a fluorine atom.

The alkyl group of R¹ and R² may have a substituent (preferably a fluorine atom) and is preferably an alkyl group having a carbon number of 1 to 4, more preferably a perfluoroalkyl group having a carbon number of 1 to 4. Specific examples of the alkyl group having a substituent of R¹ and R² include CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ and CH₂CH₂C₄F₉, with CF₃ being preferred.

Each of R¹ and R² is preferably a fluorine atom or CF₃.

x is preferably an integer of 1 to 10, more preferably from 1 to 5.

y is preferably an integer of 0 to 4, more preferably 0.

z is preferably an integer of 0 to 5, more preferably from 0 to 3.

The divalent linking group of L is not particularly limited and includes, for example, —COO—, —OCO—, —CO—, —O—, —S—, —SO—, —SO₂—, an alkylene group, a cycloalkylene group, an alkenylene group, and a linking group formed by combining a plurality thereof. A linking group having a total carbon number of 12 or less is preferred. Among these, —COO—, —OCO—, —CO— and —O— are preferred, and —COO— and —OCO— are more preferred.

The cyclic organic group of A is not particularly limited as long as it has a cyclic structure, and examples thereof include an alicyclic group, an aryl group and a heterocyclic group (including not only those having aromaticity but also those having no aromaticity).

The alicyclic group may be monocyclic or polycyclic and is preferably a monocyclic cycloalkyl group such as cyclopentyl group, cyclohexyl group and cyclooctyl group, or a polycyclic cycloalkyl group such as norbornyl group, tricyclodecanyl group, tetracyclodecanyl group, tetracyclododecanyl group and adamantyl group. Above all, an alicyclic group having a bulky structure with a carbon number of 7 or more, such as norbornyl group, tricyclodecanyl group, tetracyclodecanyl group, tetracyclododecanyl group and adamantyl group, is preferred from the standpoint that diffusion in the film during heating after exposure can be suppressed and MEEF can be improved.

The aryl group includes a benzene ring, a naphthalene ring, a phenanthrene ring, and an anthracene ring.

The heterocyclic group includes those derived from a furan ring, a thiophene ring, a benzofuran ring, a benzothiophene ring, a dibenzofuran ring, a dibenzothiophene ring and a pyridine ring. Among these, heterocyclic groups derived from a furan ring, a thiophene ring and a pyridine ring are preferred.

The cyclic organic group also includes a lactone structure, and specific examples thereof include lactone structures represented by formulae (LC1-1) to (LC1-17) which may be contained in the resin (A).

The cyclic organic group may have a substituent, and the substituent includes an alkyl group (may be any of linear, branched or cyclic; preferably having a carbon number of 1 to 12), a cycloalkyl group (may be any of monocyclic, polycyclic or spirocyclic; preferably having a carbon number of 3 to 20), an aryl group (preferably having a carbon number of 6 to 14), a hydroxy group, an alkoxy group, an ester group, an amide group, a urethane group, a ureido group, a thioether group, a sulfonamido group, a sulfonic acid ester group, etc. Incidentally, the carbon constituting the cyclic organic group (the carbon contributing to ring formation) may be carbonyl carbon.

The organic group of R₂₀₁, R₂₀₂ and R₂₀₃ includes an aryl group, an alkyl group, a cycloalkyl group, etc.

At least one of R₂₀₁, R₂₀₂ and R₂₀₃ is preferably an aryl group, and it is more preferred that all of these three members are an aryl group. The aryl group may be a heteroaryl group such as indole residue and pyrrole residue, other than a phenyl group, a naphthyl group, etc. The alkyl group and cycloalkyl group of R₂₀₁ to R₂₀₃ are preferably a linear or branched alkyl group having a carbon number of 1 to 10 and a cycloalkyl group having a carbon number of 3 to 10. The alkyl group is more preferably a methyl group, an ethyl group, an n-propyl group, an i-propyl group, an n-butyl group, etc. The cycloalkyl group is more preferably a cyclopropyl group, a cyclobutyl group, a cyclopentyl group, a cyclohexyl group, a cycloheptyl group, etc. These groups may further have a substituent, and the substituent includes, but is not limited to, a nitro group, a halogen atom such as fluorine atom, a carboxyl group, a hydroxyl group, an amino group, a cyano group, an alkoxy group (preferably having a carbon number of 1 to 15), a cycloalkyl group (preferably having a carbon number of 3 to 15), an aryl group (preferably having a carbon number of 6 to 14), an alkoxycarbonyl group (preferably having a carbon number of 2 to 7), an acyl group (preferably having a carbon number of 2 to 12), an alkoxycarbonyloxy group (preferably having a carbon number of 2 to 7), etc.

In the case where two members out of R₂₀₁ to R₂₀₃ combine to form a ring structure, the ring structure is preferably a structure represented by the following formula (A1):

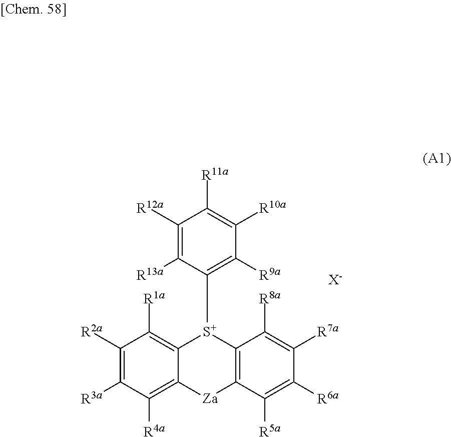

In formula (A1), each of R^{1a} to R^{13a} independently represents a hydrogen atom or a substituent.

It is preferred that from one to three members out of R^{1a} to R^{13a} are not a hydrogen atom, and it is more preferred that one of R^{9a} to R^{13a} is not a hydrogen atom.

Za represents a single bond or a divalent linking group.

X⁻ has the same meaning as Z⁻ in formula (ZI).

Specific examples of R^{1a} to R^{13a} when these are not a hydrogen atom include a halogen atom, a linear, branched or cyclic alkyl group, an alkenyl group, an alkynyl group, an aryl group, a heterocyclic group, a cyano group, a nitro group, a carboxyl group, an alkoxy group, an aryloxy group, a silyloxy group, a heterocyclic oxy group, an acyloxy group, a carbamoyloxy group, an alkoxycarbonyloxy group, an aryloxycarbonyloxy group, an amino group (including an anilino group), an ammonio group, an acylamino group, an aminocarbonylamino group, an alkoxycarbonylamino group, an aryloxycarbonylamino group, a sulfamoylamino group, an alkylsulfonylamino group, an arylsulfonylamino group, a mercapto group, an alkylthio group, an arylthio group, a heterocyclic thio group, a sulfamoyl group, a sulfo group, an alkylsulfinyl group, an arylsulfinyl group, an alkylsulfonyl group, an arylsulfonyl group, an acyl group, an aryloxycarbonyl group, an alkoxycarbonyl group, a carbamoyl group, an arylazo group, a heterocyclic azo group, an imido group, a phosphino group, a phosphinyl group, a phosphinyloxy group, a phosphinylamino group, a phosphono group, a silyl group, a hydrazino group, a ureido group, a boronic acid group (—B(OH)₂), a phosphato group (—OPO(OH)₂), a sulfato group (—OSO₃H), and other known substituents.

In the case where R^{1a} to R^{13a} are not a hydrogen atom, each is preferably a linear, branched or cyclic alkyl group substituted with a hydroxyl group.

The divalent linking group of Za includes an alkylene group, an arylene group, a carbonyl group, a sulfonyl group, a carbonyloxy group, a carbonylamino group, a sulfonylamide group, an ether bond, a thioether bond, an amino group, a disulfide group, —(CH₂)ₙ—CO—, —(CH₂)ₙ—SO₂—, —CH═CH—, an aminocarbonylamino group, an aminosulfonylamino group, etc. (n is an integer of 1 to 3).

Preferable structures when at least one of R₂₀₁, R₂₀₂ and R₂₀₃ is not an aryl group include cation structures such as compounds recited in paragraphs 0047 and 0048 of JP-A-2004-233661 and paragraphs 0040 to 0046 of JP-A-2003-35948, compounds illustrated as formulae (I-1) to (I-70) in U.S. Patent Application Publication No. 2003/0224288A1, and compounds illustrated as formulae (IA-1) to (IA-54) and formulae (IB-1) to (IB-24) in U.S. Patent Application Publication No. 2003/0077540A1.

In formulae (ZII) and (ZIII), each of R₂₀₄ to R₂₀₇ independently represents an aryl group, an alkyl group or a cycloalkyl group.

The aryl group, alkyl group and cycloalkyl group of R₂₀₄ to R₂₀₇ are the same as the aryl group, alkyl group and cycloalkyl group of R₂₀₁ to R₂₀₃ in the compound (ZI).

The aryl group, alkyl group and cycloalkyl group of R₂₀₄ to R₂₀₇ may have a substituent, and the substituent includes those that may be substituted on the aryl group, alkyl group and cycloalkyl group of R₂₀₁ to R₂₀₃ in the compound (ZI).

Z⁻ represents a non-nucleophilic anion, and examples thereof are the same as those of the non-nucleophilic anion of Z⁻ in formula (ZI).

The acid generator further includes compounds represented by the following formulae (ZIV), (ZV) and (ZVI):

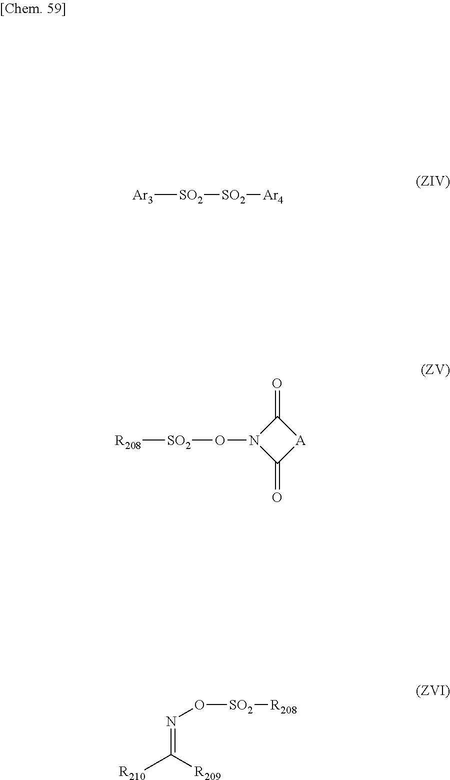

In formulae (ZIV) to (ZVI), each of Ar₃ and Ar₄ independently represents an aryl group.

Each of R₂₀₈, R₂₀₉ and R₂₁₀ independently represents an alkyl group, a cycloalkyl group or an aryl group.

A represents an alkylene group, an alkenylene group or an arylene group.

Specific examples of the aryl group of Ar₃, Ar₄, R₂₀₈, R₂₀₉ and R₂₁₀ are the same as specific examples of the aryl group of R₂₀₁, R₂₀₂ and R₂₀₃ in formula (ZI).

Specific examples of the alkyl group and cycloalkyl group of R₂₀₈, R₂₀₉ and R₂₁₀ are the same as specific examples of the alkyl group and cycloalkyl group of R₂₀₁, R₂₀₂ and R₂₀₃ in formula (ZI).

The alkylene group of A includes an alkylene group having a carbon number of 1 to 12 (for example, a methylene group, an ethylene group, a propylene group, an isopropylene group, a butylene group and an isobutylene group); the alkenylene group of A includes an alkenylene group having a carbon number of 2 to 12 (for example, an ethenylene group, a propenylene group and a butenylene group); and the arylene group of A includes an arylene group having a carbon number of 6 to 10 (for example, a phenylene group, a tolylene group and a naphthylene group).

As the acid generator for use in the present invention, a compound having, as a substituent, a group capable of decomposing by an action of an acid to decrease the solubility in an organic solvent-containing developer may also be preferably used.

Specific examples and preferred examples of the group capable of decomposing by an action of an acid to decrease the solubility in an organic solvent-containing developer are the same as specific examples and preferred examples described above for the acid-decomposable group in the resin (A).

Examples of such an acid generator include the compounds described in JP-A-2005-97254 and JP-A-2007-199692.

Of the acid generators, particularly preferred examples are illustrated below.

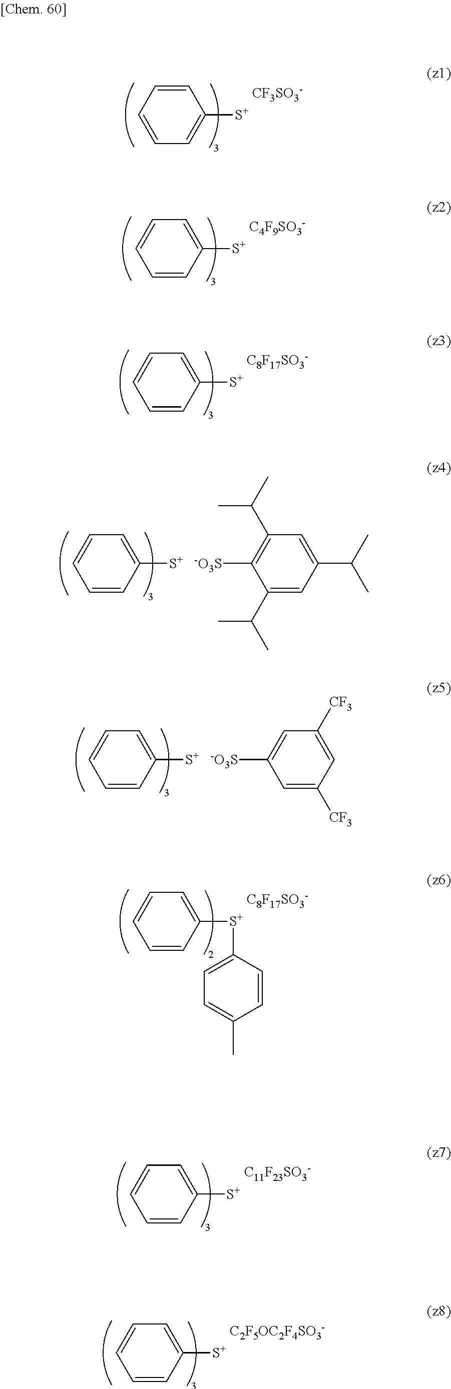

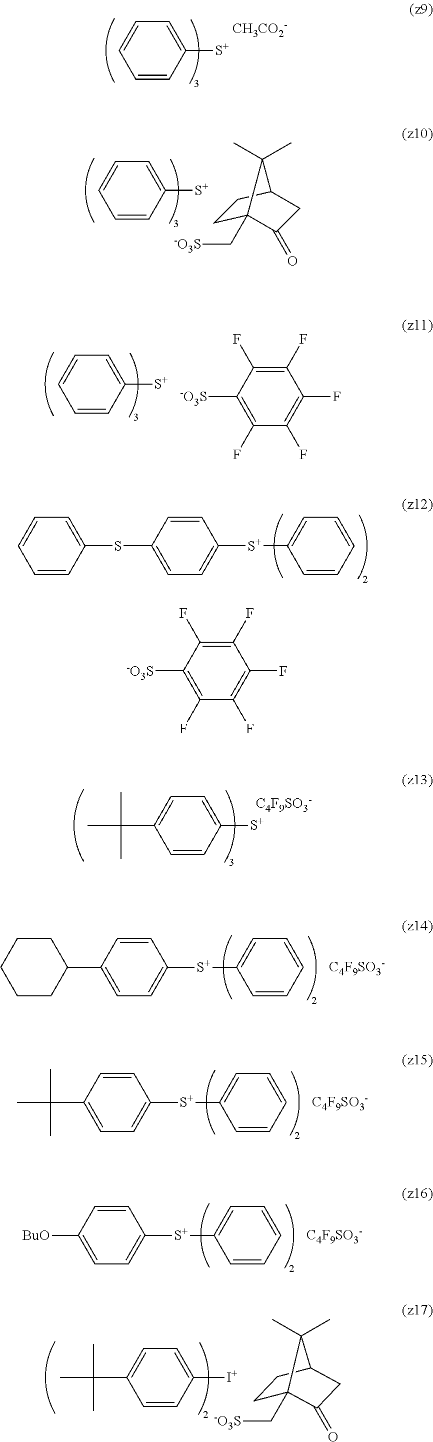

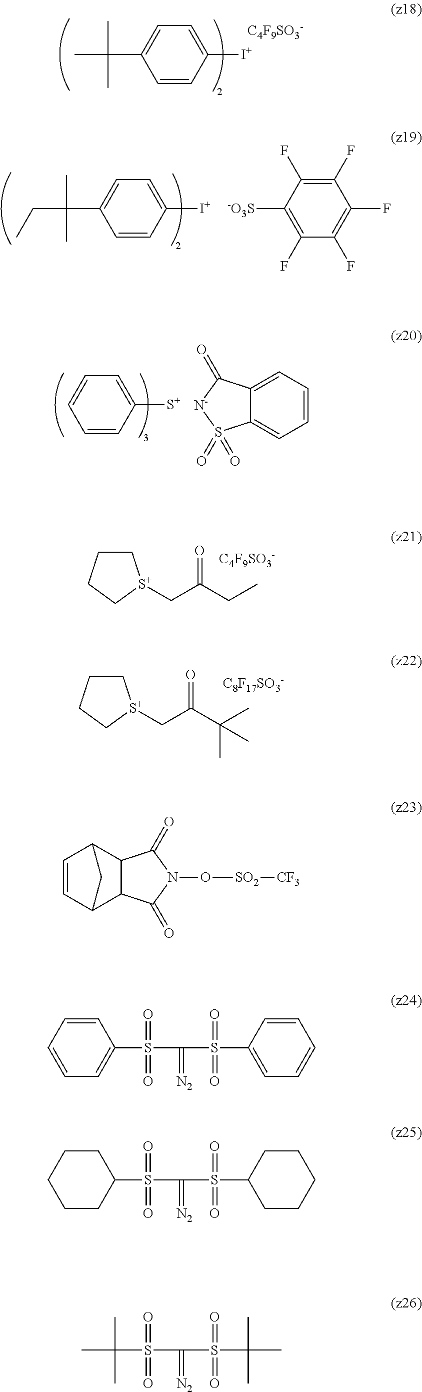

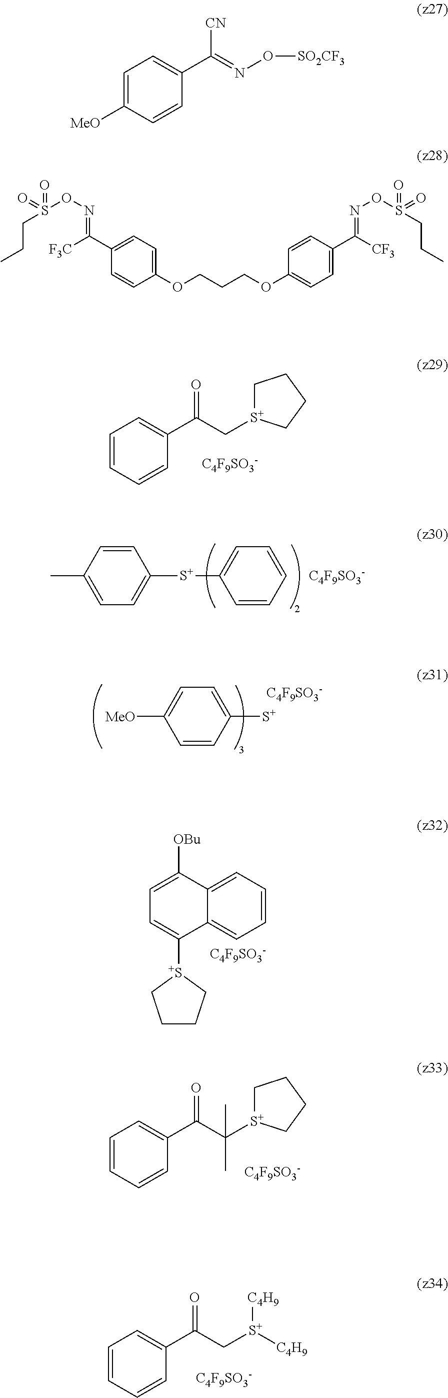

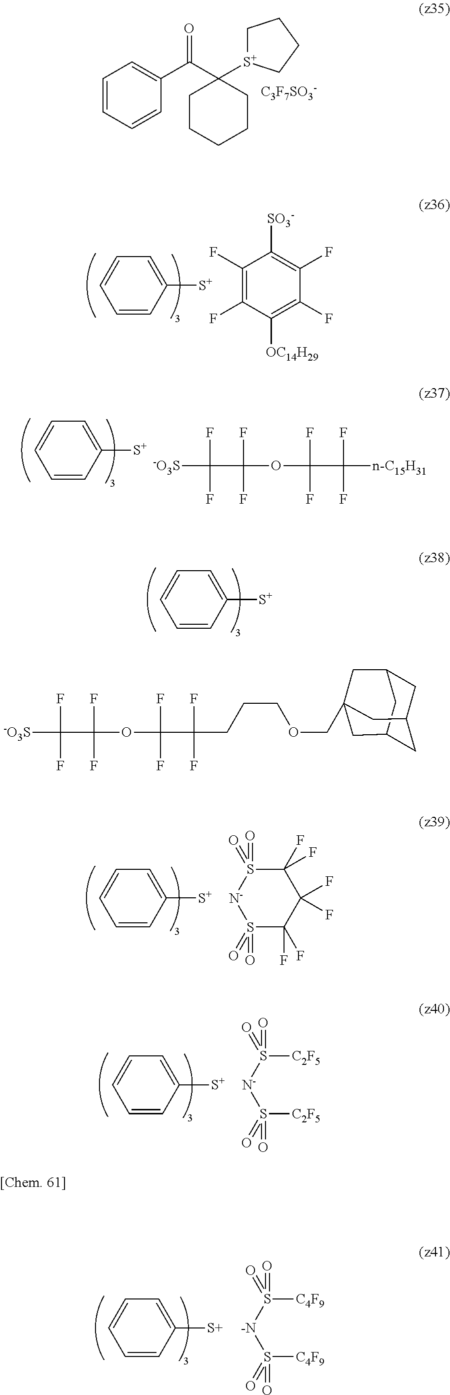

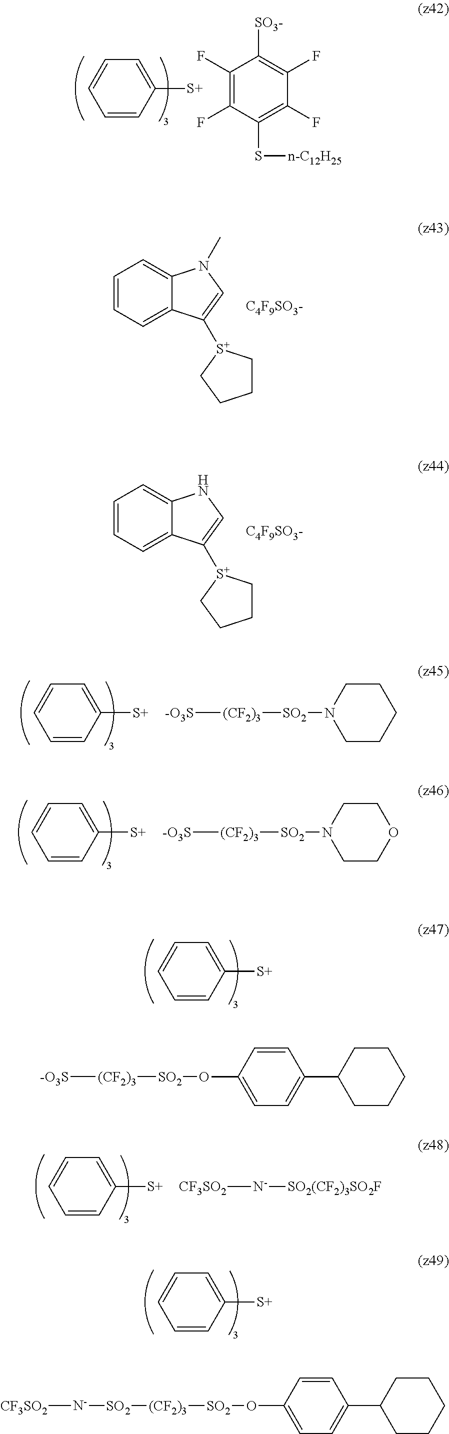

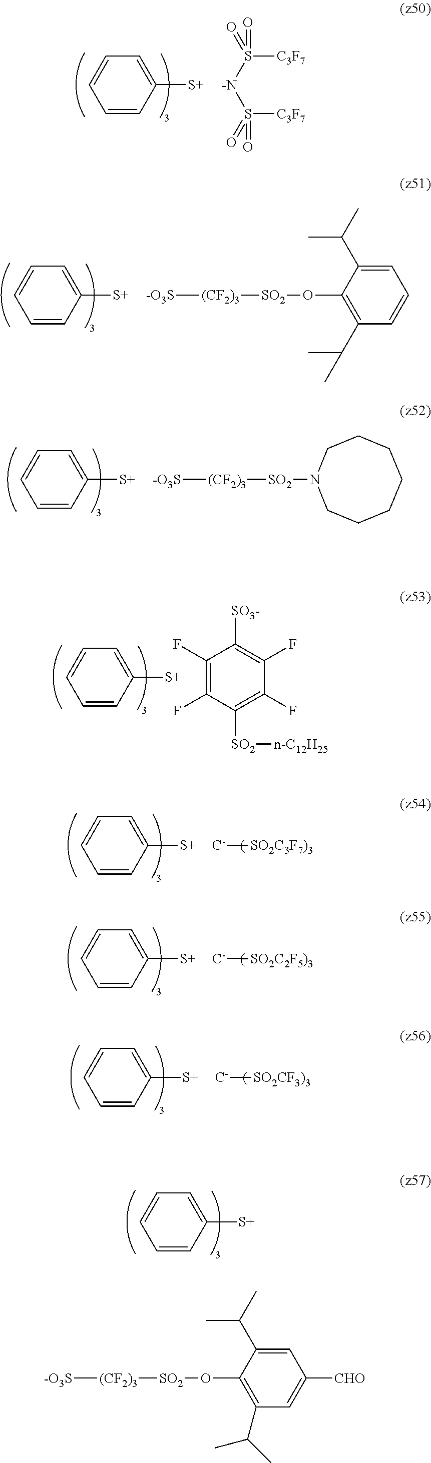

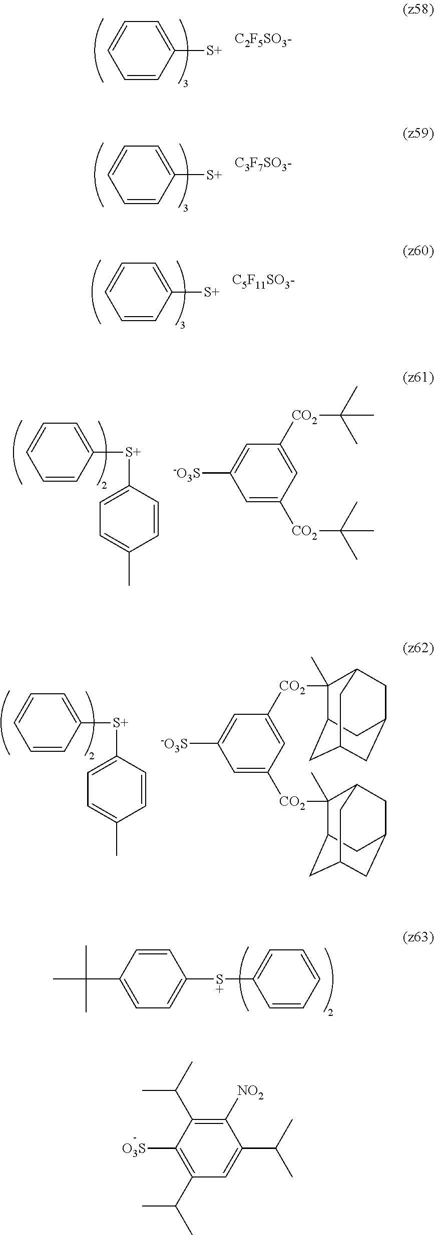

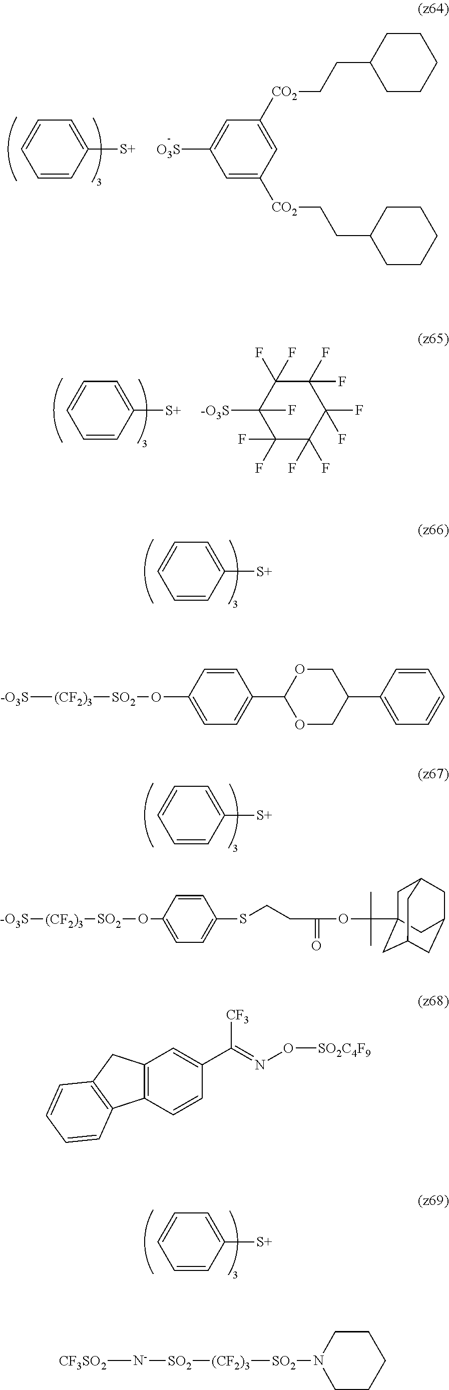

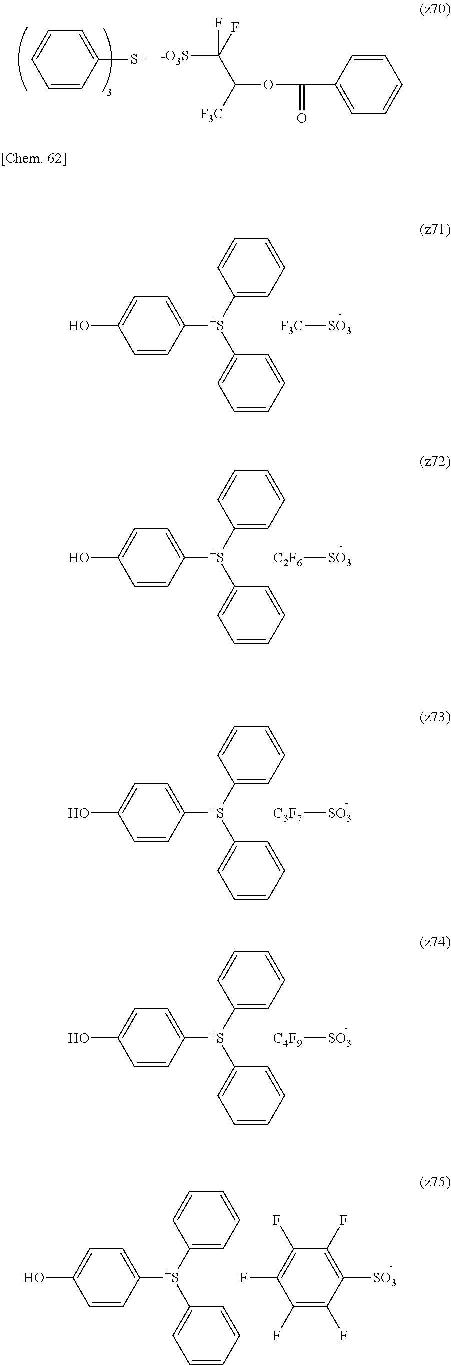

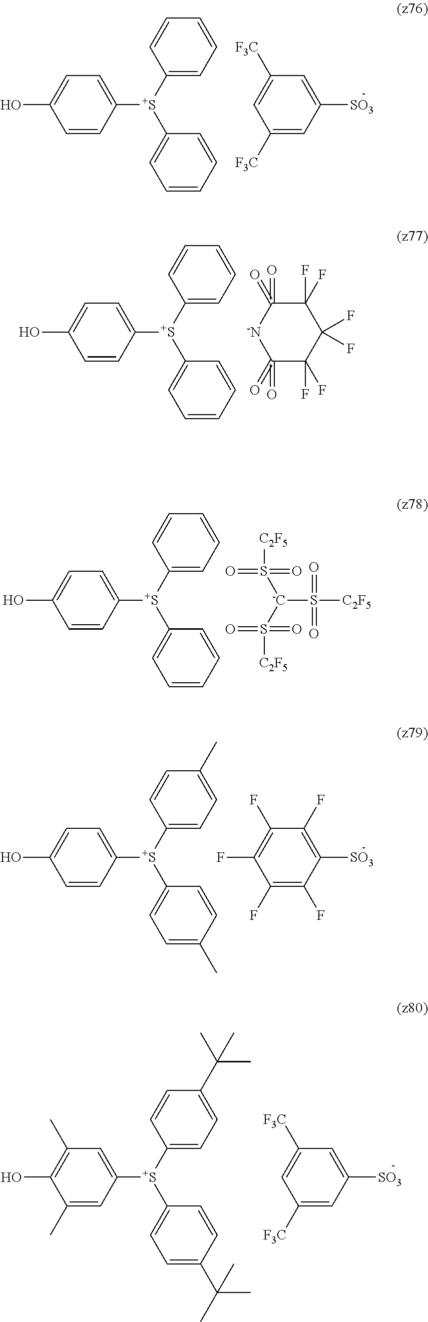

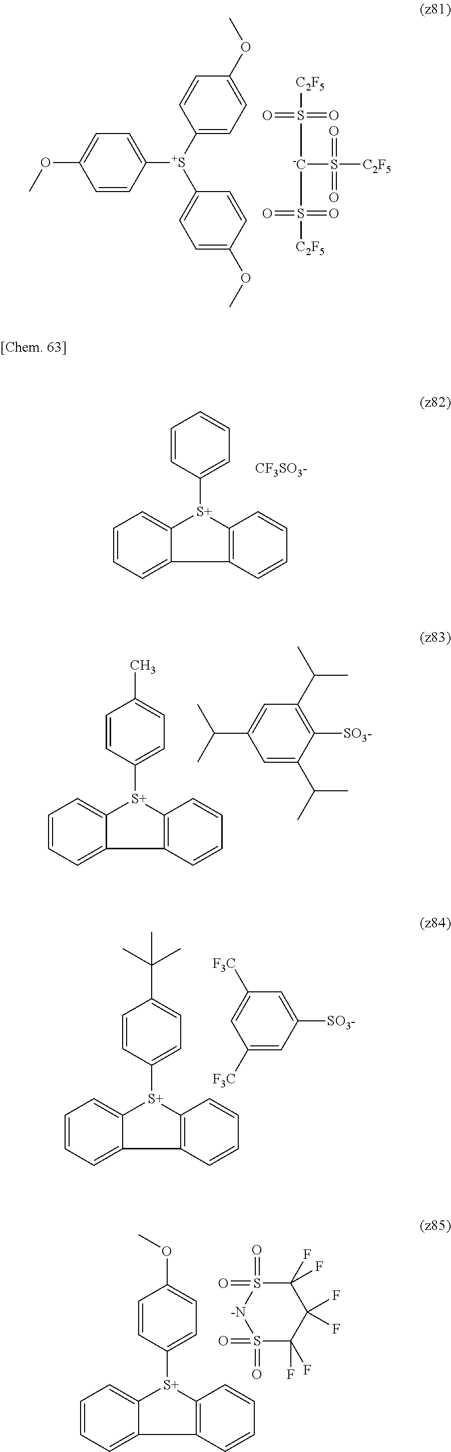

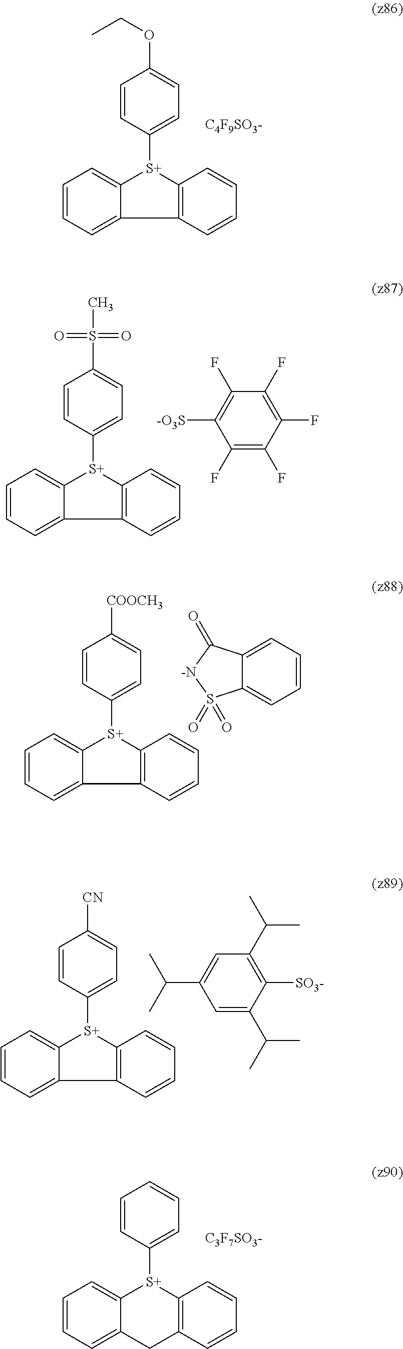

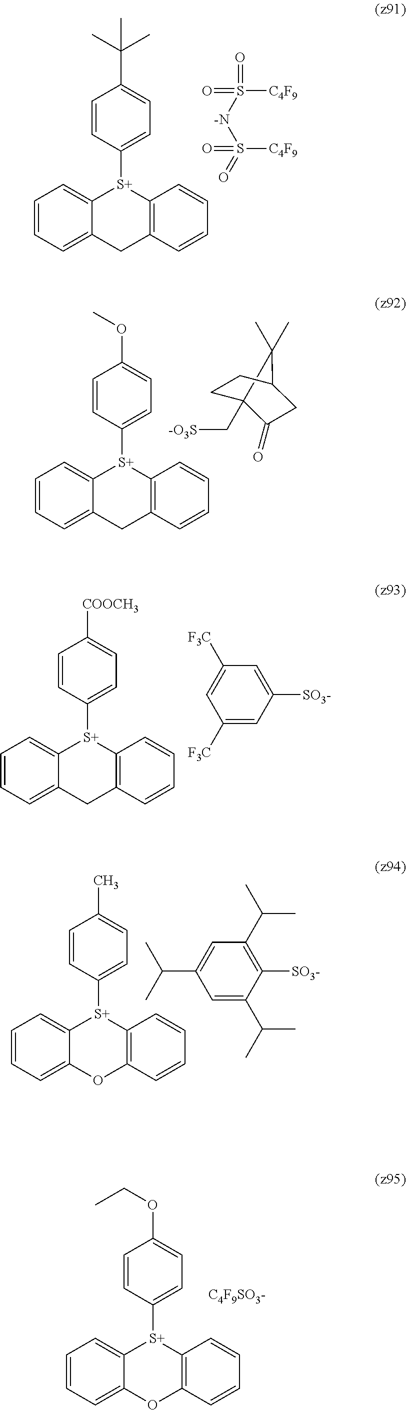

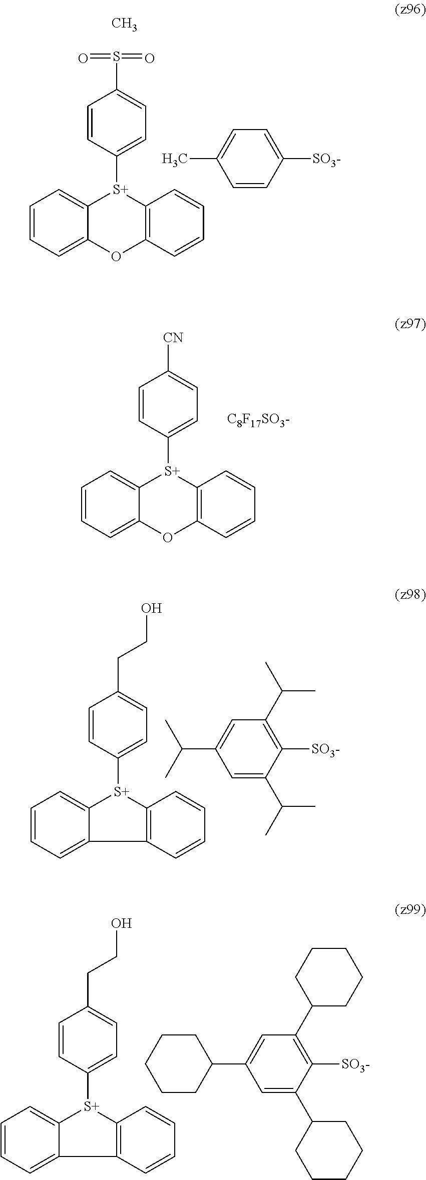

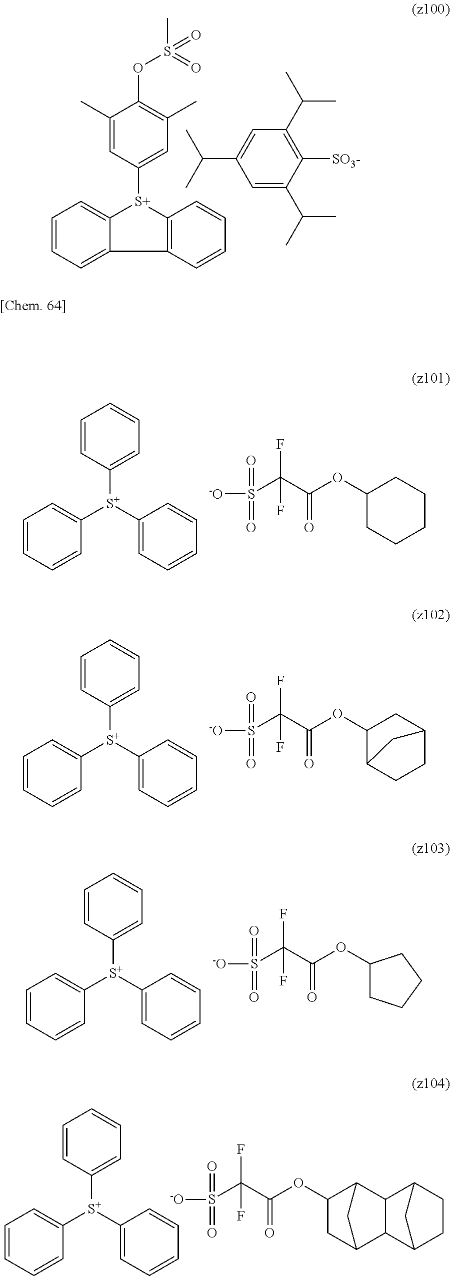

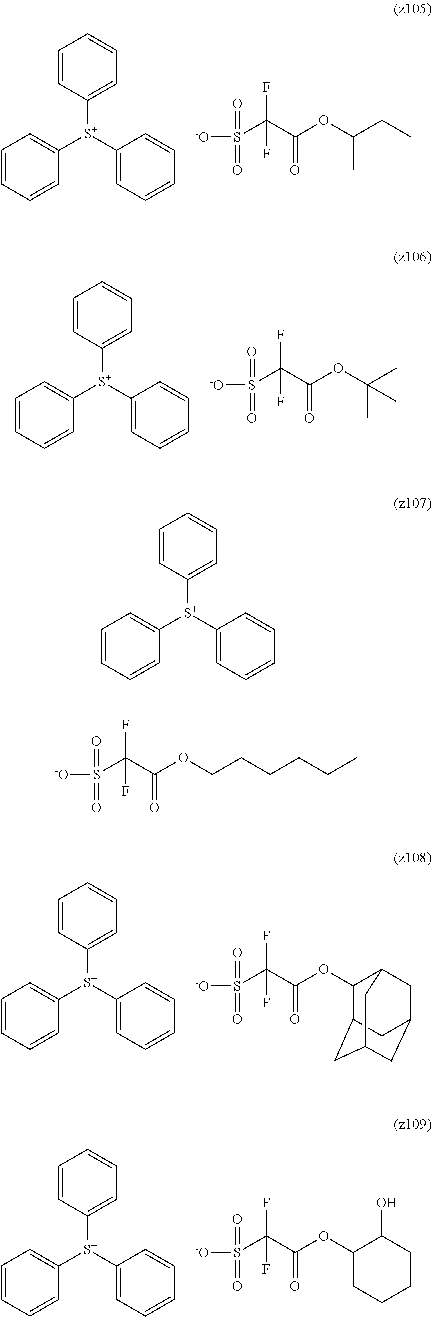

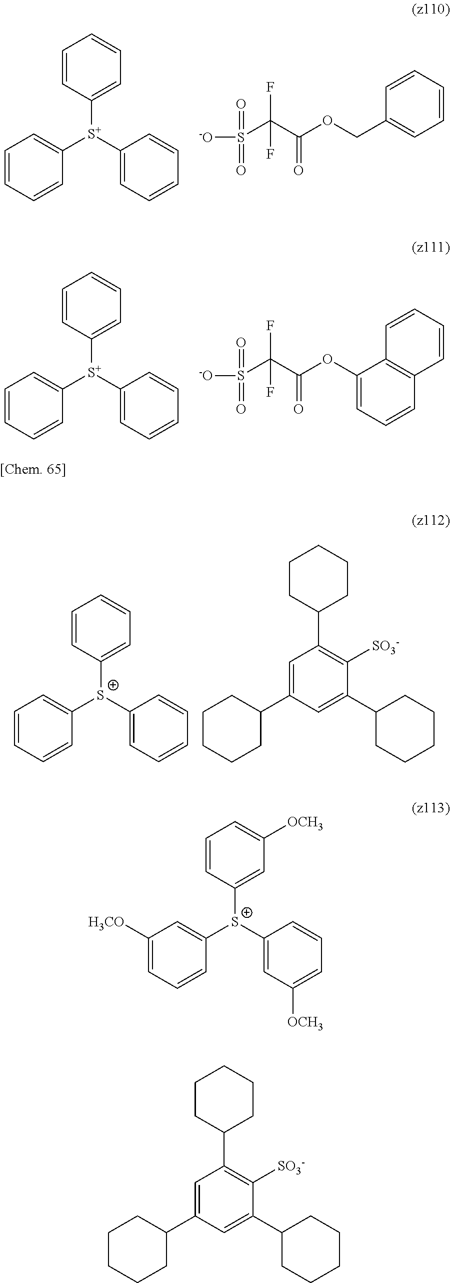

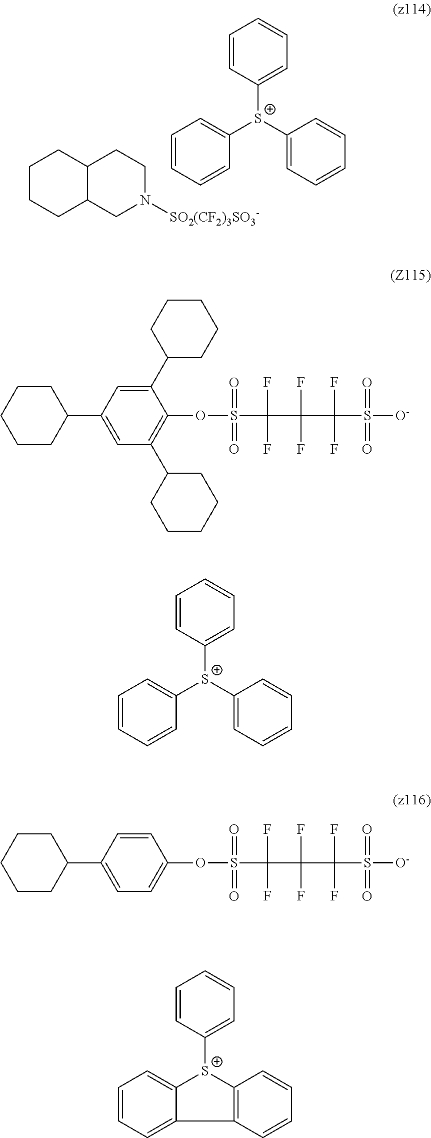

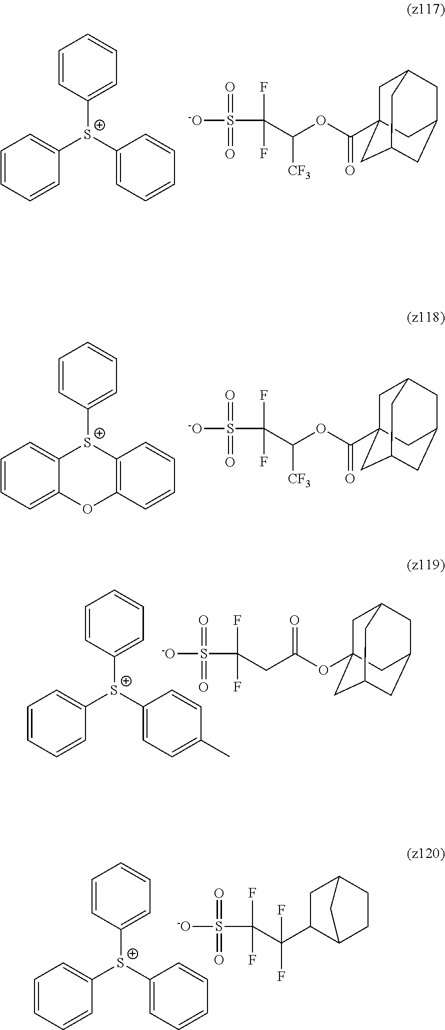

As for the acid generator, one kind of an acid generator may be used alone, or two or more kinds of acid generators may be used in combination.

The content of the acid generator in the composition is preferably from 0.1 to 70 mass %, more preferably from 0.5 to 60 mass %, still more preferably from 1.0 to 60 mass %, based on the total solid content of the composition. If the content is too small, high sensitivity and high LWR performance can be hardly brought out, whereas if the content is too large, high resolution and high LWR performance can be hardly brought out.

### [3] Basic Compound

The actinic ray-sensitive or radiation-sensitive resin composition according to the present invention preferably further contains (D) a basic compound. The basic compound (D) is a compound having stronger basicity than phenol. The basic compound is preferably an organic basic compound, more preferably a nitrogen-containing basic compound.

The nitrogen-containing basic compound that can be used is not particularly limited but, for example, the compounds classified into the following (1) to (7) may be used.

### (1) Compound Represented by Formula (BS-1)

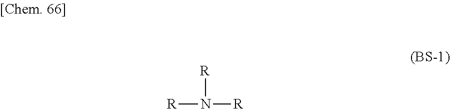

In formula (BS-1), each R independently represents a hydrogen atom or an organic group, provided that at least one of three R is an organic group. This organic group is a linear or branched alkyl group, a monocyclic or polycyclic cycloalkyl group, an aryl group or an aralkyl group.

The carbon number of the alkyl group as R is not particularly limited but is usually from 1 to 20, preferably from 1 to 12.

The carbon number of the cycloalkyl group as R is not particularly limited but is usually from 3 to 20, preferably from 5 to 15.

The carbon number of the aryl group as R is not particularly limited but is usually from 6 to 20, preferably from 6 to 10. Specifically, the aryl group includes a phenyl group, a naphthyl group, etc.

The carbon number of the aralkyl group as R is not particularly limited but is usually from 7 to 20, preferably from 7 to 11. Specifically, the aralkyl group includes a benzyl group, etc.

In the alkyl group, cycloalkyl group, aryl group and aralkyl group as R, a hydrogen atom may be substituted for by a substituent. This substituent includes an alkyl group, a cycloalkyl group, an aryl group, an aralkyl group, a hydroxy group, a carboxy group, an alkoxy group, an aryloxy group, an alkylcarbonyloxy group, an alkyloxycarbonyl group, etc.

In the compound represented by formula (BS-1), it is preferred that at least two R are an organic group.

Specific examples of the compound represented by formula (BS-1) include tri-n-butylamine, tri-n-pentylamine, tri-n-octylamine, tri-n-decylamine, triisodecylamine, dicyclohexylmethylamine, tetradecylamine, pentadecylamine, hexadecylamine, octadecylamine, didecylamine, methyloctadecylamine, dimethylundecylamine, N,N-dimethyldodecylamine, methyldioctadecylamine, N,N-dibutylaniline, N,N-dihexylaniline, 2,6-diisopropylaniline, and 2,4,6-tri(tert-butyl)aniline.

The basic compound represented by formula (BS-1) is preferably a compound where at least one R is an alkyl group substituted with a hydroxy group. Specifically, this compound includes, for example, triethanolamine and N,N-dihydroxyethylaniline.

The alkyl group as R may contain an oxygen atom in the alkyl chain, i.e., an oxyalkylene chain may be formed. The oxyalkylene chain is preferably —CH₂CH₂O—. Specifically, this compound includes, for example, tris(methoxyethoxyethyl)amine and compounds illustrated in U.S. Pat. No. 6,040,112, column 3, line 60 et seq.

Of the basic compounds represented by Formula (BS-1), those having a hydroxyl group, an oxygen atom, etc. include, for example, the followings.

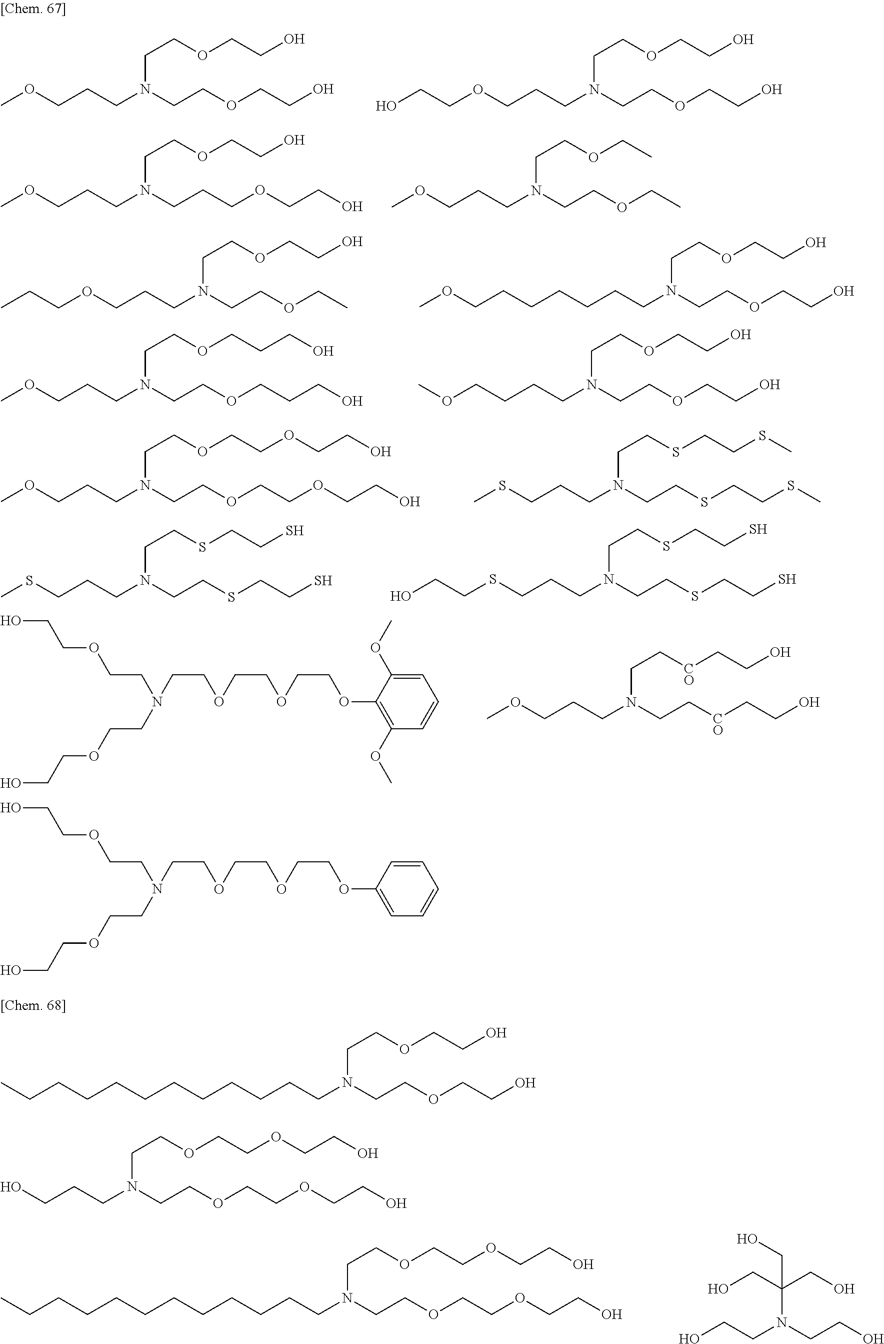

### (2) Compound Having a Nitrogen-Containing Heterocyclic Structure

The nitrogen-containing heterocyclic ring may or may not have aromaticity, may contain a plurality of nitrogen atoms, and may further contain a heteroatom other than nitrogen. Specifically, the compound includes, for example, a compound having an imidazole structure (e.g., 2-phenylbenzimidazole, 2,4,5-triphenylimidazole), a compound having a piperidine structure [e.g., N-hydroxyethylpiperidine, bis(1,2,2,6,6-pentamethyl-4-piperidyl)sebacate], a compound having a pyridine structure (e.g., 4-dimethylaminopyridine), and a compound having an antipyrine structure (e.g., antipyrine, hydroxyantipyrine).

Preferred examples of the compound having a nitrogen-containing heterocyclic structure include guanidine, aminopyridine, aminoalkylpyridine, aminopyrrolidine, indazole, imidazole, pyrazole, pyrazine, pyrimidine, purine, imidazoline, pyrazoline, piperazine, aminomorpholine, and aminoalkylmorpholine. These compounds may further have a substituent.

Preferable substituents include, for example, an amino group, an aminoalkyl group, an alkylamino group, an aminoaryl group, an arylamino group, an alkyl group, an alkoxy group, an acyl group, an acyloxy group, an aryl group, an aryloxy group, a nitro group, a hydroxyl group, and a cyano group.

Particularly preferable basic compounds include, for example, imidazole, 2-methylimidazole, 4-methylimidazole, N-methylimidazole, 2-phenylimidazole, 4,5-diphenylimidazole, 2,4,5-triphenylimidazole, 2-aminopyridine, 3-aminopyridine, 4-aminopyridine, 2-dimethylaminopyridine, 4-dimethylaminopyridine, 2-diethylaminopyridine, 2-(aminomethyl)pyridine, 2-amino-3-methylpyridine, 2-amino-4-methylpyridine, 2-amino-5-methylpyridine, 2-amino-6-methylpyridine, 3-aminoethylpyridine, 4-aminoethylpyridine, 3-aminopyrrolidine, piperazine, N-(2-aminoethyl)piperazine, N-(2-aminoethyl)piperidine, 4-amino-2,2,6,6-tetramethylpiperidine, 4-piperidinopiperidine, 2-iminopiperidine, 1-(2-aminoethyl)pyrrolidine, pyrazole, 3-amino-5-methylpyrazole, 5-amino-3-methyl-1-p-tolylpyrazole, pyrazine, 2-(aminomethyl)-5-methylpyrazine, pyrimidine, 2,4-diaminopyrimidine, 4,6-dihydroxypyrimidine, 2-pyrazoline, 3-pyrazoline, N-aminomorpholine, and N-(2-aminoethyl)morpholine.

In addition, a compound having two or more ring structures is also suitably used. Specifically, the compound includes, for example, 1,5-diazabicyclo[4.3.0]non-5-ene and 1,8-diazabicyclo[5.4.0]-undec-7-ene.

### (3) Amine Compound Having a Phenoxy Group

The amine compound having a phenoxy group is a compound having a phenoxy group at the terminal opposite the N atom of the alkyl group contained in an amine compound. The phenoxy group may have, for example, a substituent such as alkyl group, alkoxy group, halogen atom, cyano group, nitro group, carboxyl group, carboxylic acid ester group, sulfonic acid ester group, aryl group, aralkyl group, acyloxy group and aryloxy group.

This compound more preferably has at least one oxyalkylene chain between the phenoxy group and the nitrogen atom. The number of oxyalkylene chains per molecule is preferably from 3 to 9, more preferably from 4 to 6. Among oxyalkylene chains, —CH₂CH₂O— is preferred.

Specific examples of the compound include 2-[2-{2-(2,2-dimethoxy-phenoxyethoxy)ethyl}-bis-(2-methoxyethyl)]-amine and Compounds (C1-1) to (C3-3) illustrated in paragraph [0066] of U.S. Patent Application Publication No. 2007/0224539A1.

The phenoxy group-containing amine compound is obtained, for example, by reacting a primary or secondary amine having a phenoxy group with a haloalkyl ether under heating and after adding an aqueous solution of a strong base such as sodium hydroxide, potassium hydroxide and tetraalkylammonium, extracting the reaction product with an organic solvent such as ethyl acetate and chloroform. The phenoxy group-containing amine compound may also be obtained by reacting a primary or secondary amine with a haloalkyl ether having a phenoxy group at the terminal under heating and after adding an aqueous solution of a strong base such as sodium hydroxide, potassium hydroxide and tetraalkylammonium, extracting the reaction product with an organic solvent such as ethyl acetate and chloroform.

### (4) Ammonium Salt

An ammonium salt may also be appropriately used as the basic compound.

The cation of the ammonium salt is preferably a tetraalkylammonium cation substituted with an alkyl group having a carbon number of 1 to 18, more preferably tetramethylammonium cation, tetraethylammonium cation, tetra(n-butyl)ammonium cation, tetra(n-heptyl)ammonium cation, tetra(n-octyl)ammonium cation, dimethylhexadecylammonium cation, benzyltrimethyl cation, etc., and most preferably tetra(n-butyl)ammonium cation.

The anion of the ammonium salt includes, for example, a hydroxide, a carboxylate, a halide, a sulfonate, a borate, and a phosphate. Among these, a hydroxide and a carboxylate are preferred.

The halide is preferably chloride, bromide or iodide, among others.

The sulfonate is preferably an organic sulfonate having a carbon number of 1 to 20, among others. The organic sulfonate includes, for example, an alkylsulfonate having a carbon number of 1 to 20, and an arylsulfonate.

The alkyl group contained in the alkylsulfonate may have a substituent, and this substituent includes, for example, a fluorine atom, a chlorine atom, a bromine atom, an alkoxy group, an acyl group, and an aryl group. Specifically, the alkylsulfonate includes methanesulfonate, ethanesulfonate, butanesulfonate, hexanesulfonate, octanesulfonate, benzylsulfonate, trifluoromethanesulfonate, pentafluoroethanesulfonate, and nonafluorobutanesulfonate.

The aryl group contained in the arylsulfonate includes, for example, a phenyl group, a naphthyl group, and an anthryl group. Such an aryl group may have a substituent, and this substituent is preferably, for example, a linear or branched alkyl group having a carbon number of 1 to 6, or a cycloalkyl group having a carbon number of 3 to 6. Specifically, for example, a methyl group, an ethyl group, an n-propyl group, an isopropyl group, an n-butyl group, an i-butyl group, a tert-butyl group, an n-hexyl group and a cyclohexyl group are preferred. Other substituents include an alkoxy group having a carbon number of 1 to 6, a halogen atom, cyano, nitro, an acyl group, and an acyloxy group.

The carboxylate may be either an aliphatic carboxylate or an aromatic carboxylate and includes an acetate, a lactate, a pyruvate, a trifluoroacetate, an adamantanecarboxylate, a hydroxyadamantanecarboxylate, a benzoate, a naphthoate, a salicylate, a phthalate, a phenolate, etc. Among these, a benzoate, a naphthoate, a phenolate, etc. are preferred, and a benzoate is most preferred.

In this case, the ammonium salt is preferably, for example, tetra(n-butyl)ammonium benzoate or tetra(n-butyl)ammonium phenolate.

In the case of a hydroxide, the ammonium salt is preferably a tetraalkylammonium hydroxide having a carbon number of 1 to 8 (a tetraalkylammonium hydroxide such as tetramethylammonium hydroxide, tetraethylammonium hydroxide, tetra-(n-butyl)ammonium hydroxide), among others.

(5) (PA) Compound having a proton acceptor functional group and undergoing decomposition upon irradiation with an actinic ray or radiation to generate a compound reduced in or deprived of the proton acceptor property or changed from proton acceptor-functioning to acidic

The composition according to the present invention may further contain, as the basic compound, a compound having a proton acceptor functional group and undergoing decomposition upon irradiation with an actinic ray or radiation to generate a compound reduced in or deprived of the proton acceptor property or changed from proton acceptor-functioning to acidic [hereinafter, sometimes referred to as compound (PA)].

As for the compound (PA) having a proton acceptor functional group and undergoing decomposition upon irradiation with an actinic ray or radiation to generate a compound reduced in or deprived of the proton acceptor property or changed from proton acceptor-functioning to acidic, refer to JP-A-2012-32762, paragraphs [0379] to [0425] (corresponding to U.S. Patent Application Publication No. 2012/0003590, paragraphs [0386] to [0435]), the contents of which are incorporated into the description of the present invention.

### (6) Guanidine Compound

The composition of the present invention may further contain a guanidine compound having a structure represented by the following formula:

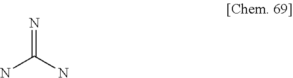

The guanidine compound exhibits strong basicity because thanks to three nitrogens, dispersion of positive electric charges of a conjugate acid is stabilized.

As for the basicity of the guanidine compound (A) for use in the present invention, the pKa of the conjugate acid is preferably 6.0 or more, more preferably from 7.0 to 20.0 in view of high neutralization reactivity with an acid and excellent roughness characteristics, and still more preferably from 8.0 to 16.0.

Such strong basicity makes it possible to suppress diffusion of an acid and contribute to formation of an excellent pattern profile.

The “pKa” as used herein is pKa in an aqueous solution and is the value described, for example, in Kagaku Binran (Chemical Handbook) (II) (4th revised edition, compiled by The Chemical Society of Japan, Maruzen (1993)), and as this value is lower, the acid strength is higher. Specifically, the acid dissociation constant at 25° C. is measured using an aqueous infinite dilution solution, whereby pKa in an aqueous solution can be actually measured. Alternatively, a value based on Hammett's substituent constants and data base containing values known in publications can be determined by computation using the following software package 1. The pKa values referred to in the description of the present invention all are a value determined by computation using this software package.

Software Package 1: Advanced Chemistry Development (ACD/Labs) Software V8.14 for Solaris (1994-2007 ACD/Labs).

In the present invention, the log P is a logarithmic value of the n-octanol/water partition coefficient (P) and is an effective parameter capable of characterizing the hydrophilicity/hydrophobicity for compounds over a wide range. The partition coefficient is generally determined by computation but not from experiments and in the present invention, a value computed using CS ChemDraw Ultra Ver. 8.0 software package (Crippen's fragmentation method) is employed.

The log P of the guanidine compound (A) is preferably 10 or less. With a value not more than this range, the compound can be uniformly incorporated into the resist film.

The log P of the guanidine compound (A) for use in the present invention is preferably from 2 to 10, more preferably from 3 to 8, still more preferably 4 to 8.

The guanidine compound (A) for use in the present invention preferably contains no nitrogen atom except for in the guanidine structure.

Specific examples of the guanidine compound are illustrated below, but the present invention is not limited thereto.

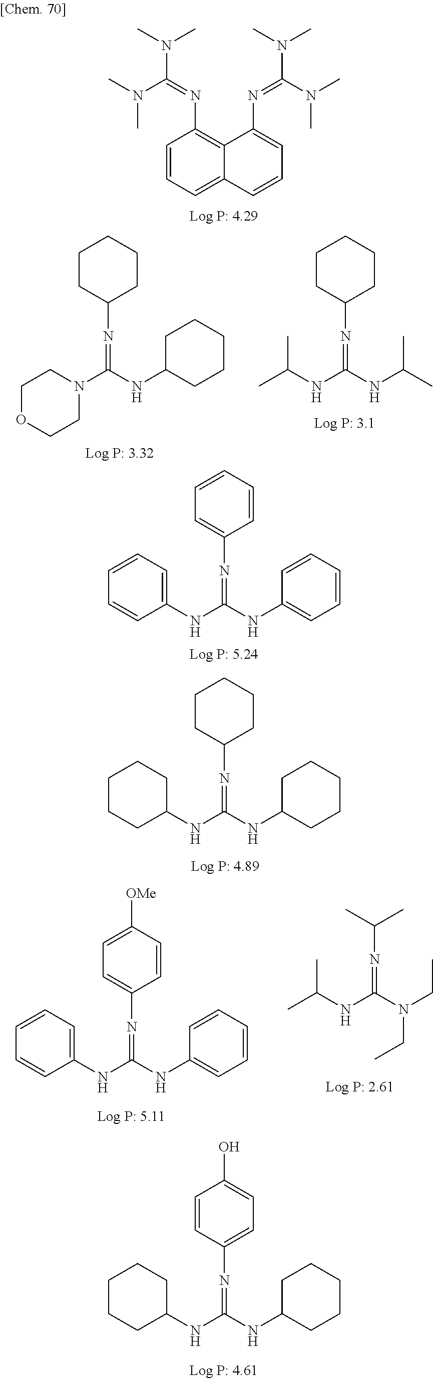

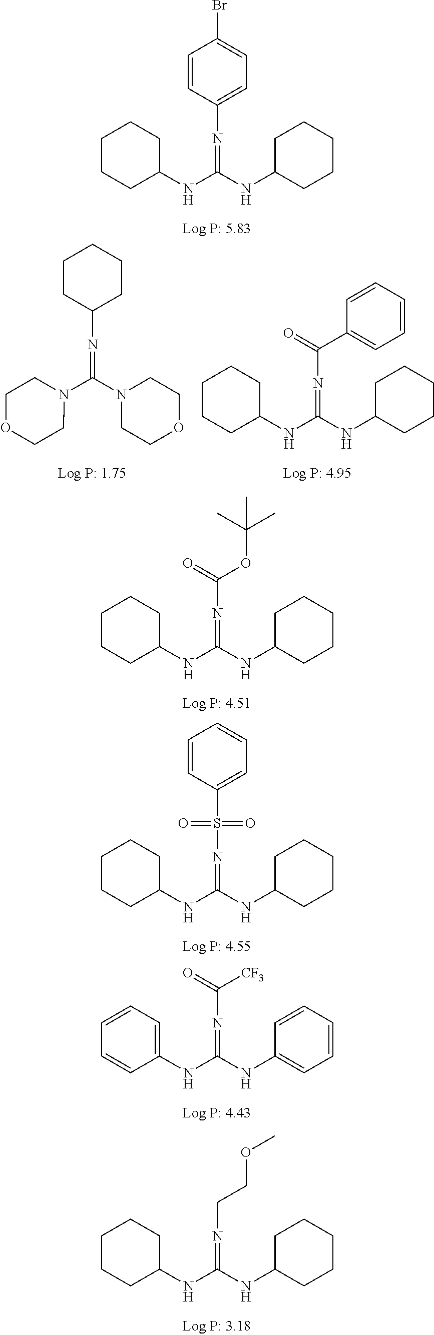

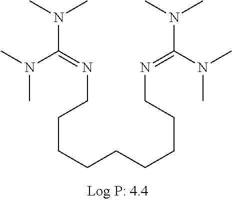

### (7) Low Molecular Compound Having a Nitrogen Atom and Having a Group Capable of Leaving by an Action of an Acid

The composition of the present invention may contain a low molecular compound having a nitrogen atom and having a group capable of leaving by an action of an acid (hereinafter, sometimes referred to as “low molecular compound (D)” or “compound (D)”). The low molecular compound (D) preferably has basicity after the group capable of leaving by an action of an acid is eliminated.

As for the low molecular compound (D), refer to JP-A-2012-133331, paragraphs [0324] to [0337], the contents of which are incorporated into the description of the present invention.

In the present invention, as for the low molecular compound (D), one compound may be used alone, or two or more compounds may be mixed and used.

Other examples of the basic compound which can be used in the composition of the present invention include the compounds synthesized in Examples of JP-A-2002-363146 and the compounds described in paragraph 0108 of JP-A-2007-298569.

A photosensitive basic compound may also be used as the basic compound. The photosensitive basic compound which can be used includes, for example, the compounds described in JP-T-2003-524799 (the term “JP-T” as used herein means a “published Japanese translation of a PCT patent application”) and J. Photopolym. Sci. & Tech., Vol. 8, pp. 543-553 (1995).

The molecular weight of the basic compound is usually from 100 to 1,500, preferably from 150 to 1,300, more preferably from 200 to 1,000.

As for the basic compound (D), one kind of a compound may be used alone, or two or more kinds of compounds may be used in combination.

The content of the basic compound (D) in the composition according to the present invention is preferably from 0.01 to 8.0 mass %, more preferably from 0.1 to 5.0 mass %, still more preferably from 0.2 to 4.0 mass %, based on the total solid content of the composition.

The molar ratio of the basic compound (D) to the acid generator is preferably from 0.01 to 10, more preferably from 0.05 to 5, still more preferably from 0.1 to 3. If the molar ratio is excessively large, the sensitivity and/or resolution may be reduced, whereas if the molar ratio is excessively small, thinning of a pattern may occur between exposure and heating (post-baking). The molar ratio is more preferably from 0.05 to 5, still more preferably from 0.1 to 3.

### [4] Solvent

The actinic ray-sensitive or radiation-sensitive composition according to the present invention preferably contains a solvent. The solvent preferably contains at least either one of (S1) a propylene glycol monoalkyl ether carboxylate and (S2) at least one member selected from the group consisting of a propylene glycol monoalkyl ether, a lactic acid ester, an acetic acid ester, an alkoxypropionic acid ester, a chain ketone, a cyclic ketone, a lactone and an alkylene carbonate. The solvent may further contain a component other than the components (S1) and (S2).

The present inventors have found that when such a solvent is used in combination with the above-described resin, the coatability of the composition is enhanced and at the same time, a pattern reduced in the number of development defects can be formed. The reason therefor is not necessarily clarified, but the present inventors consider that since the solvent exhibits a good balance among solubility, boiling point and viscosity of the resin, unevenness in the thickness of a composition film or generation, etc. of a precipitate during spin coating can be suppressed.

The component (S1) is preferably at least one member selected from the group consisting of propylene glycol monomethyl ether acetate, propylene glycol monomethyl ether propionate and propylene glycol monoethyl ether acetate, more preferably propylene glycol monomethyl ether acetate.

As the component (S2), the followings are preferred.

The propylene glycol monoalkyl ether is preferably propylene glycol monomethyl ether or propylene glycol monoethyl ether.

The lactic acid ester is preferably ethyl lactate, butyl lactate or propyl lactate.

The acetic acid ester is preferably methyl acetate, ethyl acetate, butyl acetate, isobutyl acetate, propyl acetate, isoamyl acetate, methyl formate, ethyl formate, butyl formate, propyl formate or 3-methoxybutyl acetate.

The alkoxypropionic acid ester is preferably methyl 3-methoxypropionate (MMP) or ethyl 3-ethoxypropionate (EEP).

The chain ketone is preferably 1-octanone, 2-octanone, 1-nonanone, 2-nonanone, acetone, 4-heptanone, 1-hexanone, 2-hexanone, diisobutyl ketone, phenylacetone, methyl ethyl ketone, methyl isobutyl ketone, acetyl acetone, acetonyl acetone, ionone, diacetonyl alcohol, acetyl carbinol, acetophenone, methyl naphthyl ketone or methyl amyl ketone.

The cyclic ketone is preferably methylcyclohexanone, isophorone or cyclohexanone.

The lactone is preferably γ-butyrolactone.

The alkylene carbonate is preferably propylene carbonate.

The component (S2) is more preferably propylene glycol monomethyl ether, ethyl lactate, ethyl 3-ethoxypropionate, methyl amyl ketone, cyclohexanone, butyl acetate, pentyl acetate, γ-butyrolactone or propylene carbonate.

As the component (S2), a compound having a flash point (hereinafter, sometimes referred to as fp) of 37° C. or more is preferably used. This component (S2) is preferably propylene glycol monomethyl ether (fp: 47° C.), ethyl lactate (fp: 53° C.), ethyl 3-ethoxypropionate (fp: 49° C.), methyl amyl ketone (fp: 42° C.), cyclohexanone (fp: 44° C.), pentyl acetate (fp: 45° C.), γ-butyrolactone (fp: 101° C.) or propylene carbonate (fp: 132° C.), more preferably propylene glycol monoethyl ether, ethyl lactate, pentyl acetate or cyclohexanone, still more preferably propylene glycol monoethyl ether or ethyl lactate. The “flash point” as used herein means the value described in the reagent catalogue of Tokyo Chemical Industry Co., Ltd. or Sigma-Aldrich Corporation.

The solvent preferably contains the component (S1). The solvent is more preferably composed of substantially only the component (S1) or is a mixed solvent of the component (S1) and another component. In the latter case, the solvent still more preferably contains both the component (S1) and the component (S2).

The mass ratio between the component (S1) and the component (S2) is preferably from 100:0 to 15:85, more preferably from 100:0 to 40:60, still more preferably from 100:0 to 60:40. In other words, it is preferred that the solvent is composed of only the component (S1) or that the solvent contains both the component (S1) and the component (S2) and the mass ratio therebetween is as follows. More specifically, in the latter case, the mass ratio of the component (S1) to the component (S2) is preferably 15/85 or more, more preferably 40/60 or more, still more preferably 60/40 or more. When such a configuration is employed, the number of development defects can be more reduced.

In this connection, when the solvent contains both the component (S1) and the component (S2), the mass ratio of the component (S1) to the component (S2) is, for example, 99/1 or less.

As described above, the solvent may further contain a component other than the components (S1) and (S2). In this case, the content of the component other than the components (S1) and (S2) is preferably from 5 to 30 mass % relative to the total amount of the solvent.

The content of the solvent in the composition is preferably determined such that the solid content concentration of all components becomes from 2 to 30 mass %, more preferably from 3 to 20 mass %. By determining the content in this way, the coatability of the composition can be more enhanced.

### [5] Surfactant

The actinic ray-sensitive or radiation-sensitive resin composition of the present invention preferably further contains a surfactant, more preferably contains any one of fluorine- and/or silicon-containing surfactants (a fluorine-containing surfactant, a silicon-containing surfactant, and a surfactant containing both a fluorine atom and a silicon atom), or two or more thereof.

When the actinic ray-sensitive or radiation-sensitive resin composition of the present invention contains the above-described surfactant, at the time of using an exposure light source of 250 nm or less, particularly 220 nm or less, a resist pattern with good sensitivity and resolution and little adherence and development defects can be obtained.

The fluorine-containing and/or silicon-containing surfactants include, for example, the surfactants described in JP-A-62-36663, JP-A-61-226746, JP-A-61-226745, JP-A-62-170950, JP-A-63-34540, JP-A-7-230165, JP-A-8-62834, JP-A-9-54432, JP-A-9-5988, JP-A-2002-277862 and U.S. Pat. Nos. 5,405,720, 5,360,692, 5,529,881, 5,296,330, 5,436,098, 5,576,143, 5,294,511 and 5,824,451, and the commercially available surfactant described below may also be used as it is.

The commercially available surfactant that can be used includes, for example, a fluorine-containing surfactant or a silicon-containing surfactant, such as EFtop EF301 and EF303 (produced by Shin-Akita Kasei K.K.); Florad FC430, 431 and 4430 (produced by Sumitomo 3M Inc.); Megaface F171, F173, F176, F189, F113, F110, F177, F120 and R08 (produced by DIC Corporation); SurfIon S-382, SC101, 102, 103, 104, 105 and 106 (produced by Asahi Glass Co., Ltd.); and Troysol S-366 (produced by Troy Chemical Industries, Inc.); GF-300 and GF-150 (produced by Toagosei Co., Ltd.); SurfIon S-393 (produced by Seimi Chemical Co., Ltd.); EFtop EF121, EF122A, EF122B, RF122C, EF125M, EF135M, EF351, 352, EF801, EF802 and EF601 (produced by JEMCO Inc.); PF636, PF656, PF6320 and PF6520 (produced by OMNOVA Solutions Inc.); and FTX-204G, 208G, 218G, 230G, 204D, 208D, 212D, 218D and 222D (produced by NEOS). In addition, Polysiloxane Polymer KP-341 (produced by Shin-Etsu Chemical Co., Ltd.) may also be used as a silicon-containing surfactant.

Other than these known surfactants, a surfactant using a polymer having a fluoroaliphatic group that is derived from a fluoroaliphatic compound produced by a telomerization process (also called telomer process) or an oligomerization process (also called oligomer process) may also be used. The fluoroaliphatic compound can be synthesized by the method described in JP-A-2002-90991.

For example, as the commercially available surfactant, the surfactant includes Megaface F178, F-470, F-473, F-475, F-476 and F-472 (produced by DIC Corporation). In addition, the surfactant includes a copolymer of a C₆F₁₃ group-containing acrylate (or methacrylate) with a (poly(oxyalkylene)) acrylate (or methacrylate), a copolymer of a C3F7 group-containing acrylate (or methacrylate) with a (poly(oxyethylene)) acrylate (or methacrylate) and a (poly(oxypropylene)) acrylate (or methacrylate), etc.

Furthermore, a surfactant other than fluorine- and/or silicon-containing surfactants may also be used. Specifically, the surfactant includes a nonionic surfactant, etc., for example, polyoxyethylene alkyl ethers such as polyoxyethylene lauryl ether, polyoxyethylene stearyl ether, polyoxyethylene cetyl ether and polyoxyethylene oleyl ether, polyoxyethylene alkylaryl ethers such as polyoxyethylene octylphenol ether and polyoxyethylene nonylphenol ether, polyoxyethylene-polyoxypropylene block copolymers, sorbitan fatty acid esters such as sorbitan monolaurate, sorbitan monopalmitate, sorbitan monostearate, sorbitan monooleate, sorbitan trioleate and sorbitan tristearate, and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate and polyoxyethylene sorbitan tristearate.

One of these surfactants may be used alone, or some of them may be used in combination.

The amount of the surfactant used is preferably from 0.0001 to 2 mass %, more preferably from 0.001 to 1 mass %, relative to the total amount of the actinic ray-sensitive or radiation-sensitive resin composition (excluding the solvent).

### [6] Low Molecular Additive

The actinic ray-sensitive or radiation-sensitive resin composition of the present invention may contain a low molecular additive having a molecular weight of 3,000 or less and being capable of decomposing by an action of an acid to increase the solubility in an alkali developer (hereinafter, sometimes referred to as “low molecular compound”).

The low molecular compound is preferably an alicyclic or aliphatic compound containing an acid-decomposable group, such as acid-decomposable group-containing cholic acid derivatives described in Proceeding of SPIE, 2724, 355 (1996). Examples of the acid-decomposable group and alicyclic structure are the same as those described above for the acid-decomposable resin.

In the case where the actinic ray-sensitive or radiation-sensitive resin composition of the present invention is irradiated with an electron beam, a compound containing a structure where a phenolic hydroxyl group in a phenol compound is substituted with an acid-decomposable group, is preferred. The phenol compound is preferably a compound containing from 1 to 9 phenol frameworks, more preferably from 2 to 6 phenol frameworks.

The molecular weight of the low molecular compound for use in the present invention is 3,000 or less, preferably from 300 to 3,000, more preferably from 500 to 2,500.

The amount of the low molecular compound added is preferably from 0 to 50 mass %, more preferably from 0 to 40 mass %, relative to the total solid content of the actinic ray-sensitive or radiation-sensitive resin composition.

Specific examples of the low molecular compound are illustrated below, but the present invention is not limited thereto.

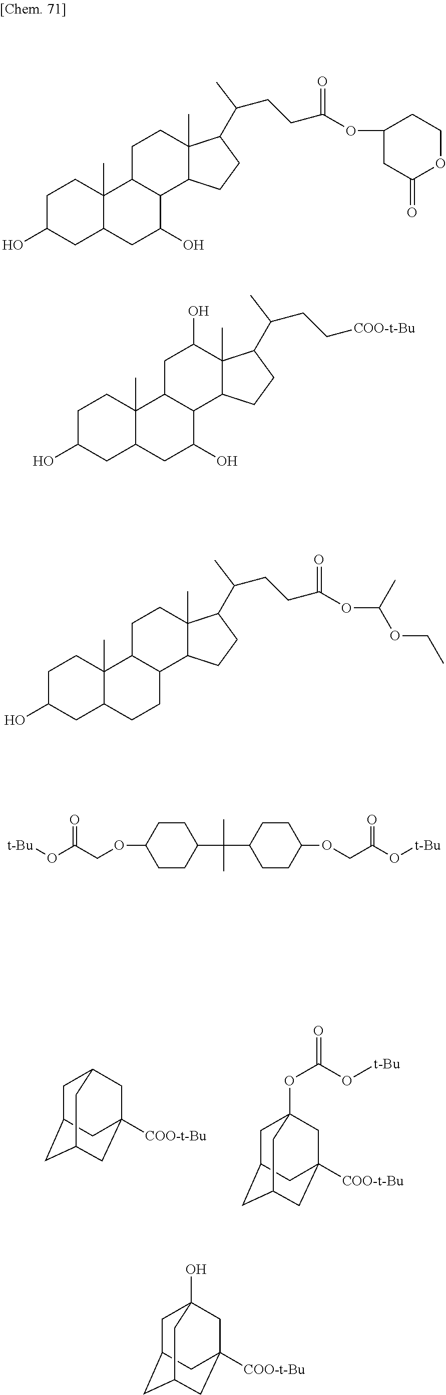

### [7] Acid-Increasing Agent

The actinic ray-sensitive or radiation-sensitive resin composition of the present invention may further contain one compound or two or more compounds capable of decomposing by an action of an acid to generate an acid (hereinafter, sometimes referred to as acid-increasing agent). The acid generated from the acid-increasing agent is preferably a sulfonic acid, a methide acid or an imide acid. The content of the acid-increasing agent is preferably from 0.1 to 50 mass %, more preferably from 0.5 to 30 mass %, still more preferably from 1.0 to 20 mass %, based on the total solid content of the composition.

The quantitative ratio of the acid-increasing agent and the acid generator (amount of solid content of acid-increasing agent based on the total solid content in composition/amount of solid content of acid generator based on the total solid content in composition) is not particularly limited but is preferably from 0.01 to 50, more preferably from 0.1 to 20, still more preferably from 0.2 to 1.0.

Examples of the compound that can be used in the present invention are illustrated below, but the present invention is not limited thereto.

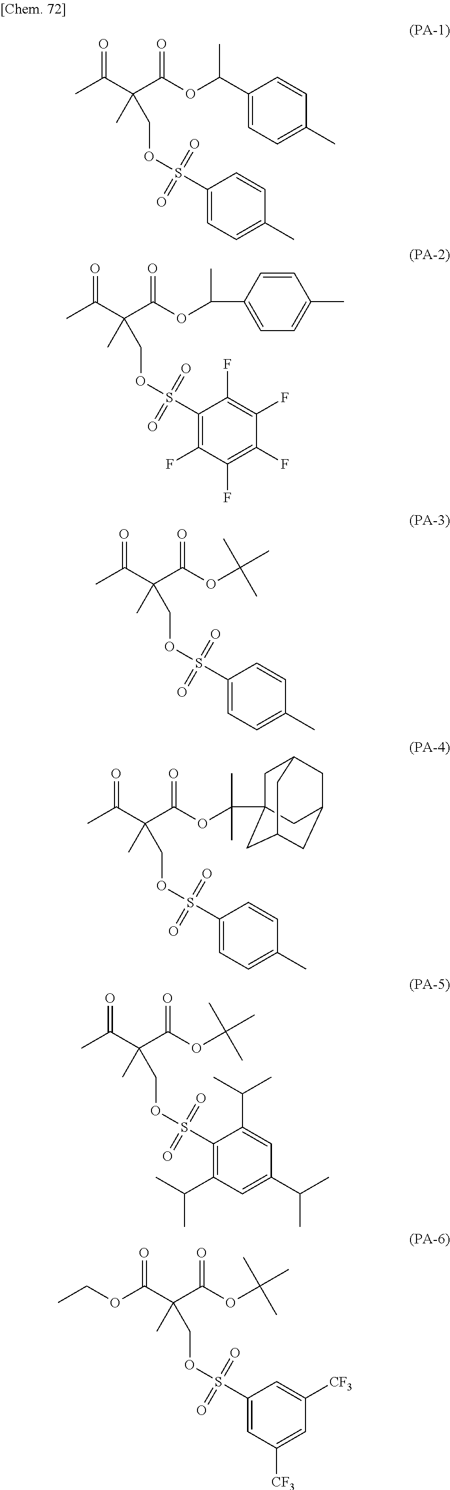

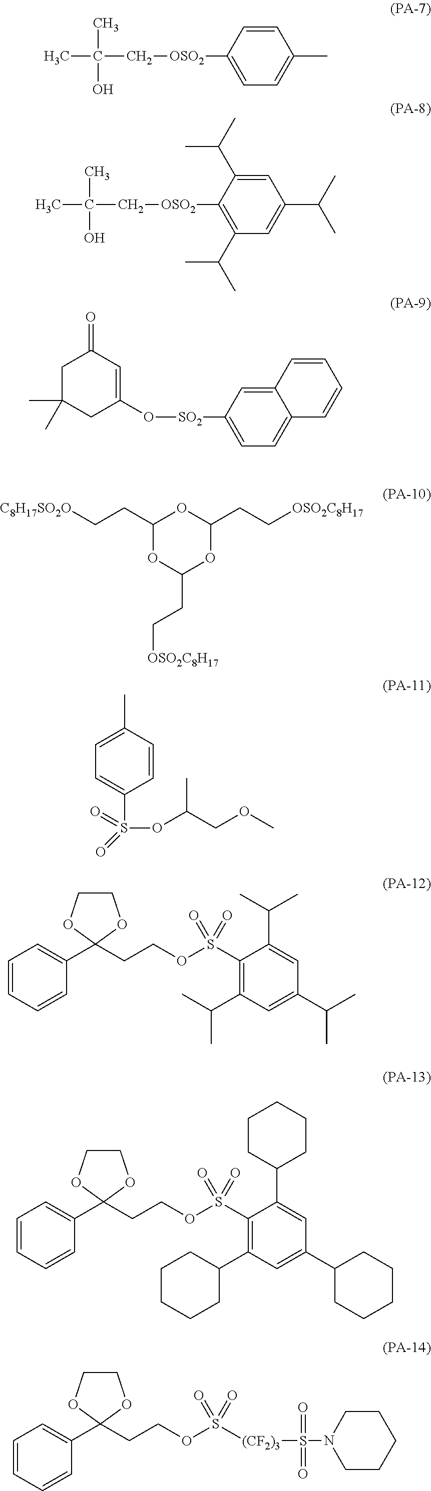

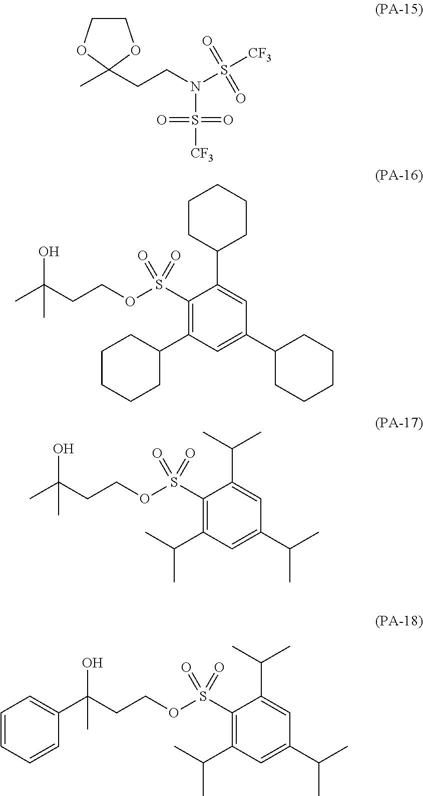

### [8] Other Additives

In addition to the components described above, the composition of the present invention may appropriately contain a carboxylic acid, an onium carboxylate, a low molecular compound having a molecular weight of 3,000 or less described, for example, in Proceeding of SPIE, 2724, 355 (1996), a dye, a plasticizer, a photosensitizer, a light absorber, an antioxidant, etc.

Among others, a carboxylic acid is suitably used for enhancing the performance. The carboxylic acid is preferably an aromatic carboxylic acid such as benzoic acid and naphthoic acid.

The content of the carboxylic acid is preferably from 0.01 to 10 mass %, more preferably from 0.01 to 5 mass %, still more preferably from 0.01 to 3 mass %, relative to the total solid content concentration of the composition.

From the standpoint of enhancing the resolution, the actinic ray-sensitive or radiation-sensitive resin composition of the present invention is preferably used in a film thickness of 10 to 250 nm, more preferably from 20 to 200 nm, still more preferably from 30 to 100 nm. Such a film thickness can be achieved by setting the solid content concentration in the composition to an appropriate range, thereby imparting an appropriate viscosity and enhancing the coatability and film-forming property.

The solid content concentration of the actinic ray-sensitive or radiation-sensitive resin composition of the present invention is usually from 1.0 to 10 mass %, preferably from 2.0 to 5.7 mass %, more preferably from 2.0 to 5.3 mass %. By setting the solid content concentration to the range above, the resist solution can be uniformly coated on a substrate and furthermore, a resist pattern improved in the line width roughness can be formed. The reason therefor is not clearly known, but it is considered that probably thanks to a solid content concentration of 10 mass % or less, preferably 5.7 mass % or less, aggregation of materials, particularly, a photoacid generator, in the resist solution is suppressed, as a result, a uniform resist film can be formed.

The solid content concentration is a weight percentage of the weight of resist components excluding the solvent, relative to the total weight of the actinic ray-sensitive or radiation-sensitive resin composition.

The actinic ray-sensitive or radiation-sensitive resin composition of the present invention is used by dissolving the components above in a predetermined organic solvent, preferably in the above-described mixed solvent, filtering the solution, and coating the filtrate on a predetermined support (substrate). The filter used for filtration is preferably a polytetrafluoroethylene-, polyethylene- or nylon-made filter having a pore size of 0.1 μm or less, more preferably 0.05 μm or less, still more preferably 0.03 μm or less. In the filtration through a filter, as described, for example, in JP-A-2002-62667, circulating filtration may be performed, or the filtration may be performed by connecting a plurality of kinds of filters in series or in parallel. In addition, the composition may be filtered a plurality of times. Furthermore, a deaeration treatment, etc. may be applied to the composition before and after filtration through a filter.

### [Usage]

The pattern forming method of the present invention is suitably used for the fabrication of a semiconductor microcircuit, for example, in the production of VLSI or a high-capacity microchip. Incidentally, at the time of fabrication of a semiconductor microcircuit, the resist film having formed therein a pattern is subjected to circuit formation or etching and the remaining resist film part is finally removed with a solvent, etc. Therefore, unlike a so-called permanent resist used for a printed board, etc., the resist film derived from the actinic ray-sensitive or radiation-sensitive resin composition of the present invention does not remain in the final product such as microchip.

The pattern forming method of the present invention may also be used for guide pattern formation (see, for example, ACS Nano, Vol. 4, No. 8, pp. 4815-4823) in DSA (Directed Self-Assembly).

In addition, the resist pattern formed by the method above can be used as a core material (core) in the spacer process disclosed, for example, in JP-A-3-270227 and JP-A-2013-164509.

The present invention also relates to a method for manufacturing an electronic device, including the above-described pattern forming method of the present invention, and an electronic device manufactured by this manufacturing method.

The electronic device of the present invention is suitably mounted on electric electronic equipment (such as home electronic device, OA•media-related device, optical device and communication device).

### EXAMPLES

The present invention is described below by referring to Examples, but the present invention is not limited thereto.

### Synthesis Example 1

### Synthesis of Resin (P-1)

The resin was synthesized according to the following scheme.

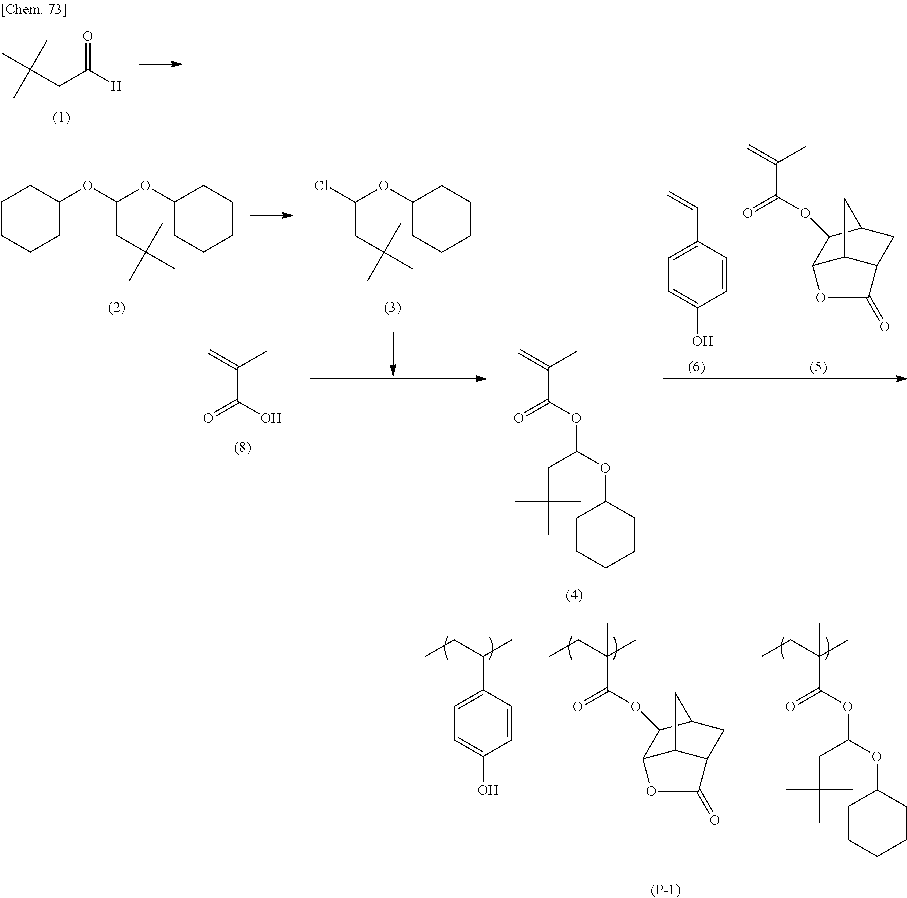

20.00 g of Compound (1) was dissolved in 113.33 g of n-hexane, and 42.00 g of cyclohexanol, 20.00 g of anhydrous magnesium sulfate, and 2.32 g of 10-camphorsulfonic acid were added thereto. The resulting mixture was stirred at room temperature (25° C.) for 7.5 hours, and 5.05 g of triethylamine was added. After stirring for 10 minutes, the solid substance was removed by filtration, and 400 g of ethyl acetate was added to the residue. The organic phase was washed with 200 g of ion-exchanged water five times and then dried over anhydrous magnesium sulfate, and thereafter, the solvent was removed by distillation to obtain 44.86 g of a Compound (2)-containing solution.

To 23.07 g of the Compound (2)-containing solution, 4.52 g of acetyl chloride was added, and the resulting mixture was stirred at room temperature for 2 hours to obtain 27.58 g of a Compound (3)-containing solution.

3.57 g of Compound (8) was dissolved in 26.18 g of dehydrated tetrahydrofuran, and 3.57 g of anhydrous magnesium sulfate and 29.37 g of triethylamine were added thereto. The resulting mixture was stirred in a nitrogen atmosphere and then cooled to 0° C., and 27.54 g of the Compound (3)-containing solution was added dropwise. After stirring at room temperature for 3.5 hours, the solid substance was removed by filtration, and 400 g of ethyl acetate was added to the residue. The organic phase was washed with 150 g of ion-exchanged water five times and then dried over anhydrous magnesium sulfate, and the solvent was removed by distillation. The residue was subjected to isolation and purification by column chromatography to obtain 8.65 g of Compound (4).

A solution (50.00 mass %) of 2.52 g of Compound (6) in cyclohexanone, 0.78 g of Compound (5), 5.64 g of Compound (4) and 0.32 g of polymerization initiator V-601 (produced by Wako Pure Chemical Industries, Ltd.) were dissolved in 27.01 g of cyclohexanone, and 15.22 g of cyclohexanone was put in a reaction vessel and, in a nitrogen gas atmosphere, added dropwise to the system at 85° C. over 4 hours. The reaction solution was stirred under heating over 2 hours and then allowed to cool to room temperature.

The reaction solution above was added dropwise to 400 g of heptane to precipitate a polymer and then filtered. The solid substance collected by filtration was washed by spraying 200 g of heptane, and the solid substance after washing was dried under reduced pressure to obtain 2.98 g of Resin (P-1).

Resins (P-2) to (P-8) shown below were synthesized in the same manner as in Synthesis Example 1.

The weight average molecular weight, compositional ratio (molar ratio) and polydispersity of each of the resins obtained are shown below.

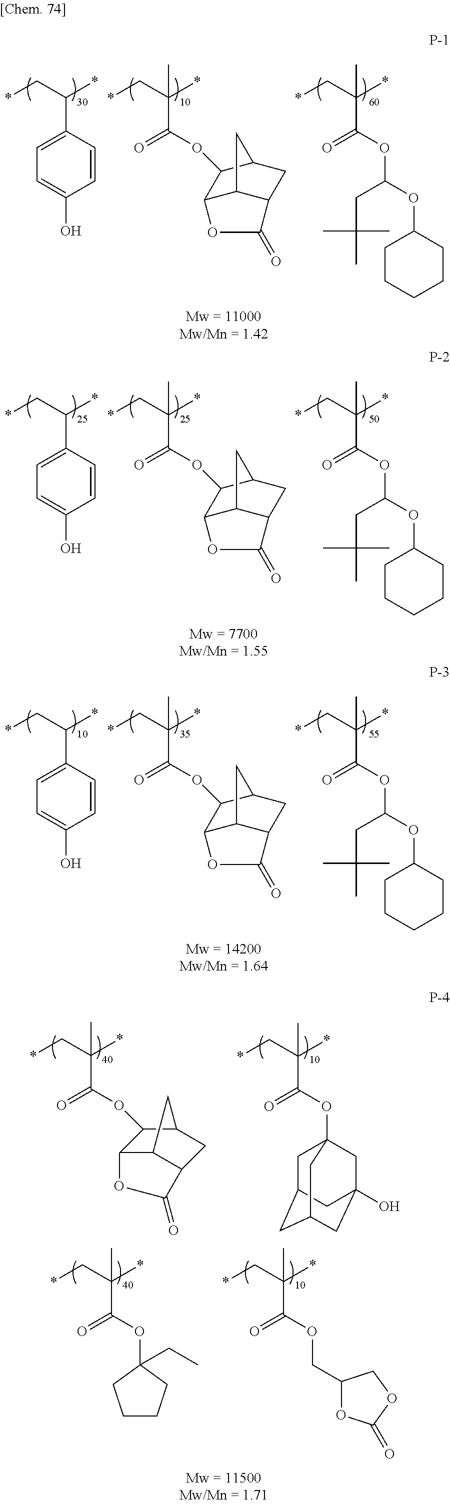

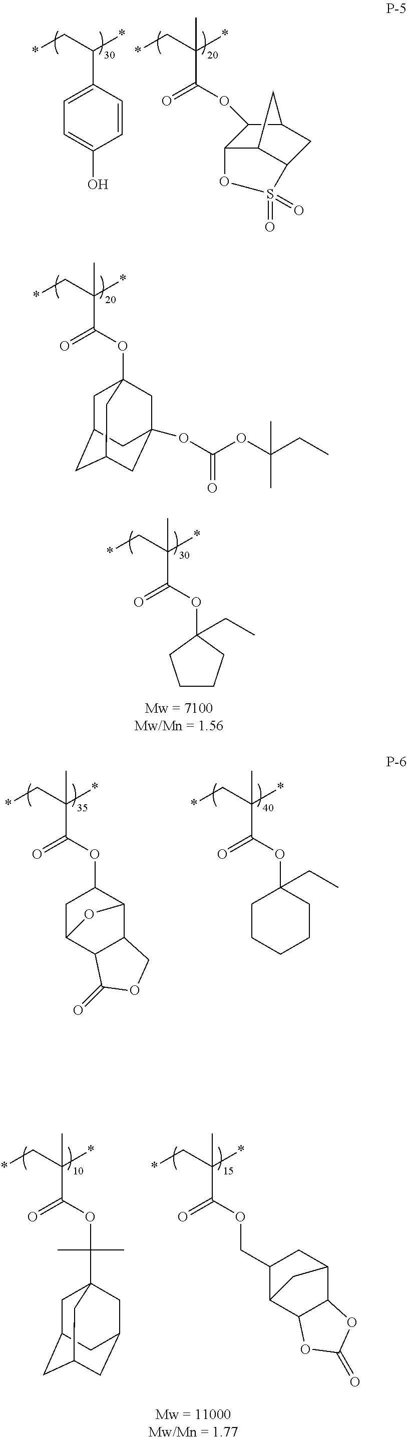

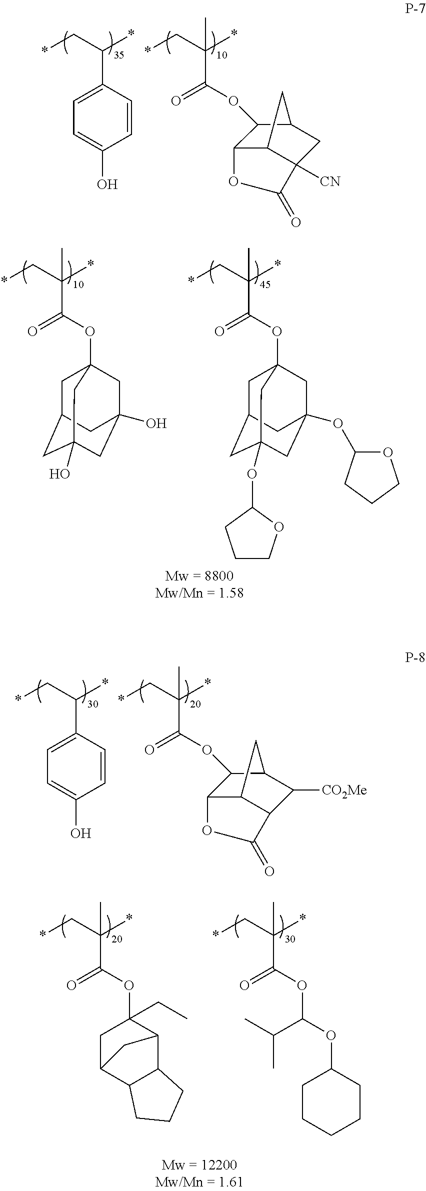

### <Synthesis of Resin (R-1)>

After anionic polymerization of p-tert-butoxystyrene, deprotection with an acid was performed to obtain poly(p-hydroxystyrene). The weight average molecular weight (Mw) determined by GPC (carrier: tetrahydrofuran, in terms of polystyrene) was Mw=3,300, and the polydispersity (Pd) was 1.2.

To 50.0 parts by mass of a mixed solution (solid content: 20.0 mass %) of thoroughly dehydrated poly(p-hydroxystyrene) and propylene glycol monomethyl ether acetate (PGMEA), 3.21 parts by mass of cyclohexylethyl vinyl ether was added. Subsequently, 1.58 parts by mass of a mixed solution (solid content: 1.0 mass %) of p-toluenesulfonic acid and PGMEA was added, and the reaction was allowed to proceed at room temperature for 1 hour under stirring.

After adding 0.99 parts by mass of pyridine, 0.85 parts by mass of acetic anhydrous was added, and the reaction was allowed to proceed at room temperature for another 2 hours under stirring.

After the completion of reaction, the reaction solution was subjected to water washing, concentration, reprecipitation with a large amount of hexane, filtration and drying to obtain 11.9 parts by mass of a powder of Polymer (R-1). The weight average molecular weight, compositional ratio (molar ratio) and polydispersity of the polymer obtained are shown below.

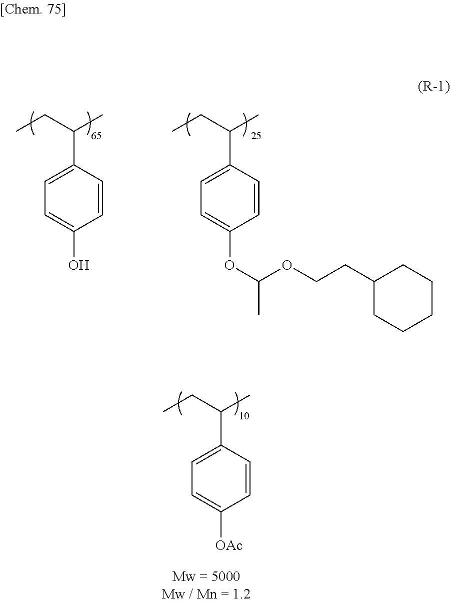

### Examples 1 to 10 and Comparative Examples 1 to 3

### Extreme-Ultraviolet (EUV) Exposure

### (1) Preparation and Coating of Coating Solution of Actinic Ray-Sensitive or Radiation-Sensitive Resin Composition

A coating solution composition having a solid content concentration of 2.5 mass % according to the formulation shown in the Table below was microfiltered through a membrane filter having a pore size of 0.05 μm to obtain an actinic ray-sensitive or radiation-sensitive resin composition (resist composition) solution.

This actinic ray-sensitive or radiation-sensitive resin composition was coated on a 6-inch Si wafer previously subjected to a hexamethyldisilazane (HMDS) treatment, by using a spin coater, Mark 8, manufactured by Tokyo Electron Ltd. and dried on a hot plate at 100° C. for 60 seconds to obtain a resist film having a thickness of 50 nm.

In Examples 1 to 10 and Comparative Example 2, a protective film having a thickness of 30 nm was then formed from the protective film composition shown in Table 1 by the same method.

### (2) EUV Exposure and Development

The resist film-coated wafer obtained in (1) above was patternwise exposed through an exposure mask (line/space=1/4) by using an EUV exposure apparatus (Micro Exposure Tool, manufactured by Exitech, NA: 0.3, X-dipole, outer sigma: 0.68, inner sigma: 0.36). After the irradiation, the resist film was heated on a hot plate at 110° C. for 60 seconds, then developed by puddling the developer shown in the Table below for 30 seconds, rinsed by using the rinsing solution shown in the Table below, spun at a rotation speed of 4,000 rpm for 30 seconds and baked at 90° C. for 60 seconds to obtain a resist pattern having an isolated space pattern of line/space=4:1. In Comparative Examples 2 and 3, the pattern was formed in the same manner as in Example 1 except that the exposure mask was reversed (an exposure mask of line/space=4/1 was used).

In Example 2, the pattern was formed in the same manner as in Example 1 except that the protective film was removed by the contact with water for 90 seconds before development.

### (3) Evaluation of Resist Pattern

Using a scanning electron microscope (S-9380II, manufactured by Hitachi Ltd.), the resist pattern obtained was evaluated for resolution by the following method.

### (3-1) Line Edge Roughness (LER)

The resist composition was coated on a silicon wafer subjected to a hexamethyldisilazane treatment and baked on a hot plate at 100° C. for 60 seconds to form a resist film having a thickness of 50 nm. This resist film-coated wafer was patternwise exposed through an exposure mask (line/space=1/1) by using an EUV exposure apparatus (Micro Exposure Tool, manufactured by Exitech, NA: 0.3, Quadrupole, outer sigma: 0.68, inner sigma: 0.36). After the irradiation, the resist film was heated on a hot plate at 110° C. for 60 seconds, then developed by puddling the developer shown in the Table for 30 seconds, spun at a rotation speed of 4,000 rpm for 30 seconds and baked at 90° C. for 60 seconds to obtain a resist pattern of 1:1 line-and-space having a line width of 50 nm.

With respect to arbitrary 30 points included in the longitudinal 50 μm region of a resist pattern at the exposure dose when forming the above-described resist pattern of 1:1 line-and-space having a line width of 50 nm, the distance from the reference line where the edge should be present was measured using a scanning electron microscope (S-9220, manufactured by Hitachi, Ltd.). The standard deviation of the measured distances was determined, and 3σ (nm) was computed. A smaller value indicates better performance.

### (3-2) Resolution in Isolated Space

The limiting resolution (the minimum space width below which the line and the space were not separated and resolved) of the isolated space (line/space=4:1) was determined. This value was taken as “Resolution (nm)”. A smaller value indicates better performance.

### (3-3) Top Roughness

A cross-sectional SEM photograph of the above-described resist pattern of 1:1 line-and-space having a line width of 50 nm was taken, and the unevenness of pattern top was evaluated with an eye. The pattern with small surface roughness was rated as A, and the pattern with large surface roughness was rated as B.

### [Protective Layer Composition]

As the protective layer composition, the following (T-1) or (T-2) was used.

T-1: A 1 wt % MIBC (methyl isobutyl carbinol) solution of the polymer shown below.

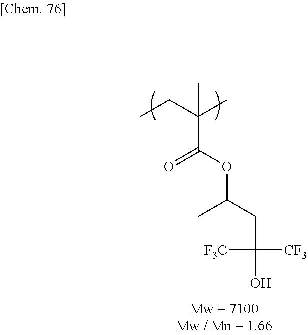

T-2: An aqueous solution containing 1 wt % of Polyvinylpyrrolidone K 15 produced by Tokyo Chemical Industry Co., Ltd. (viscosity average molecular weight: 10,000) (CAS No.: 9003-39-8) and 0.01 wt % of Olfine EXP4200 (surfactant, produced by Nissin Chemical Industry Co., Ltd.) (the pH of Solution T-2 is 6.7)

### [Photoacid Generator]

As the photoacid generator, a photoacid generator appropriately selected from the following compounds as specific examples was used.

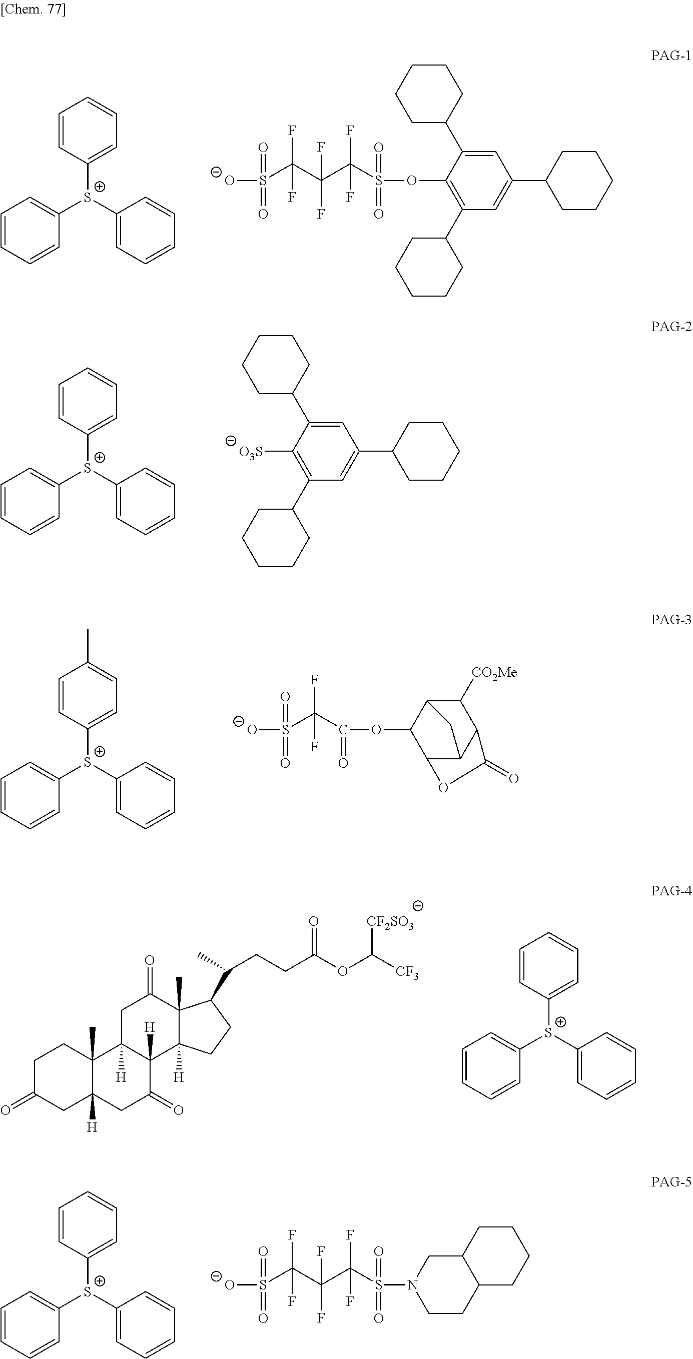

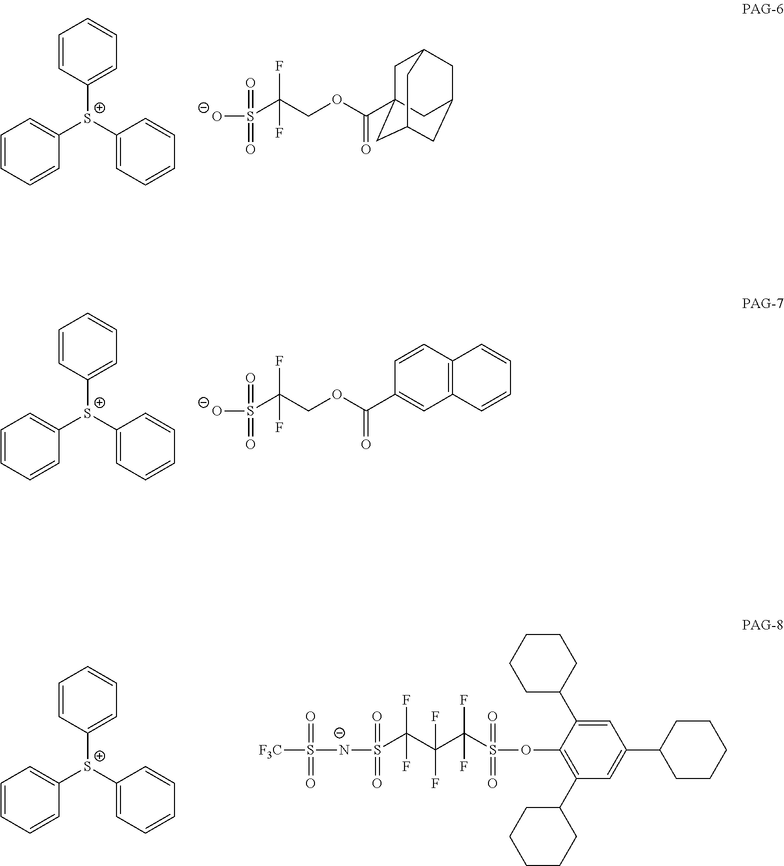 [SMILES: c1ccc([S+](c2ccccc2)c2ccccc2)cc1 ; O=C(OCC(F)(F)S(=O)(=O)[O-])C12CC3CC(CC(C3)C1)C2 ; c1ccc([S+](c2ccccc2)c2ccccc2)cc1 ; O=C(OCC(F)(F)S(=O)(=O)[O-])c1ccc2ccccc2c1 ; c1ccc([S+](c2ccccc2)c2ccccc2)cc1 ; O=S(=O)([N-]S(=O)(=O)C(F)(F)C(F)(F)C(F)(F)S(=O)(=O)Oc1c(C2CCCCC2)cc(C2CCCCC2)cc1C1CCCCC1)C(F)(F)F]

### [Basic Compound]

As the basic compound, any one of the following Compounds (N-1) to (N-11) was used.

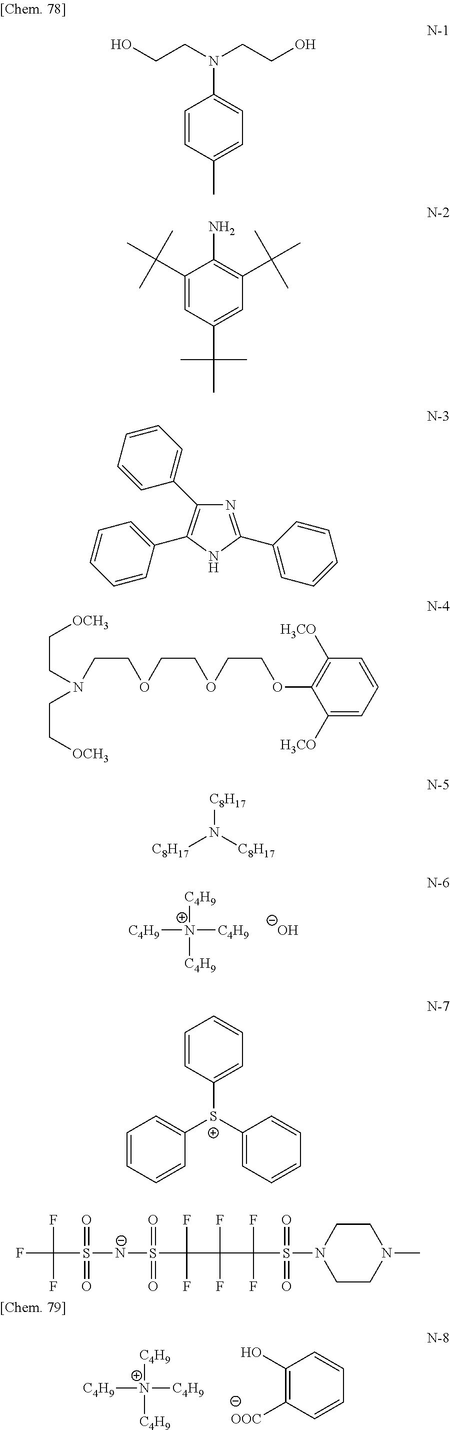

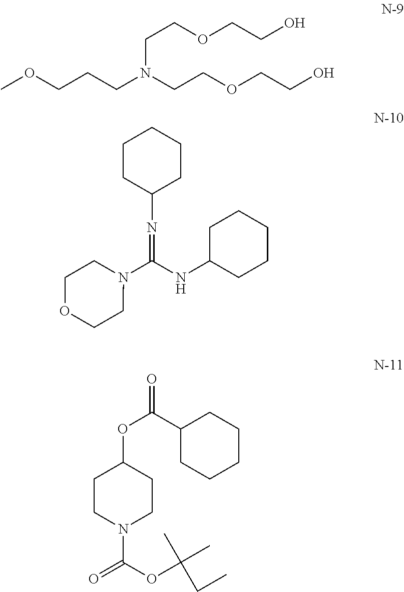

Here, Compound (N-7) comes under the above-described compound (PA) and was synthesized based on the description in [0354] of JP-A-2006-330098.

### [Surfactant]

As the surfactant, the following W-1 to W-4 were used.

W-1: Megaface F176 (produced by DIC Corp.) (fluorine-containing)
W-2: Megaface R08 (produced by DIC Corp.) (containing fluorine and silicon)
W-3: Polysiloxane Polymer KP-341 (produced by Shin-Etsu Chemical Co., Ltd.) (silicon-containing) W-4: PF6320 (produced by OMNOVA Solutions Inc.) (fluorine-containing)

### [Coating Solvent]

As the coating solvent, the followings were used.

S1: Propylene glycol monomethyl ether acetate (PGMEA)
S2: Propylene glycol monomethyl ether (PGME)
S3: Ethyl lactate

### S4: Cyclohexanone

### S5: γ-Butyrolactone

### <Developer>

As the developer, the followings were used.

SG-1: Butyl acetate
TMAH: An aqueous 2.38 mass % tetramethylammonium hydroxide solution

### <Rinsing Solution>

As the rinsing solution, the followings were used.

SR-1: 4-Methyl-2-pentanol

### SR-2: 1-Hexanol

SR-3: Methyl isobutyl carbinol
Water: Ultrapure water

TABLE 1

| | | | Basic | | | | | | | | |
|---|---|---|---|---|---|---|---|---|---|---|---|
| | Resin (A) | | Compound | Surfactant | | | | | | Resolution | Top |
| | (parts by | Acid Generator | (parts by | (parts by | Solvent | Protective | | Rinsing | | of Isolated | Rough- |
| | mass) | (parts by mass) | mass) | mass) | (parts by mass) | Layer | Developer | Solution | LER | Space | ness |
| Example 1 | P-1 | PAG-1 | N-6 | W-4 | S1/S2 | T-1 | SG-1 | | 3.1 | 28 | A |
| | (82.19) | (16) | (1.8) | (0.01) | (3120/780) | | | | | | |
| Example 2 | P-1 | PAG-1 | N-6 | W-4 | S1/S2 | T-2 | SG-1 | | 2.9 | 29 | A |
| | (82.19) | (16) | (1.8) | (0.01) | (3120/780) | | | | | | |
| Example 3 | P-2 | PAG-1 | N-6 | W-4 | S1/S2 | T-1 | SG-1 | | 3 | 28 | A |
| | (82.19) | (16) | (1.8) | (0.01) | (3120/780) | | | | | | |
| Example 4 | P-3 | PAG-1 | N-6 | W-4 | S1/S2 | T-1 | SG-1 | SR-3 | 2.9 | 28 | A |
| | (82.19) | (16) | (1.8) | (0.01) | (3120/780) | | | | | | |
| Example 5 | P-4 | PAG-6/PAG-1 | N-7/N-4 | | S1/S3/S4 | T-1 | SG-1 | | 3.2 | 29 | A |
| | (74.7) | (15/7) | (3/0.3) | | (2400/1000/500) | | | | | | |
| Example 6 | P-5/P-8 | PAG-4/PAG-6 | N-10/N-5 | W-4 | S1/S3/S4 | T-1 | SG-1 | | 2.9 | 27 | A |
| | (54.15/20) | (15/8) | (2.5/0.3) | (0.05) | (2400/1000/500) | | | | | | |
| Example 7 | P-6 | PAG-3/PAG-8 | N-9/N-8 | | S1/S2/S5 | T-1 | SG-1 | SR-1 | 3 | 28 | A |
| | (74) | (20/4) | (1/1) | | (2600/1200/100) | | | | | | |
| Example 8 | P-7/P-1 | PAG-2/PAG-5 | N-1/N-3 | W-3 | S1/S2/S5 | T-1 | SG-1 | SR-2 | 3 | 29 | A |
| | (50.48/30) | (14/3.5) | (1/1) | (0.02) | (2600/1200/100) | | | | | | |
| Example 9 | P-8 | PAG-7/PAG-2 | N-2/N-11 | W-3 | S1/S2/S5 | T-1 | SG-1 | | 3 | 29 | A |
| | (66.98) | (20/11) | (1/1) | (0.02) | (2400/1200/300) | | | | | | |
| Example 10 | P-7 | PAG-4/PAG-2 | N-11/N-6 | W-2 | S1/S2/S5 | T-1 | SG-1 | | 3 | 28 | A |
| | (76.98) | (15/6) | (1/1) | (0.02) | (2400/1200/300) | | | | | | |
| Comparative | P-1 | PAG-1 | N-6 | W-4 | S1/S2 | none | SG-1 | | 4.7 | 35 | B |
| Example 1 | (82.19) | (16) | (1.8) | (0.01) | (3120/780) | | | | | | |
| Comparative | R-1 | PAG-1 | N-6 | W-4 | S1/S2 | T-1 | TMAH | water | 4.5 | 36 | B |
| Example 2 | (82.19) | (16) | (1.8) | (0.01) | (3120/780) | | | | | | |
| Comparative | R-1 | PAG-1 | N-6 | W-1 | S1/S2 | none | TMAH | water | 5.2 | 36 | B |
| Example 3 | (82.19) | (16) | (1.8) | (0.01) | (3120/780) | | | | | | |

It is apparent from the results shown in the Table above that in Examples 1 and 2 where the resist pattern was formed using the pattern forming method of the present invention, the resolution at the time of formation of an isolated space pattern is excellent, compared with Comparative Examples 1 and 3 where the resist pattern was formed using a pattern method not including a step of forming, on the resist film, a protective film from a protective film composition.

In addition, it is apparent that in Examples 1 and 2 where the resist pattern was formed using the pattern forming method of the present invention, the resolution at the time of formation of an isolated space pattern is more excellent than in Comparative Examples 2 and 3 where the pattern was formed using an alkali developer.

Furthermore, it is seen that the resolution at the time of formation of an isolated space patter has no difference between Comparative Example 2 where a protective film was formed on the resist film and alkali development was performed and Comparative Example 3 where alkali development was performed without forming a protective film on the resist film. On the other hand, it is evident that in Examples 1 to 10 where a protective film was formed on the resist film and development using an organic solvent was performed, the resolution at the time of formation of an isolated space pattern is more improved, compared with Comparative Example 1 where development using an organic solvent was performed without forming a protective film on the resist film.

### INDUSTRIAL APPLICABILITY

According to the present invention, a pattern forming method ensuring excellent resolution at the time of formation of an isolated space pattern having an ultrafine space width (for example, a space width of 30 nm or less) can be provided.

While the invention has been described in detail and with reference to specific embodiments thereof, it will be apparent to one skilled in the art that various changes and modifications can be made therein without departing from the spirit and scope of the invention.

This application is based on Japanese Patent Application (Patent Application No. 2013-017957) filed on Jan. 31, 2013, the contents of which are incorporated herein by way of reference.

1. A pattern forming method comprising:
a step of forming a resist film from an actinic ray-sensitive or radiation-sensitive resin composition containing a resin capable of increasing the polarity by an action of an acid to decrease the solubility in an organic solvent-containing developer and a compound capable of decomposing upon irradiation with an actinic ray or radiation to generate an acid,
a step of forming, on the resist film, a protective film from a protective film composition,
a step of exposing the resist film having a protective film to an electron beam or an extreme-ultraviolet ray, and
a step of developing the resist film by using the organic solvent-containing developer.

2. The pattern forming method as claimed in claim 1,
wherein the exposure is exposure without intervention of an immersion medium.

3. The pattern forming method as claimed in claim 1,
wherein the protective film composition is an aqueous composition.

4. The pattern forming method as claimed in claim 3,
wherein the pH of the aqueous composition is from 1 to 10.

5. The pattern forming method as claimed in claim 3, further comprising a separation step between the step of exposing the resist film and the step of developing the resist film.

6. The pattern forming method as claimed in claim 5,
wherein the separation step is performed by bringing the protective film into contact with water.

7. The pattern forming method as claimed in claim 1,
wherein the protective film composition contains an amphiphatic resin.

8. The pattern forming method as claimed in claim 1,
wherein the protective film composition is an organic solvent-based composition.

9. The pattern forming method as claimed in claim 1,
wherein the resin capable of increasing the polarity by an action of an acid to decrease the solubility in an organic solvent-containing developer contains a repeating unit represented by the following formula (I): 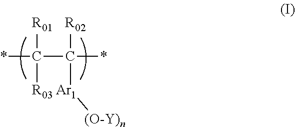
wherein
each of R₀₁, R₀₂ and R₀₃ independently represents a hydrogen atom, an alkyl group, a cycloalkyl group, a halogen atom, a cyano group or an alkoxycarbonyl group,
R₀₃ may represent an alkylene group and combine with Ar₁ to form a 5- or 6-membered ring,
Ar₁ represented an aromatic ring group,
each of n Ys independently represents a hydrogen atom or a group capable of leaving by an action of an acid, provided that at least one Y represents a group capable of leaving by an action of an acid, and
n represents an integer of 1 to 4.

10. The pattern forming method as claimed in claim 1,
wherein the resin capable of increasing the polarity by an action of an acid to decrease the solubility in an organic solvent-containing developer contains a repeating unit having a lactone structure-containing group.

11. The pattern forming method as claimed in claim 1,
wherein the organic solvent contained in the organic solvent-containing developer is at least one organic solvent selected from the group consisting of a ketone-based solvent, an ester-based solvent and an ether-based solvent.

12. The pattern forming method as claimed in claim 1, comprising rinsing the resist film by using an organic solvent-containing rinsing solution after development using the organic solvent-containing developer.

13. The pattern forming method as claimed in claim 12,
wherein the organic solvent contained in the rinsing solution is an alcohol-based solvent.

14. A method for manufacturing an electronic device, comprising the pattern forming method claimed in claim 1.

15. An electronic device manufactured by the method for manufacturing an electronic device claimed in claim 14.
